(19) United States
(12) Patent Application Publication
(10) Pub. No.: US 2025/0089438 A1
(43) Pub. Date: Mar. 13, 2025

(54) ELECTRONIC APPARATUS COMPRISING ORGANIC PHOTODETECTOR AND LIGHT-EMITTING DEVICE

(71) Applicant: Samsung Display Co., LTD., Yongin-si (KR)

(72) Inventors: Jinsoo Jung, Yongin-si (KR); Seokgyu Yoon, Yongin-si (KR); Minsoo Choi, Yongin-si (KR); Soungwook Kim, Yongin-si (KR); Hyejin Jung, Yongin-si (KR)

(21) Appl. No.: 18/598,962

(22) Filed: Mar. 7, 2024

(30) Foreign Application Priority Data
Sep. 6, 2023 (KR) 10-2023-0118549

(51) Int. Cl. H10K 39/34; H10K 50/15; H10K 50/16; H10K 50/19; H10K 85/30; H10K 85/60

(52) U.S. Cl. CPC H10K 39/34; H10K 50/15; H10K 50/16; H10K 50/19; H10K 85/342; H10K 85/622; H10K 85/633; H10K 85/636; H10K 85/653; H10K 85/654; H10K 85/655; H10K 85/656; H10K 85/6572; H10K 85/6574; H10K 85/658

(57) ABSTRACT

An electronic apparatus includes a substrate including a light detection region and an emission region, an organic photodetector on the light detection region, and a light-emitting device on the emission region, wherein the organic photodetector includes a first pixel electrode, a counter electrode facing the first pixel electrode, m organic light detection units each including an active layer between the first pixel electrode and the counter electrode, and m−1 charge generation layers between two adjacent organic light detection units from among the m organic light detection units, and the m organic light detection units absorb different colors of light from each other.

### CROSS-REFERENCE TO RELATED APPLICATION

The present application claims priority to and the benefit of Korean Patent Application No. 10-2023-0118549, filed on Sep. 6, 2023, in the Korean Intellectual Property Office, the entire disclosure of which is incorporated by reference herein.

### BACKGROUND

### 1. Field

One or more embodiments of the present disclosure relate to an electronic apparatus including an organic photodetector and a light-emitting device.

### 2. Description of the Related Art

Photoelectric devices are devices that convert light and electrical signals and include a photodiode and a phototransistor. Photoelectric devices may be applied to an image sensor, a solar cell, an organic light-emitting device, and/or the like.

In the case of silicon, which is mainly used in photodiodes, as the size of pixels decreases, an absorption region may decrease, thereby deteriorating sensitivity. Accordingly, organic materials that may replace silicon are being studied.

As organic materials have a large extinction coefficient and may selectively absorb light in a set or specific wavelength region according to the molecular structure thereof, organic materials may replace photodiodes and color filters concurrently (e.g., simultaneously), which may facilitate improvements in sensitivity and high integration.

An organic photodetector (OPD) including such an organic material may be applied to, for example, a display apparatus and/or an image sensor.

### 1 SUMMARY

One or more embodiments of the present disclosure include an electronic apparatus including an organic photodetector having improved efficiency.

Additional aspects of embodiments will be set forth in part in the description which follows and, in part, will be apparent from the description, or may be learned by practice of the presented embodiments of the disclosure.

According to one or more embodiments, an electronic apparatus includes a substrate including a light detection region and an emission region, an organic photodetector on the light detection region, and a light-emitting device on the emission region, wherein the organic photodetector includes a first pixel electrode, a counter electrode facing the first pixel electrode, m organic light detection units including an active layer (ACL) between the first pixel electrode and the counter electrode, and m−1 charge generation layers between two adjacent organic light detection units among the m organic light detection units, the light-emitting device includes a 2-1 pixel electrode, the counter electrode facing the 2-1 pixel electrode, m first emission units including an emission layer between the 2-1 pixel electrode and the counter electrode, and m−1 charge generation layers between two adjacent first emission units among the m first emission units, a 2-2 pixel electrode, the counter electrode facing the 2-2 pixel electrode, m second emission units including an emission layer between the 2-2 pixel electrode and the counter electrode, and m−1 charge generation layers between two adjacent second emission units among the m second emission units, a 2-3 pixel electrode, the counter electrode facing the 2-3 pixel electrode, m third emission units including an emission layer between the 2-3 pixel electrode and the counter electrode, and m−1 charge generation layers between two adjacent third emission units among the m third emission units, m is an integer of 2 or more, the m first emission units emit a first light, the m second emission units emit a second light, the m third emission units emit a third light, the first to third lights have different colors from each other, the m organic light detection units absorb different colors of light from each other, the first pixel electrode and the active layers are provided in correspondence with the light detection region, the 2-1 to 2-3 pixel electrodes and the emission layers are provided in correspondence with the emission region, and the m−1 charge generation layers and the counter electrode are provided for the entirety of the light detection region and the emission region.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic cross-sectional view of a structure of a general organic photodetector according to an embodiment;

FIGS. 2 and 3 are each a schematic cross-sectional view of a structure of an electronic apparatus, including an organic photodetector and a light-emitting device;

FIG. 4 is a schematic cross-sectional view of an electronic apparatus according to an embodiment; and

FIG. 5 is a graph showing a comparison of external quantum efficiency according to wavelength between an electronic apparatus in the art and an electronic apparatus according to an embodiment.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

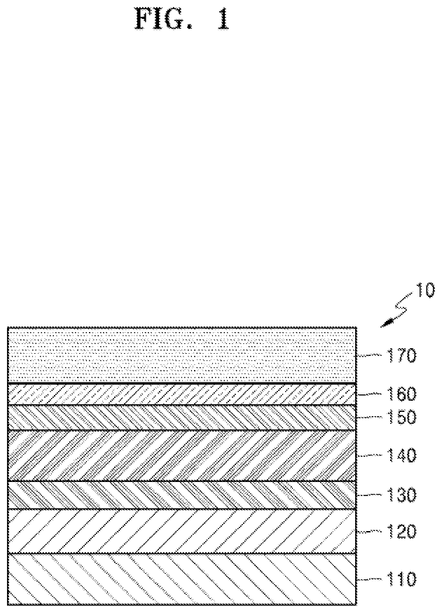

### Description of FIG. 1

FIG. 1 is a schematic cross-sectional view of a structure of a general organic photodetector according to an embodiment.

Referring to FIG. 1, an organic photodetector 10 may include: a first electrode 110; a second electrode 170 facing the first electrode 110; an active layer 140 between the first electrode 110 and the second electrode 170; an electron injection layer between the active layer 140 and the second electrode 170; an electron transport layer 160; a buffer layer 150; and a hole injection layer, a hole transport layer 120, and an optical auxiliary layer 130, which are between the first electrode 110 and the active layer 140.

The active layer 140 generates excitons in response to light irradiation from the outside and divides the generated excitons into holes and electrons. The active layer 140 may include a p-type semiconductor compound and an n-type semiconductor compound.

The optical auxiliary layer 130 may be a layer which increases light introduction efficiency by compensating for an optical resonance distance according to a wavelength of light introduced to the active layer 140.

For example, a total thickness of the optical auxiliary layer 130 may be about 100 Å to about 500 Å. When the thickness of the optical auxiliary layer is within the above range, such thickness may be suitable as a resonance thickness.

In FIG. 1, for example, the electron injection layer, the buffer layer 150, and the hole injection layer may each independently be present or not present in some embodiments.

The active layer 140 may include a p-type semiconductor compound and an n-type semiconductor compound. For example, the active layer 140 may be a mixed layer including a p-type semiconductor compound and an n-type semiconductor compound or include a layer including a p-type semiconductor compound and a layer including an n-type semiconductor compound.

The layer including a p-type semiconductor compound and the layer including an n-type semiconductor compound may form a PN junction. Excitons may be efficiently separated into holes and electrons by photo-induced charge separation occurring at an interface between these layers.

When the active layer 140 is a mixed layer, excitons may be generated within a diffusion distance from a p-type semiconductor compound-n-type semiconductor compound interface, and thus, the organic photodetector may have improved efficiency. A ratio between the p-type semiconductor compound and the n-type semiconductor compound may be, for example, 10:90 to 90:10 (weight ratio).

For example, the active layer 140 may be a mixed layer including or consisting of a p-type semiconductor compound and an n-type semiconductor compound. For example, the active layer 140 may include or consist of a layer consisting of a p-type semiconductor compound and a layer consisting of an n-type semiconductor compound.

The thickness of the active layer 140 may be about 200 Å to about 2,000 Å, and for example, about 400 Å to about 600 Å. When the active layer 140 includes a layer including a p-type semiconductor compound and a layer including an n-type semiconductor compound, the thicknesses of the layer including a p-type semiconductor layer and the layer including an n-type semiconductor compound may each independently be about 50 Å to about 1,000 Å, and for example, about 100 Å to about 400 Å.

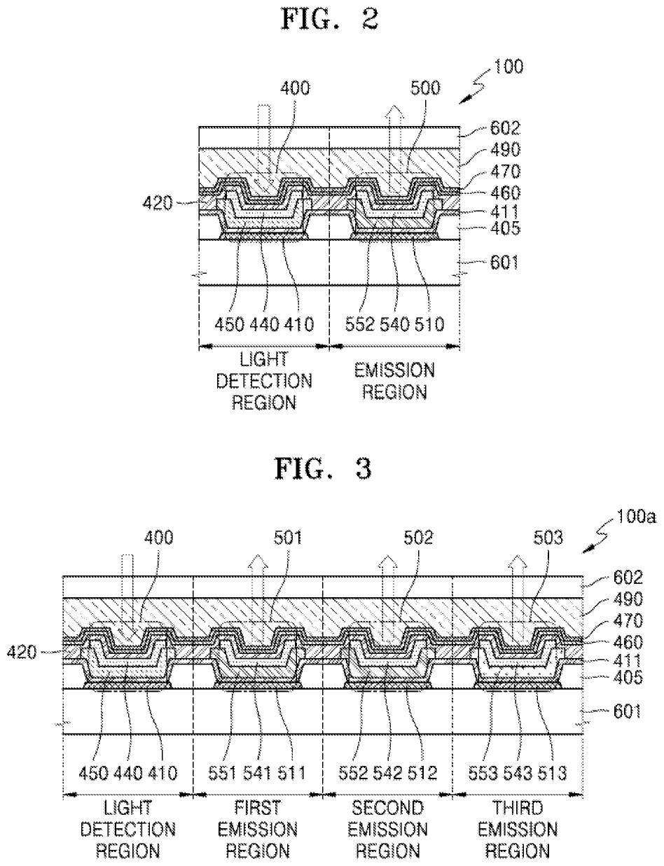

### Description of FIGS. 2 and 3

FIG. 2 is a schematic cross-sectional view of an electronic apparatus 100, including an organic photodetector and a light-emitting device.

Referring to FIG. 2, the electronic apparatus 100 may include an organic photodetector 400 and a light-emitting device 500 between a substrate 601 and a substrate 602.

The substrate 601 and the substrate 602 may be a flexible substrate, a glass substrate, and/or a metal substrate. A buffer layer and a thin-film transistor may be located on the substrate 601.

The buffer layer serves to prevent or reduce infiltration of impurities through the substrate 601 and provide a flat surface on the substrate 601. The thin-film transistor is on the buffer layer, and may include an active layer, a gate electrode, a source electrode, and a drain electrode.

The thin-film transistor is electrically connected to the light-emitting device 500 to drive the light-emitting device. A second pixel electrode 510 of the light-emitting device 500 may be electrically connected with either one of the source electrode and the drain electrode.

Another thin-film transistor may be electrically connected to the organic photodetector 400. A first pixel electrode 410 of the organic photodetector 400 may be electrically connected with either one of the source electrode and the drain electrode.

The organic photodetector 400 may include a first pixel electrode 410, a hole transport layer 411, an optical auxiliary layer 450, an active layer 440, a buffer layer 420, an electron transport layer 460, and a counter electrode 470.

The first pixel electrode 410 may be an anode, and the counter electrode 470 may be a cathode. In some embodiments, as the organic photodetector 400 is driven by applying a reverse bias across the first pixel electrode 410 and the counter electrode 470, the electronic apparatus 100 may detect light incident onto the organic photodetector 400, generate charges, and extract the charges as a current.

The light-emitting device 500 may include a second pixel electrode 510, a hole transport layer 411, an optical auxiliary layer 552, an emission layer 540, a buffer layer 420, an electron transport layer 460, and a counter electrode 470.

The second pixel electrode 510 may be an anode, and the counter electrode 470 may be a cathode. In some embodiments, in the light-emitting device 500, holes injected from the second pixel electrode 510 and electrons injected from the counter electrode 470 recombine in the emission layer 540 to generate excitons, which generate light by changing from an excited state to a ground state.

For descriptions of the first pixel electrode 410 and the second pixel electrode 510, the descriptions of the first electrode 110 provided herein may be referred to.

A pixel define layer 405 is provided at the edge portions of the first pixel electrode 410 and the second pixel electrode 510. The pixel define layer 405 defines a pixel region, and may electrically insulate the first pixel electrode 410 and the second pixel electrode 510. The pixel define layer 405 may include, for example, various suitable organic insulating material (for example, silicone-based materials, and/or the like), inorganic insulating materials, or organic/inorganic composite insulating materials. The pixel define layer 405 may be a transmissive film that transmits visible light, or a blocking film that blocks or reduces transmission of visible light.

As a common layer, the hole transport layer 411 may be on the first pixel electrode 410 and the second pixel electrode 510. The hole transport layer 411 is the same as described in the specification.

The active layer 440 may be on the optical auxiliary layer 450 to correspond to the light detection region. The active layer 440 is the same as described herein in connection with the active layer 140 of FIG. 1.

The emission layer 540 may be formed on the optical auxiliary layer 552 to correspond to the emission region. In one or more embodiments, the light-emitting device 500 may further include, between the second pixel electrode 510 and the emission layer 540, an electron blocking layer provided in correspondence with the light emission region.

As common layers for the entirety of the light detection region and the emission region, the buffer layer 420, the electron transport layer 460, and the counter electrode 470 may be sequentially formed on the active layer 440 and the emission layer 540. The buffer layer 420, the electron transport layer 460, and the counter electrode 470 are respectively the same as described herein in connection with the buffer layer, the electron transport layer, and the second electrode 170.

The hole transport layer 411, the buffer layer 420, and the electron transport layer 460 may each be located for the entirety of the light detection region and the emission region.

As such, the manufacturing process of the electronic apparatus 100 may be simplified by providing common layers for the organic photodetector 400 and the light-emitting device 500, existing functional layer materials used in the light-emitting device 500 can also be used for the organic photodetector 400, and thus, the organic photodetector 400 may be provided in-pixel in the electronic apparatus.

For example, an electron injection layer may be further included between the electron transport layer 460 and the counter electrode 470.

A capping layer may be on the counter electrode 470. A material that can be used for the capping layer may include an organic material and/or inorganic material as described above. The capping layer may facilitate efficient emission of light generated from the light-emitting device 500, in addition to having a protective function for the organic photodetector 400 and the light-emitting device 500.

An encapsulation portion 490 may be on the capping layer. The encapsulation portion 490 may be on the organic photodetector 400 and the light-emitting device 500 to protect the organic photodetector 400 and the light-emitting device 500 from moisture and/or oxygen. The encapsulation portion 490 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, and/or the like), an epoxy-based resin (for example, aliphatic glycidyl ether (AGE), and/or the like), or any combination thereof; or a combination of the inorganic film and the organic film.

The electronic apparatus 100 may be, for example, a display apparatus. The electronic apparatus 100 includes both the organic photodetector 400 and the light-emitting device 500, and thus, may be a display apparatus having a light detection function.

In FIG. 2, the electronic apparatus 100 is illustrated as including one light-emitting device 500, but, as shown in FIG. 3, an electronic apparatus 100a may include the organic photodetector 400, a first light-emitting device 501, a second light-emitting device 502, and a third light-emitting device 503.

Components illustrated in FIG. 3 may be understood by referring to the descriptions of the electronic apparatus 100.

The first light-emitting device 501 may include a 2-3 pixel electrode 511, a hole transport layer 411, an optical auxiliary layer 551, a first emission layer 541, a buffer layer 420, an electron transport layer 460, and a counter electrode 470.

The second light-emitting device 502 may include a 2-2 pixel electrode 512, a hole transport layer 411, an optical auxiliary layer 552, a second emission layer 542, a buffer layer 420, an electron transport layer 460, and a counter electrode 470.

The third light-emitting device 503 may include a 2-1 pixel electrode 513, a hole transport layer 411, an optical auxiliary layer 553, a third emission layer 543, a buffer layer 420, an electron transport layer 460, and a counter electrode 470.

The 2-3 pixel electrode 511, the 2-2 pixel electrode 512, and the 2-1 pixel electrode 513 may respectively be provided to correspond to a first emission region, a second emission region, and a third emission region, and may respectively be the same as described in connection with the first electrode 110 in the specification.

The first emission layer 541 is provided in correspondence with the first light emission region and emits a first color light, the second emission layer 542 is provided in correspondence with the second light emission region and emits a second color light, and the third emission layer 543 is provided in correspondence with the light emission region and emits a third color light.

A maximum emission wavelength of the first color light, a maximum emission wavelength of the second color light, and a maximum emission wavelength of the third color light may be identical to or different from each other. For example, the maximum emission wavelength of the first color light and the maximum emission wavelength of the second color light may each be greater than the maximum emission wavelength of the third color light.

In an embodiment, the first color light may be red light, the second color light may be green light, and the third color light may be blue light, but embodiments of the disclosure are not limited thereto. Accordingly, the electronic apparatus 100a is capable of full-color emission. The first color light, the second color light, and the third color light are not limited to red light, green light, and blue light, respectively, and may be any combination of light of different colors, as long as mixed light thereof is white light.

The organic photodetector 400, the first light-emitting device 501, the second light-emitting device 502, and the third light-emitting device 503 may be subpixels constituting a single pixel. For example, one pixel may include at least one organic photodetector 400.

The electronic apparatus 100a may be a display apparatus. The electronic apparatus 100a includes all the organic photodetector 400 and the first light-emitting device 501, the second light-emitting device 502, and the third light-emitting device 503, and thus, may be a full-color display apparatus having a light detection function.

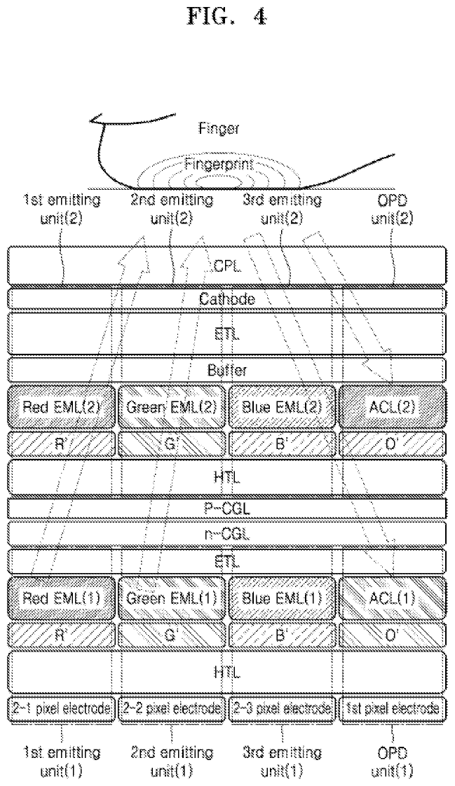

### Description of FIG. 4

FIG. 4 is a schematic cross-sectional view of an electronic apparatus according to an embodiment.

Fingerprint sensing by an organic photodetector may be performed by 1) sensing a fingerprint touch, 2) emitting light by a light-emitting device, and 3) sensing green light by the organic photodetector. In related arts, as only green light is used, there has been a limitation in sensing.

An electronic apparatus according to an aspect of embodiments of the disclosure may include:

a substrate including a light detection region and an emission region;

an organic photodetector on the light detection region; and

a light-emitting device on the emission region,

wherein the organic photodetector may include a first pixel electrode, a counter electrode facing the first pixel electrode, m organic light detection units including an active layer (ACL) between the first pixel electrode and the counter electrode, and m−1 charge generation layers between two adjacent organic light detection units among the m organic light detection units,

the light-emitting device may include a 2-1 pixel electrode, the counter electrode facing the 2-1 pixel electrode, m first emission units including an emission layer between the 2-1 pixel electrode and the counter electrode, and m−1 charge generation layers between two adjacent first emission units among the m first emission units,

a 2-2 pixel electrode, the counter electrode facing the 2-2 pixel electrode, m second emission units including an emission layer between the 2-2 pixel electrode and the counter electrode, and m−1 charge generation layers between two adjacent second emission units among the m second emission units,

a 2-3 pixel electrode, the counter electrode facing the 2-3 pixel electrode, m third emission units including an emission layer between the 2-3 pixel electrode and the counter electrode, and m−1 charge generation layers between two adjacent third emission units among the m third emission units, m may be an integer of 2 or more,

the m first emission units may emit first color light, the m second emission units may emit second color light, the m third emission units may emit third color light, the first to third color lights may have different colors from each other,

the m organic light detection units may absorb different colors of light from each other,

the first pixel electrode and the active layers may be provided in correspondence with the light detection region,

the 2-1 to 2-3 pixel electrodes and the emission layers may be provided in correspondence with the emission region, and

the m−1 charge generation layers and the counter electrode may be provided for the entirety of the light detection region and the emission region.

Components illustrated in FIG. 4 may be understood by referring to the descriptions of FIGS. 1 to 3.

In an electronic apparatus according to an embodiment of the disclosure, as a light-emitting device and an organic photodetector use a tandem structure, and organic light detection units included in the organic photodetector absorb different colors of light from each other, the electronic apparatus may have improved fingerprint sensing sensitivity.

The first pixel electrode, the 2-1 pixel electrode, and the 2-3 pixel electrode of FIG. 4 may be understood by referring to the description of the first electrode 110 provided in the specification. The cathode and the capping layer CPL of FIG. 4 may be understood by referring to the description of the second electrode 170 and the capping layer provided in the present specification.

In an embodiment, an organic photodetector from among the m organic light detection units may include a hole transport region between the first pixel electrode and the counter electrode.

In an embodiment, the organic photodetector may further include an electron transport region.

In an embodiment, an emission unit from among the m first emission units may include a hole transport region between the 2-1 pixel electrode and the counter electrode,

an emission unit from among the m second emission units may include a hole transport region between the 2-2 pixel electrode and the counter electrode, or

an emission unit from among the m third emission units may include a hole transport region between the 2-3 pixel electrode and the counter electrode.

In an embodiment, an emission unit from among the m first emission units, an emission unit from among the m second emission units, or an emission unit from among the m third emission units may further include an electron transport region.

In an embodiment, the hole transport region may further include a hole injection layer, a hole transport layer, an electron blocking layer, an auxiliary layer, or any combination thereof.

In an embodiment, the electron transport region may include a buffer layer, a hole blocking layer, an electron transport layer, an electron injection layer, or any combination thereof.

In an embodiment, the hole transport region may include the hole transport layer, and the hole transport layer may be provided for the entirety of the light detection region and the emission region.

In an embodiment, the electron transport region may include the buffer layer and/or the electron transport layer, and the buffer layer and/or the electron transport layer may be provided for the entirety of the light detection region and the emission region.

In an embodiment, the first to third color lights may each independently be any one selected from red light, green light, and blue light.

In an embodiment, m may be 2, and each of the two organic light detection units of the organic photodetector may absorb red light or green light, absorb red light or blue light, or absorb green light or blue light, or

m may be 3, and each of the three organic light detection units of the organic photodetector may absorb red light, green light, or blue light.

In an embodiment, the charge generation layer may include an n-type charge generation layer and a p-type charge generation layer.

In an embodiment, the active layer may include a layer including a p-type semiconductor compound and a layer including an n-type semiconductor compound.

Referring to FIG. 4, m may be 2,

the organic photodetector may include a first pixel electrode, a cathode facing the first pixel electrode, an organic light detection unit (1) including an active layer (1) between the first pixel electrode and the cathode, an organic light detection unit (2) including an active layer (2), and one charge generation layer between two adjacent organic light detection units from among the two organic light detection units. The charge generation layer may include an n-charge generation layer n-CGL and a p-charge generation layer p-CGL.

Referring to FIG. 4, the light-emitting device may include:

a 2-1 pixel electrode, a cathode facing the 2-1 pixel electrode, a first emission unit (1) including a red emission layer (1) between the 2-1 pixel electrode and the cathode, a first emission unit (2) including a red emission layer (2), and one charge generation layer between the two first emission units,

a 2-2 pixel electrode, a cathode facing the 2-2 pixel electrode, a second emission unit (1) including a green emission layer (1) between the 2-2 pixel electrode and the cathode, a second emission unit (2) including a green emission layer (2), and one charge generation layer between the two second emission units, and

a 2-3 pixel electrode, a cathode facing the 2-3 pixel electrode, a third emission unit (1) including a blue emission layer (1) between the 2-3 pixel electrode and the cathode, a third emission unit (2) including a blue emission layer (2), and one charge generation layer between the two third emission units, wherein the charge generation layer may include an n-charge generation layer and a p-charge generation layer.

The two first emission units may emit red light as a first color light, the two second emission units may emit green light as a second color light, and the two third emission units may emit blue light as a third color light.

Referring to FIG. 4, among the two organic light detection units, the organic light detection unit (2) close to the cathode may absorb green light, and the other organic light detection unit (1) may absorb red light.

Unlike FIG. 4, in some embodiments, among the two organic light detection units, the organic light detection unit (2) close to the cathode may absorb red light, and the other organic light detection unit (1) may absorb green light. Or, each organic light detection unit of the two organic light detection units may absorb red light or blue light or absorb green light or blue light.

In some embodiments, when m is 3, each organic light detection unit of the three organic light detection units may absorb red light, green light, or blue light.

Referring to FIG. 4, the hole transport layer, the electron transport layer, the buffer layer, and the capping layer may be provided as a common layer, and

An auxiliary layer R′ of the first emission unit (1), an auxiliary layer R′ of the first emission unit (2), an auxiliary layer G′ of the second emission unit (1), an auxiliary layer R′ of the second emission unit (2), an auxiliary layer B′ of the third emission unit (2), an auxiliary layer B′ of the third emission unit (2), an auxiliary layer O′ of the organic light detection unit (1), and an auxiliary layer O′ of the organic light detection unit (2) may be provided individually. In some cases, the auxiliary layer R′ of the first emission unit (1), the auxiliary layer R′ of the first emission unit (2), the auxiliary layer G′ of the second emission unit (1), the auxiliary layer R′ of the second emission unit (2), the auxiliary layer B′ of the third emission unit (2), the auxiliary layer B′ of the third emission unit (2), the auxiliary layer O′ of the organic light detection unit (1), and/or the auxiliary layer O′ of the organic light detection unit (2) may not be present.

FIG. 4 illustrates a case in which m is 2; however, other embodiments in which m is 3 to 5 may be illustrated in the same manner.

### First Electrode 110

In FIG. 1, a substrate may be under the first electrode 110 and/or on the second electrode 170. As the substrate, a glass substrate and/or a plastic substrate may be used. In one or more embodiments, the substrate may be a flexible substrate, and may include plastics (e.g., polymers) having excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing and/or sputtering a material for forming the first electrode 110 on the substrate. When the first electrode 110 is an anode, the material for forming the first electrode 110 may be a high-work function material.

The first electrode 110 may be a reflective electrode, a semi-transmissive electrode, or a transmissive electrode. When the first electrode 110 is a transmissive electrode, indium tin oxide (ITO), indium zinc oxide (IZO), tin oxide (SnO₂), zinc oxide (ZnO), or any combination thereof may be used as a material for forming the first electrode 110. In one or more embodiments, when the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combinations thereof may be used as a material for forming the first electrode 110.

The first electrode 110 may have a single-layered structure consisting of a single layer or a multi-layered structure including a plurality of layers. For example, the first electrode 110 may have a three-layered structure of ITO/Ag/ITO.

### Hole Transport Region

In an embodiment, the charge auxiliary layers between the 2-1 pixel electrode, the 2-2 pixel electrode, the 2-3 pixel electrode, and the first pixel electrode and the red emission layer (1), the green emission layer (1), the blue emission layer (1), and the active layer (1); and between the charge generation layer and the red emission layer (2), the green emission layer (2), the blue emission layer (2), and the active layer (2) of FIG. 4 may be collectively referred to as a hole transport region.

The hole transport region may include a hole injection layer, a hole transport layer, an auxiliary layer, an electron blocking layer, or any combination thereof.

The hole transport region may include a hole transport material. For example, the hole transport material may include a compound represented by Formula 201, a compound represented by Formula 202, or any combination thereof:

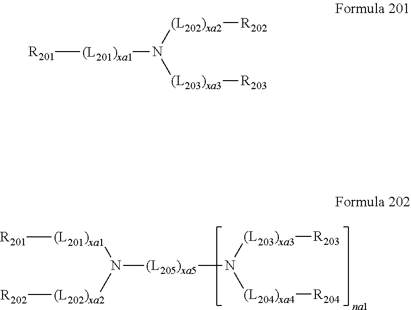

wherein, in Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and Q₂₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,

R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group or the like) unsubstituted or substituted with at least one R₁₀ₐ (for example, Compound HT16),

R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and

na1 may be an integer from 1 to 4.

For example, each of Formulae 201 and 202 may include at least one selected from groups represented by Formulae CY201 to CY217:

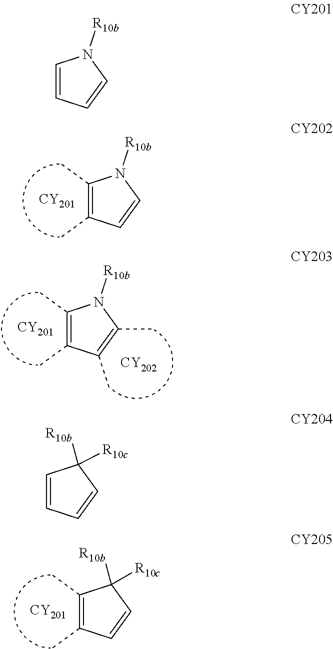

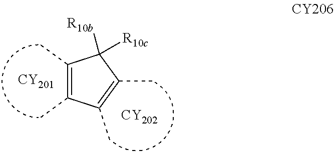

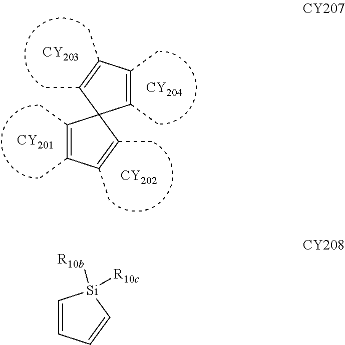

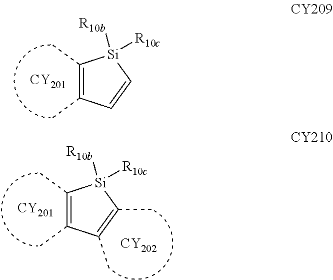

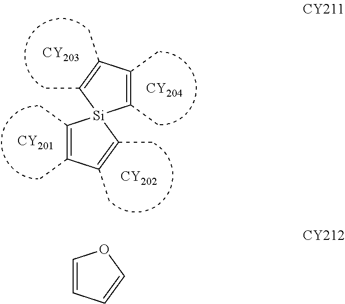

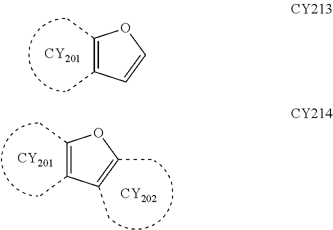

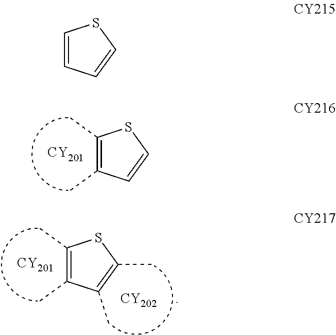

In Formulae CY201 to CY217, R_{10b} and R_{10c} may each be the same as described with respect to R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described above.

In an embodiment, ring CY201 to ring CY204 in Formulae CY201 to CY217 may each independently be a benzene group, a naphthalene group, a phenanthrene group, or an anthracene group.

In one or more embodiments, each of Formulae 201 and 202 may include at least one of groups represented by Formulae CY201 to CY203.

In one or more embodiments, Formula 201 may include at least one of the groups represented by Formulae CY201 to CY203 and at least one of the groups represented by Formulae CY204 to CY217.

In one or more embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include a group represented by one of Formulae CY201 to CY203.

In one or more embodiments, each of Formulae 201 and 202 may not include a group represented by one of Formulae CY201 to CY203, and may include at least one of the groups represented by Formulae CY204 to CY217.

In one or more embodiments, each of Formulae 201 and 202 may not include a group represented by one of Formulae CY201 to CY217.

For example, the hole transport material may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

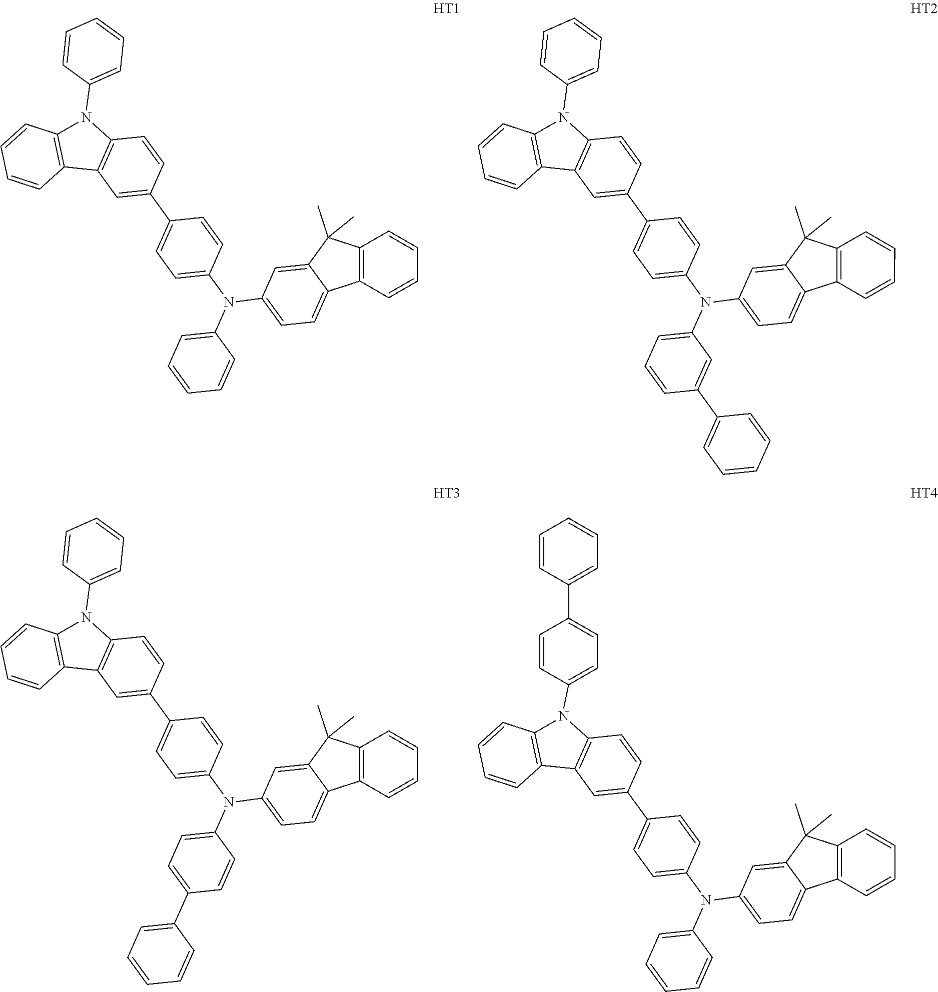 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

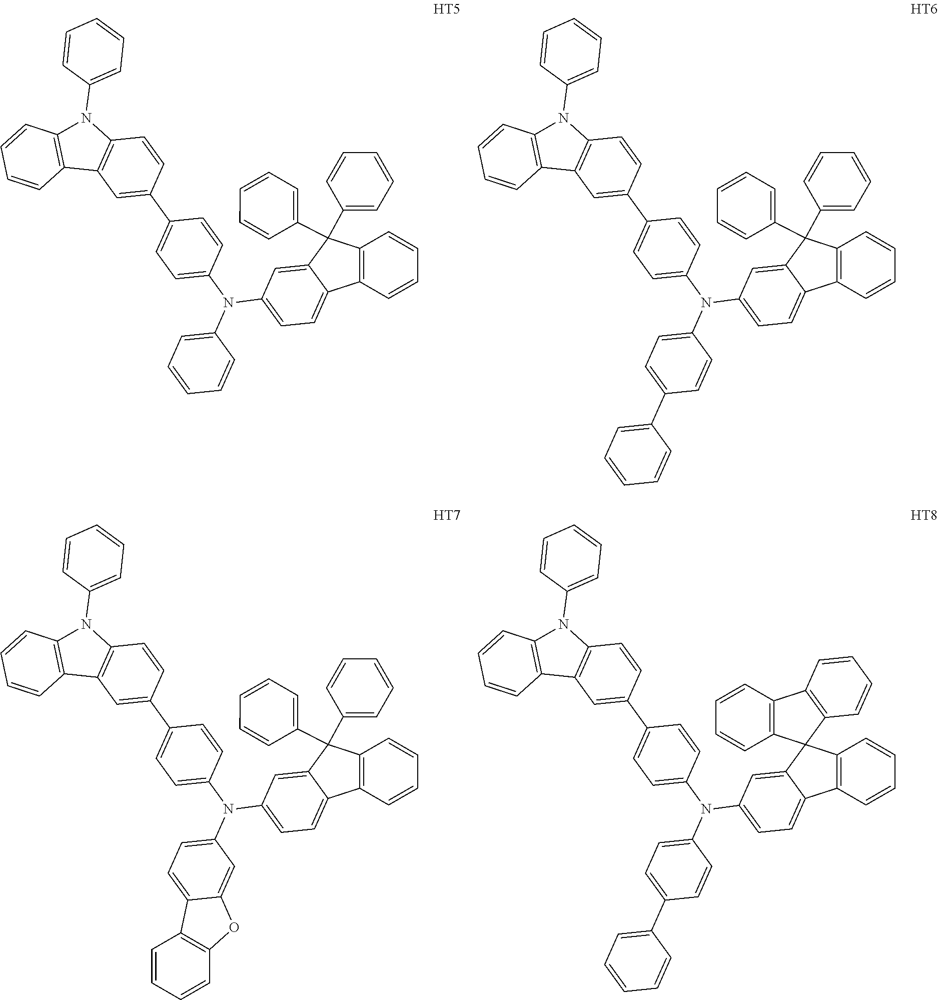 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

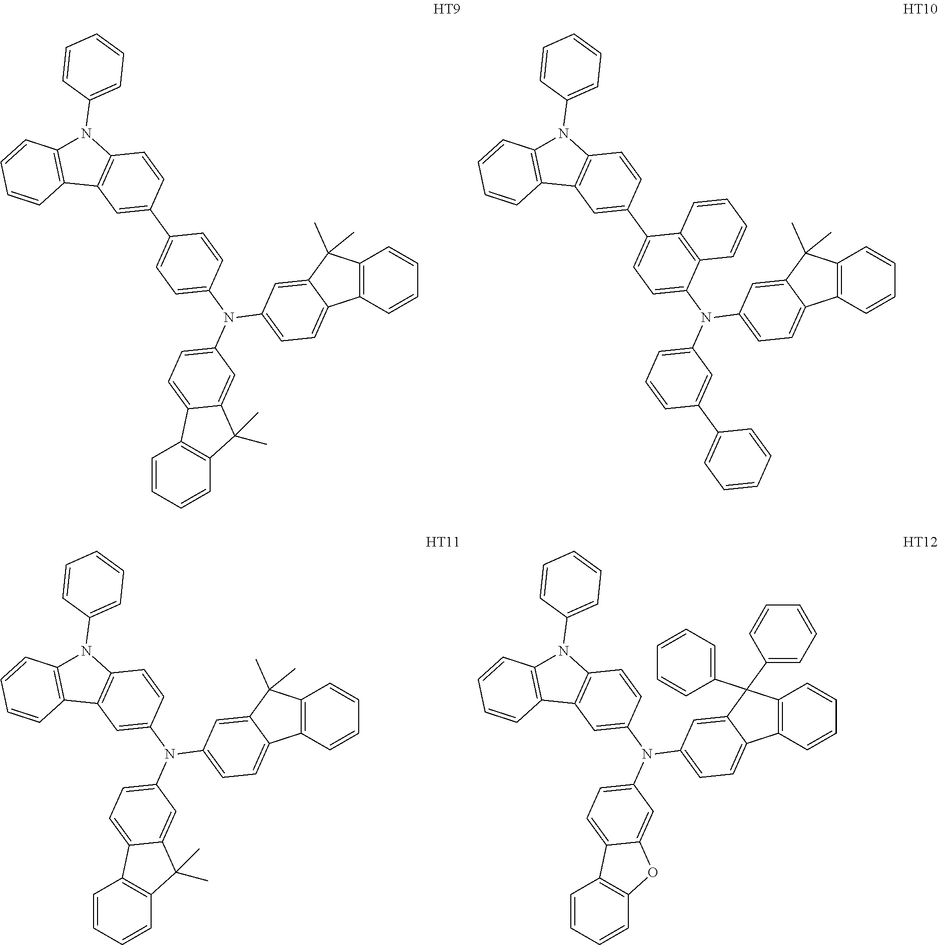

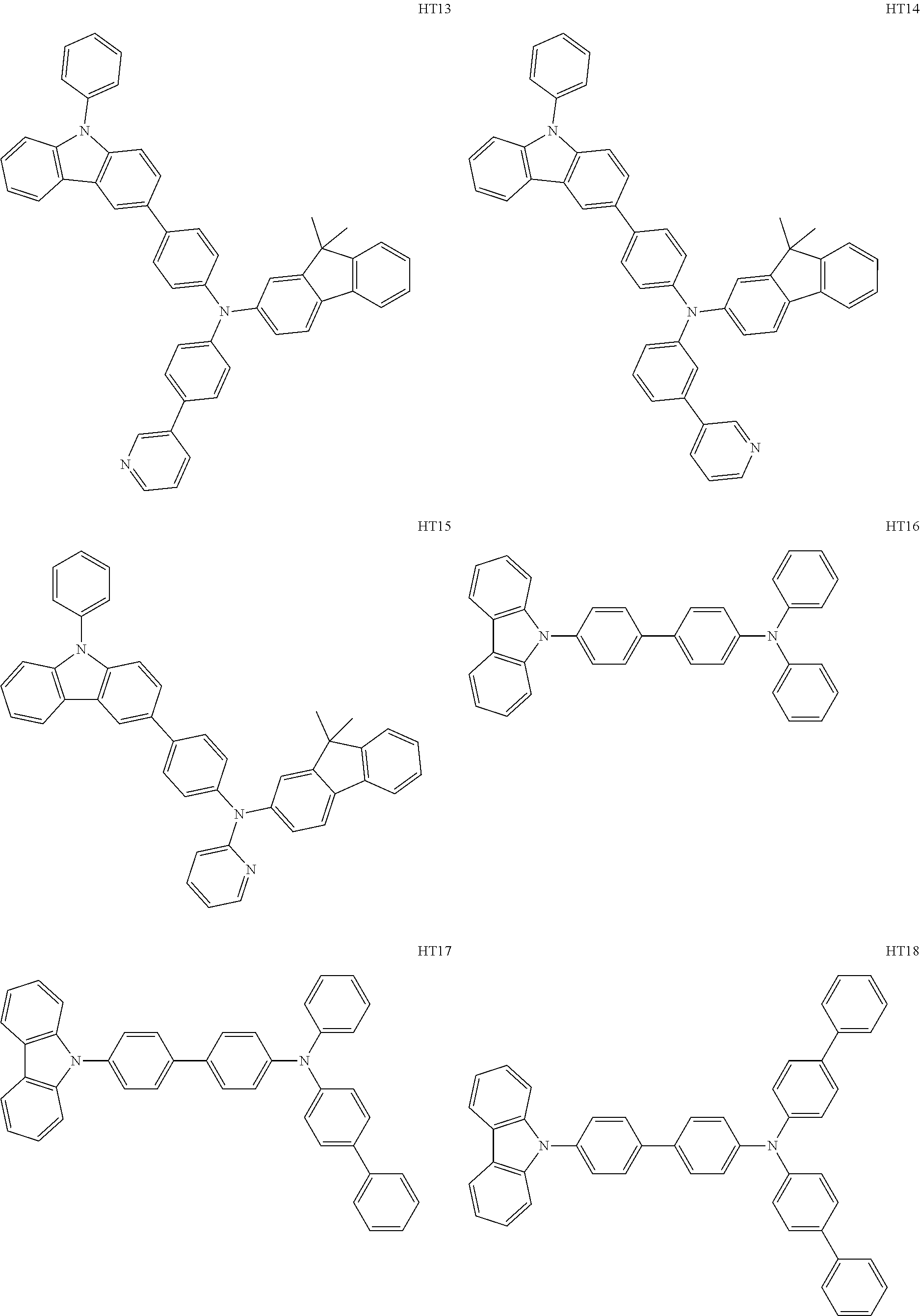 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

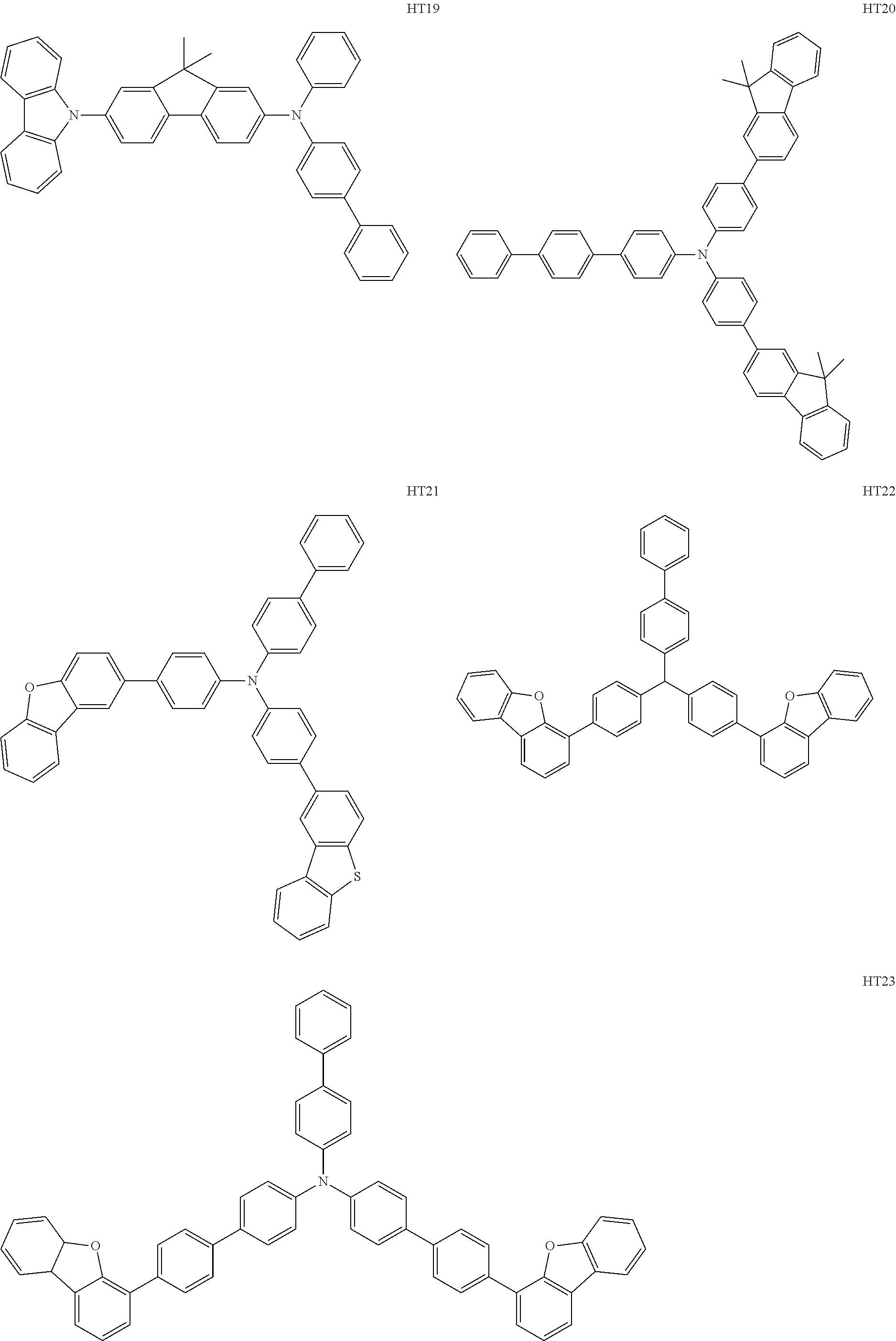 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(C(c3ccc(-c4cccc5c4oc4ccccc45)cc3)c3ccc(-c4cccc5c4oc4ccccc45)cc3)cc2)cc1 ; C1=CC2Oc3c(-c4ccc(-c5ccc(N(c6ccc(-c7ccccc7)cc6)c6ccc(-c7ccc(-c8cccc9c8oc8ccccc89)cc7)cc6)cc5)cc4)cccc3C2C=C1]

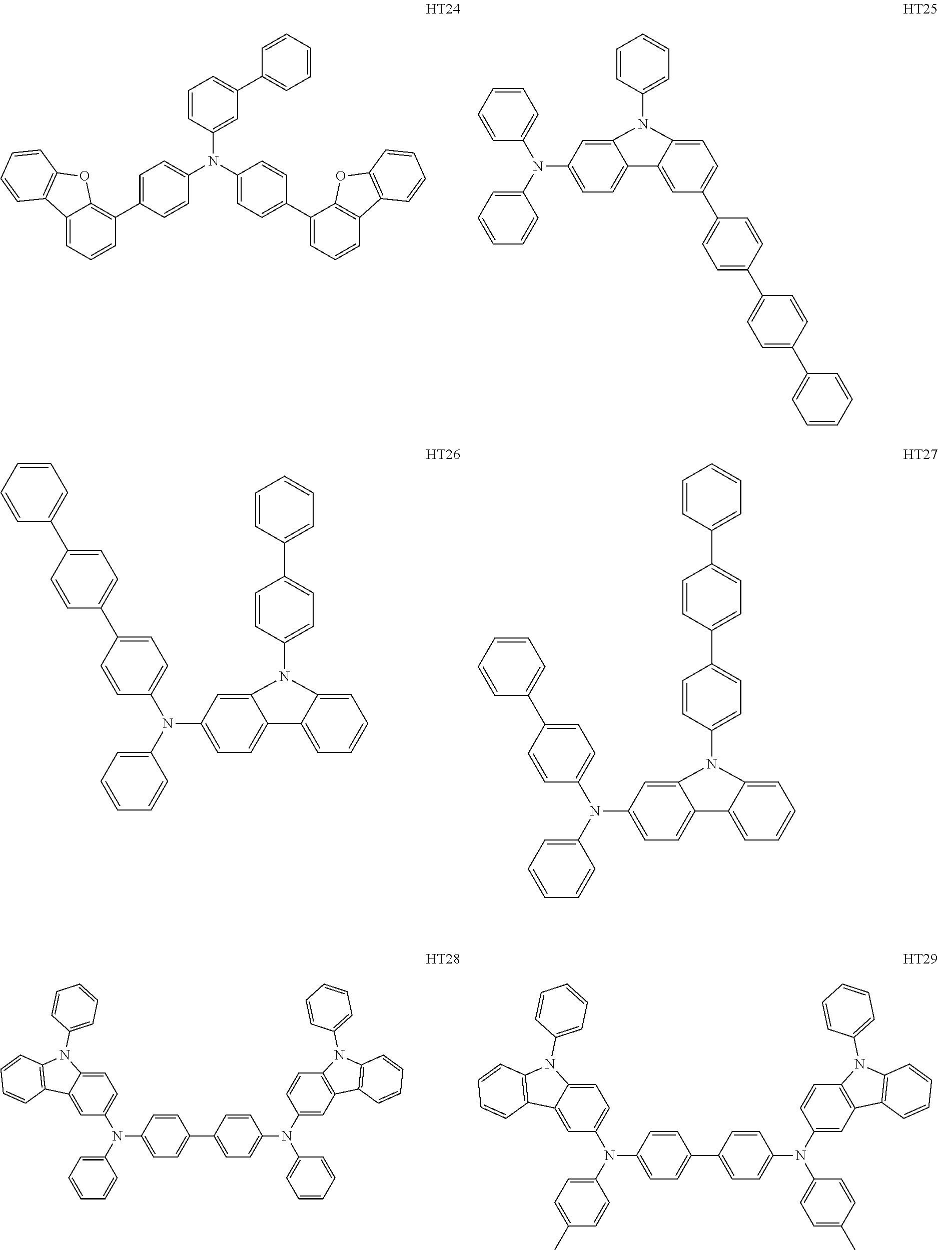

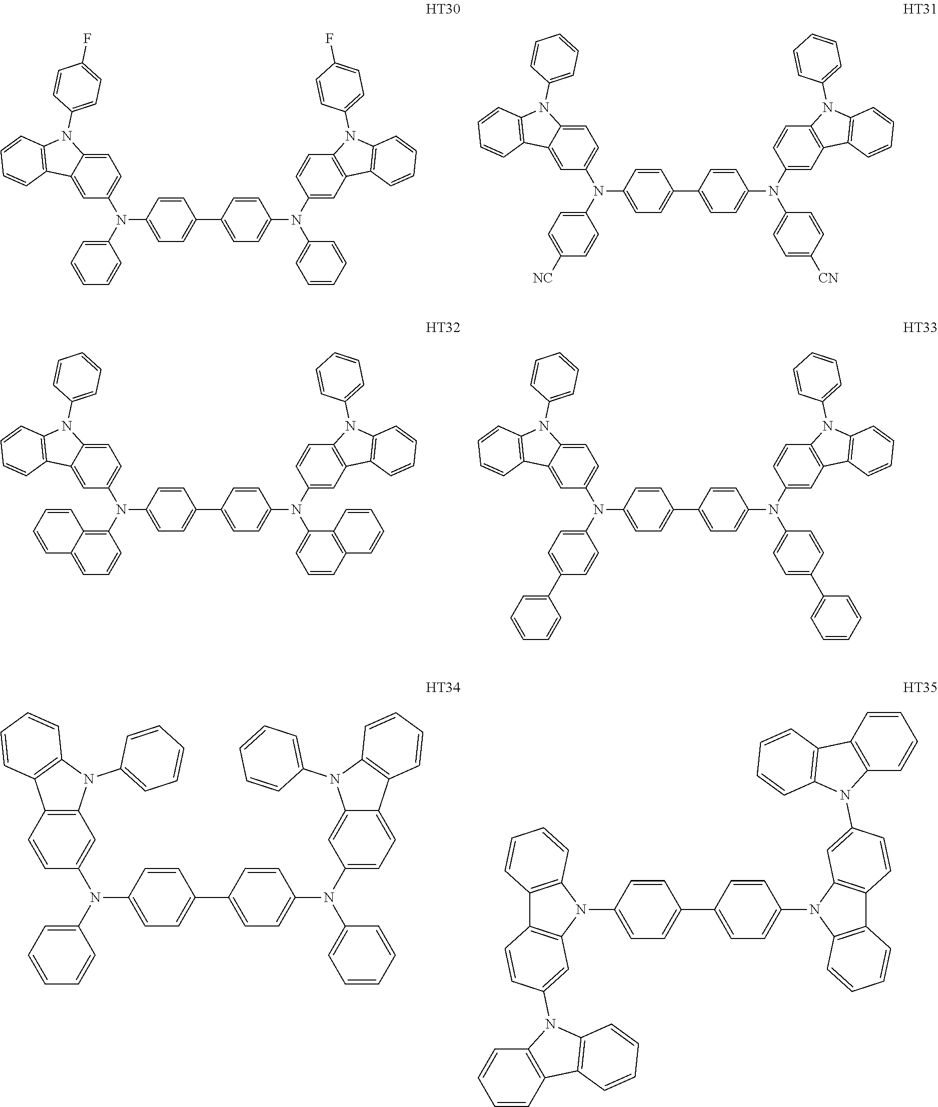

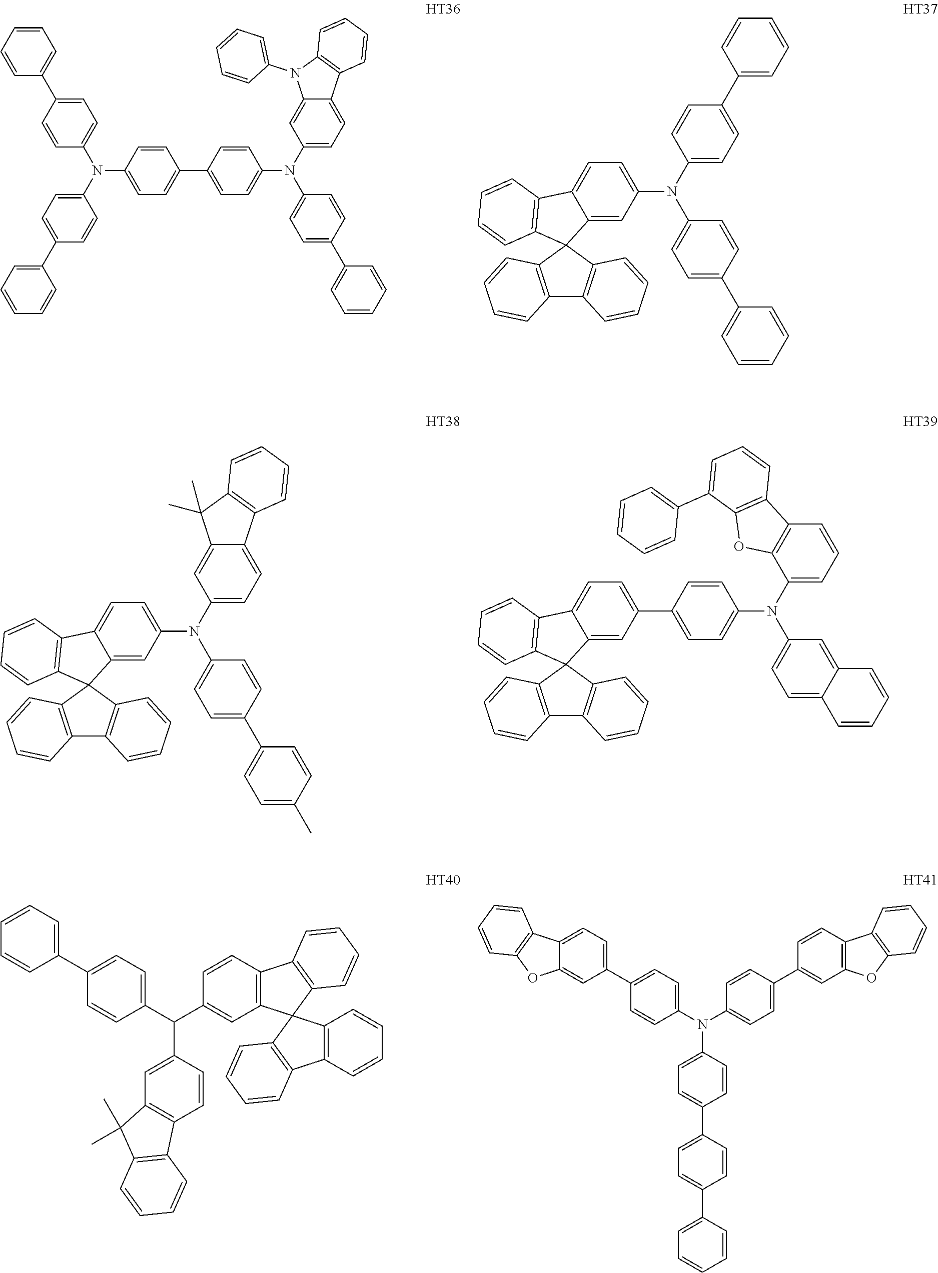

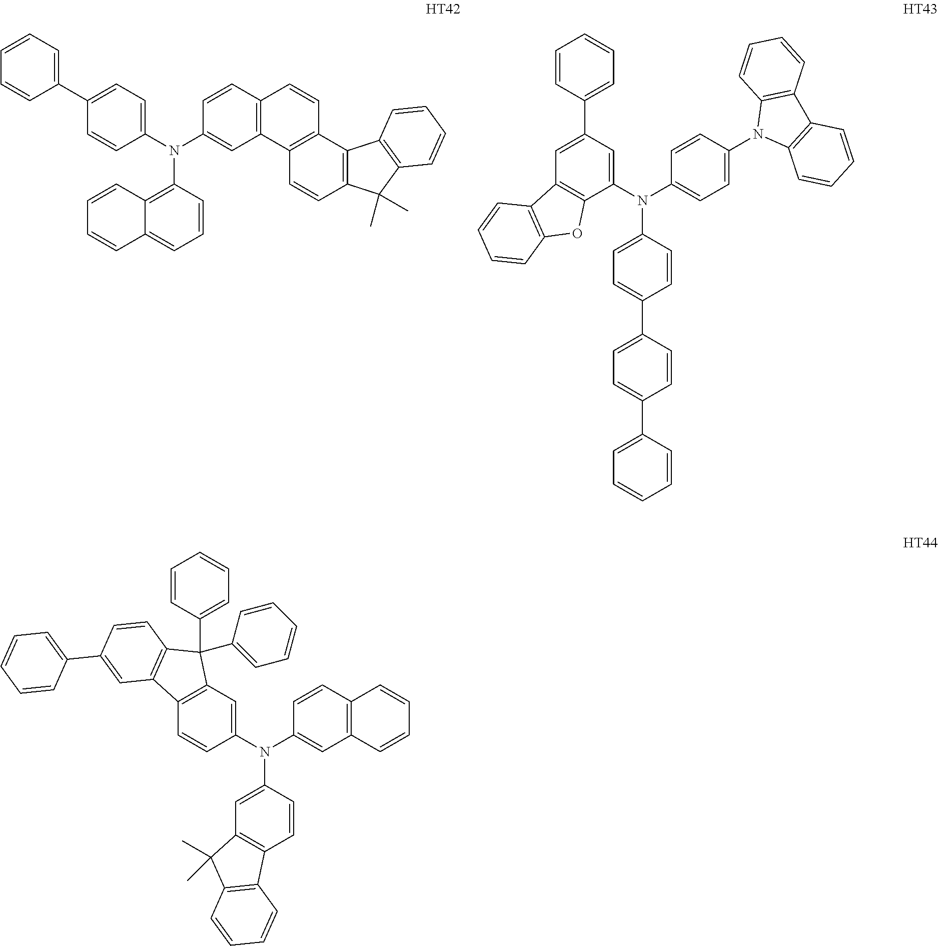 [SMILES: CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21]

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, suitable or satisfactory hole transporting characteristics may be obtained without a substantial increase in driving voltage.

The auxiliary layer may increase light introduction efficiency by compensating for an optical resonance distance according to a wavelength of light introduced to the red emission layer (1), the green emission layer (1), the blue emission layer (1), the active layer (1), the red emission layer (2), the green emission layer (2), the blue emission layer (2), and the active layer (2). The electron blocking layer may block or reduce the leakage of electrons from the red emission layer (2), the green emission layer (1), the blue emission layer (1), the active layer (1), the red emission layer (2), the green emission layer (2), the blue emission layer (2), and the active layer (2) to the hole transport region. The hole transporting material may be included in the auxiliary layer and the electron blocking layer.

### Electron Transport Region

In an embodiment, the charge auxiliary layers between the charge generation layer and the red emission layer (1), the green emission layer (1), the blue emission layer (1), and the active layer (1); and between the cathode (counter electrode) and the red emission layer (2), the green emission layer (2), the blue emission layer (2), and the active layer (2) of FIG. 4 may be collectively referred to as an electron transport region.

The electron transport region may have: i) a single-layered structure consisting of a single layer consisting of a single material, ii) a single-layered structure consisting of a single layer consisting of a plurality of different materials, or iii) a multi-layered structure including a plurality of layers including different materials.

The electron transport region may include a buffer layer, a hole blocking layer, an electron transport layer, an electron injection layer, or any combination thereof.

The electron transport region (for example, the buffer layer, the hole blocking layer, or the electron transport layer in the electron transport region) may include a metal-free compound including at least one IT electron-deficient nitrogen-containing C₁-C₆₀ cyclic group.

For example, the electron transport region may include a compound represented by Formula 601 below:

[Ar₆₀₁]ₓₑ₁₁-[(L₆₀₁)ₓₑ₁-R₆₀₁]ₓₑ₂₁ Formula 601

wherein, in Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may each be the same as described herein with respect to Q₁,

xe21 may be 1, 2, 3, 4, or 5, and

at least one of Ar₆₀₁, L₆₀₁, and R₆₀₁ may each independently be a IT electron-deficient nitrogen-containing C₁-C₆₀ cyclic group unsubstituted or substituted with at least one R₁₀ₐ.

For example, when xe11 in Formula 601 is 2 or more, two or more of Ar₆₀₁(s) may be linked to each other via a single bond.

In other embodiments, Ar₆₀₁ in Formula 601 may be a substituted or unsubstituted anthracene group.

In other embodiments, the electron transport region may include a compound represented by Formula 601-1:

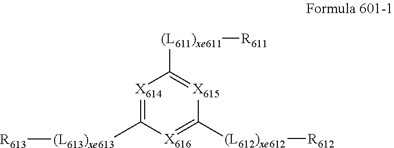

wherein, in Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,

L₆₁₁ to L₆₁₃ may each be the same as described herein with respect to L₆₀₁, xe611 to xe613 may each be the same as described herein with respect to xe1,

R₆₁₁ to R₆₁₃ may each be the same as described herein with respect to R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, Balq, TAZ, NTAZ, or any combination thereof:

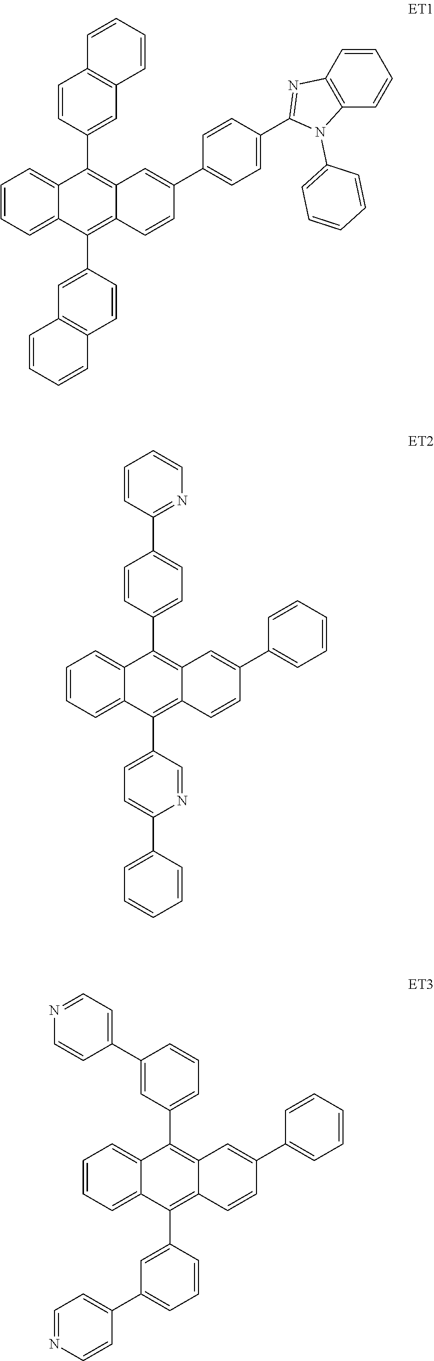 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccc5)nc4)c4ccccc4c(-c4ccc(-c5ccccn5)cc4)c3c2)cc1 ; c1ccc(-c2ccc3c(-c4cccc(-c5ccncc5)c4)c4ccccc4c(-c4cccc(-c5ccncc5)c4)c3c2)cc1]

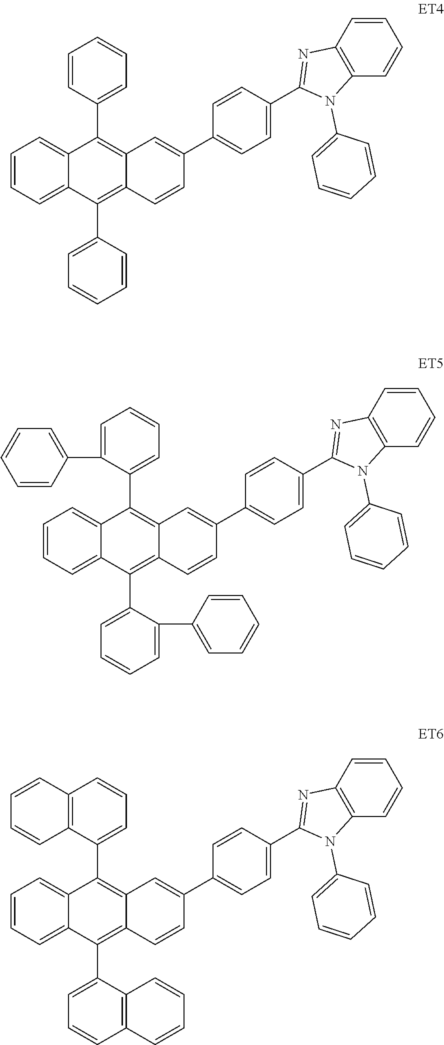 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

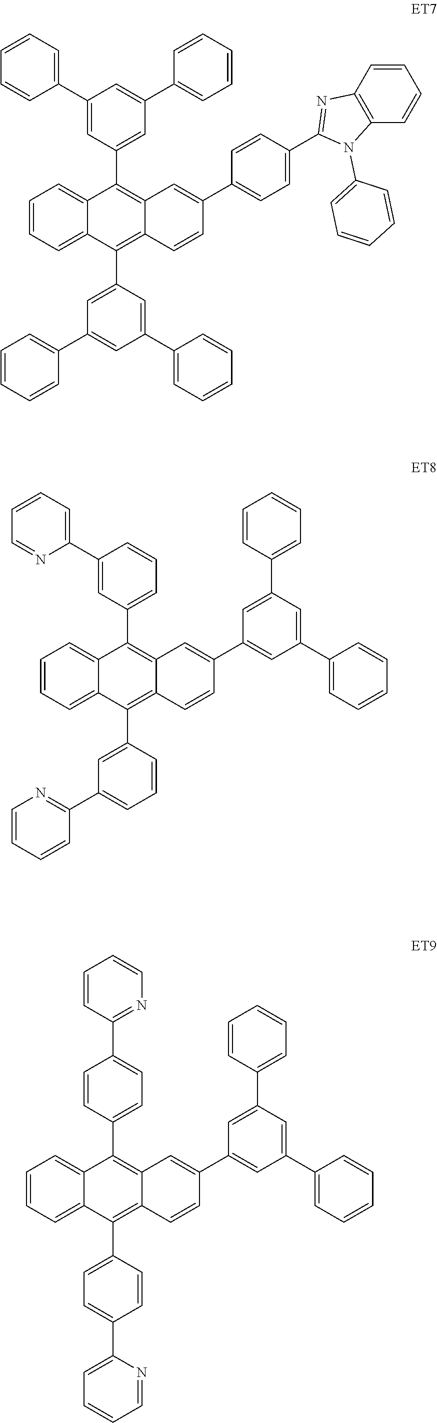 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

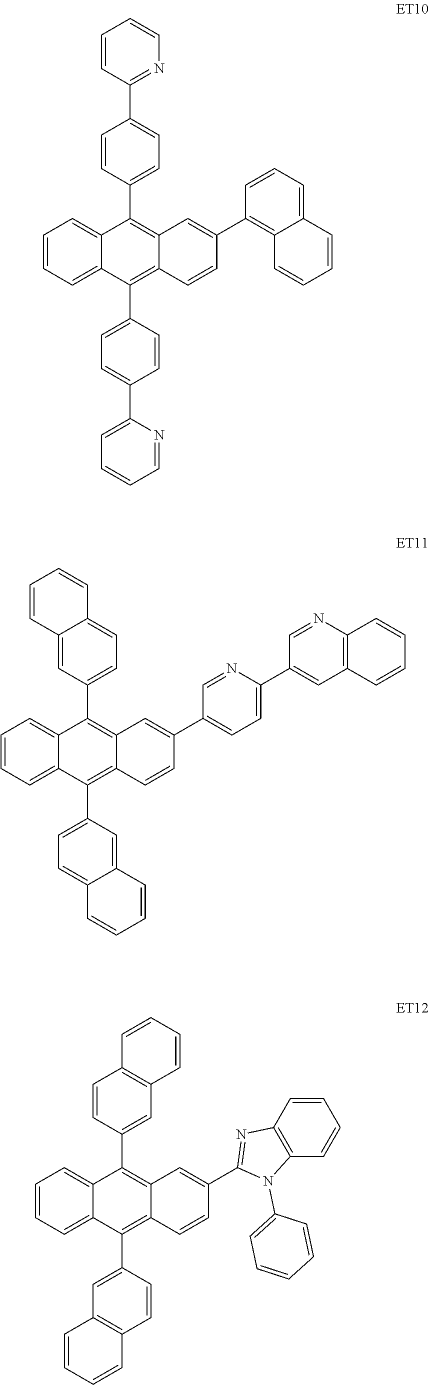 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

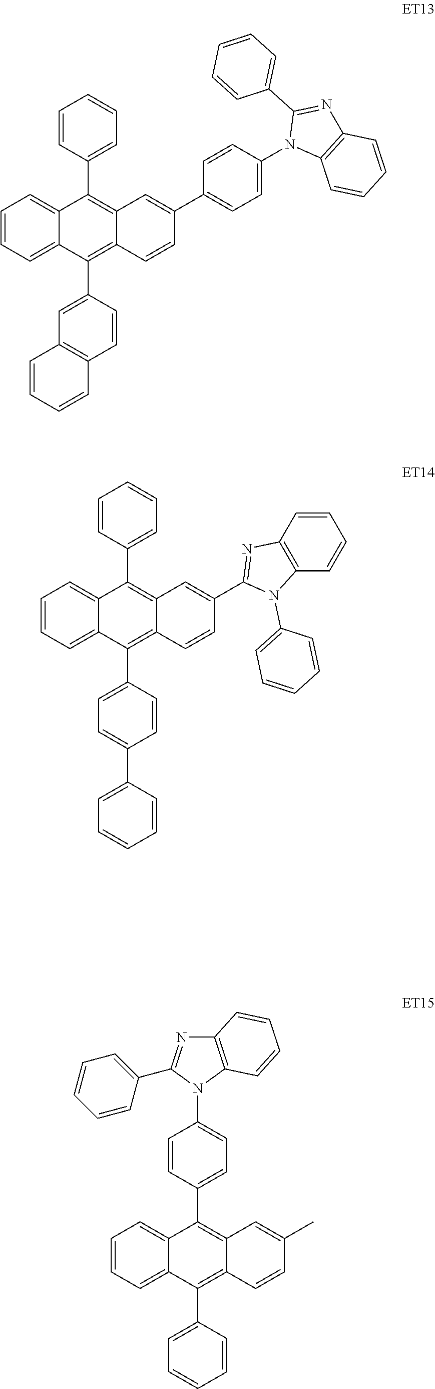 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

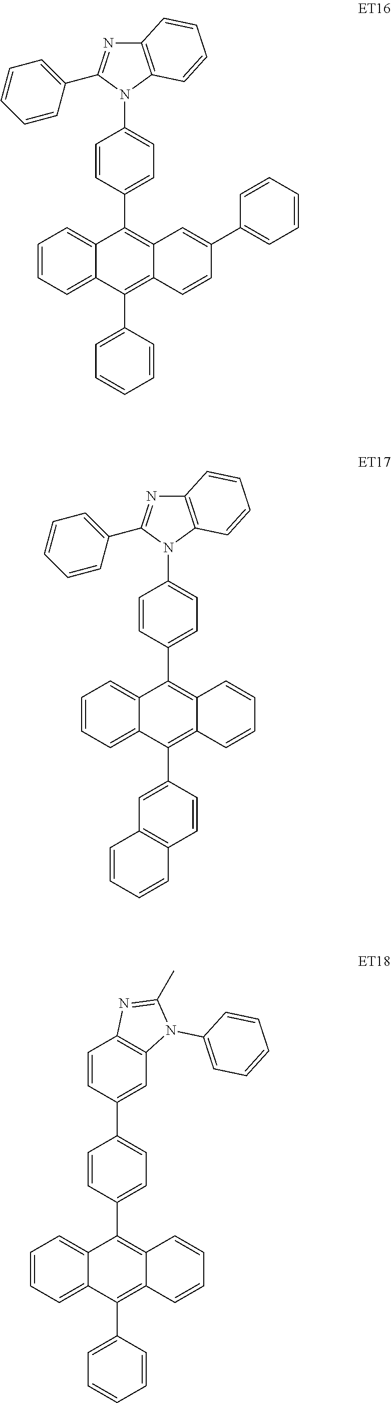 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

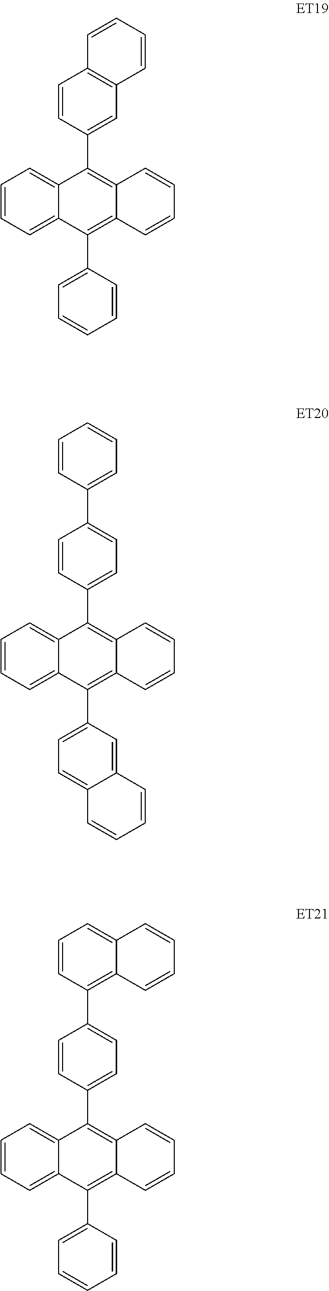

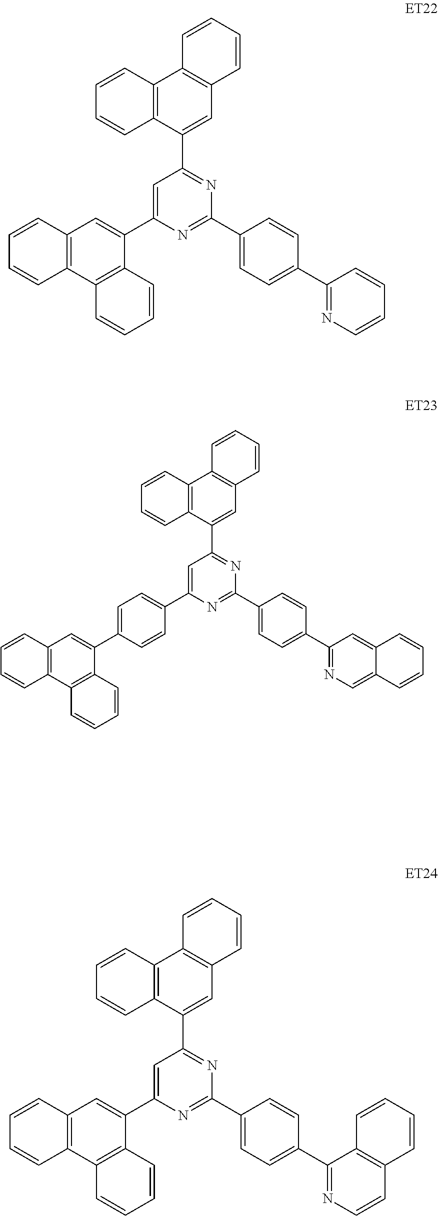 [SMILES: c1ccc(-c2ccc(-c3nc(-c4cc5ccccc5c5ccccc45)cc(-c4cc5ccccc5c5ccccc45)n3)cc2)nc1 ; c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1]

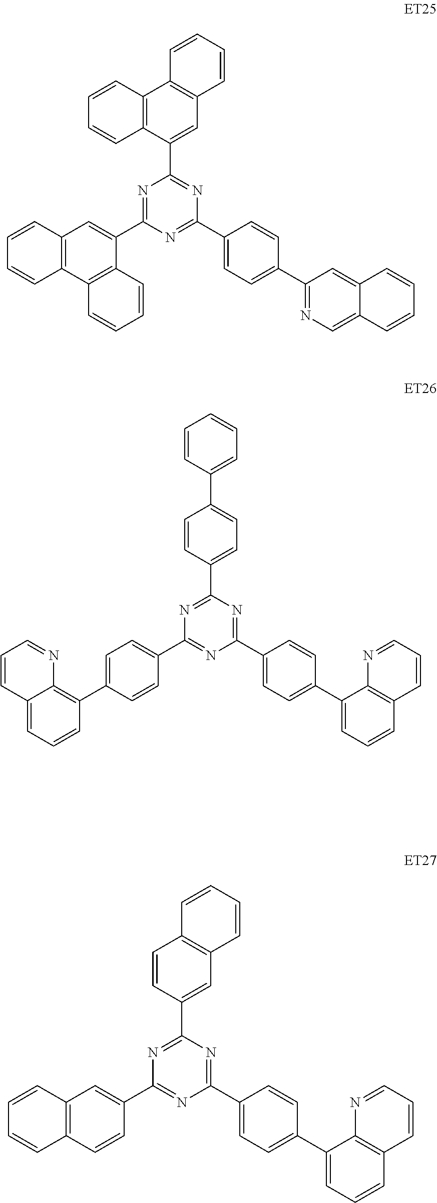 [SMILES: c1ccc2cc(-c3ccc(-c4nc(-c5cc6ccccc6c6ccccc56)nc(-c5cc6ccccc6c6ccccc56)n4)cc3)ncc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

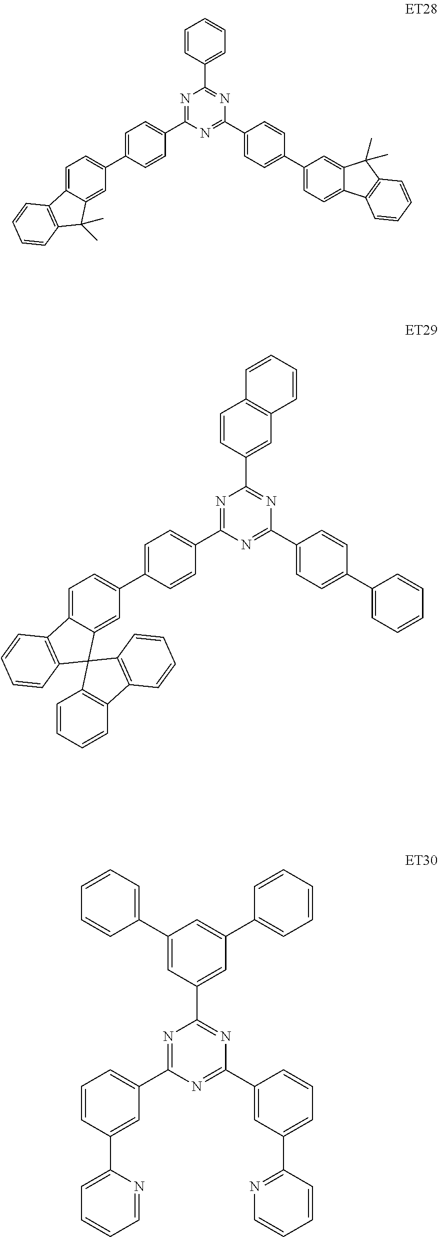 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

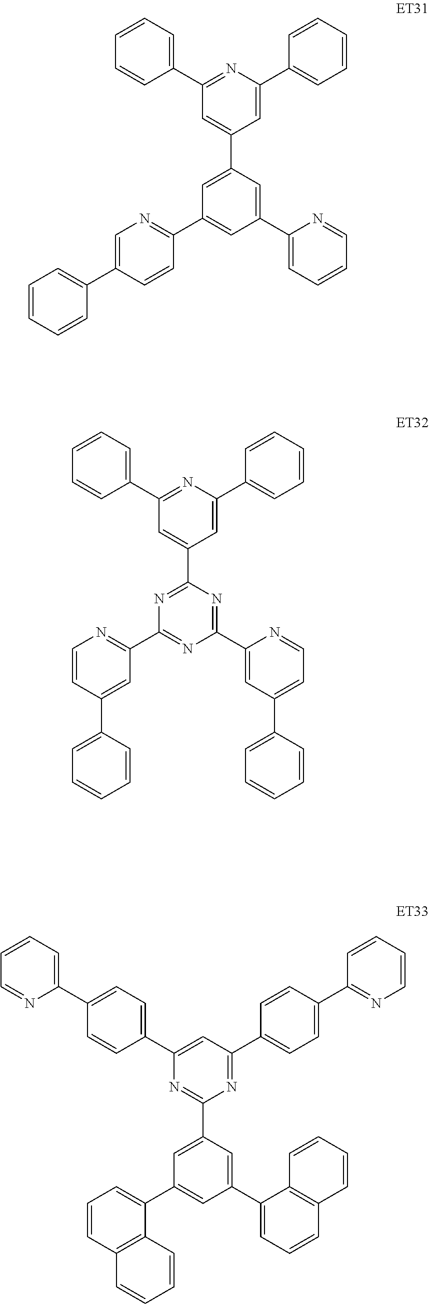 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3nc(-c4cc(-c5ccccc5)nc(-c5ccccc5)c4)nc(-c4cc(-c5ccccc5)ccn4)n3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

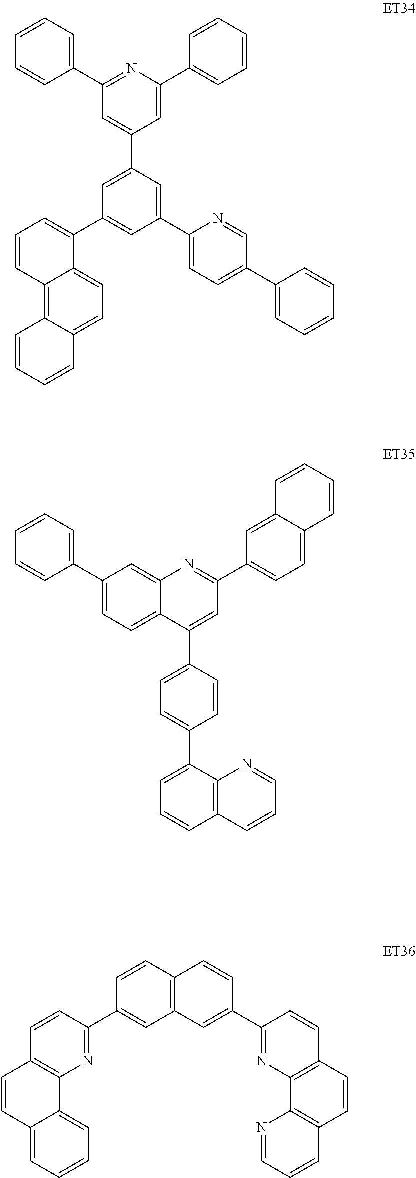 [SMILES: c1ccc(-c2ccc(-c3cc(-c4cc(-c5ccccc5)nc(-c5ccccc5)c4)cc(-c4cccc5c4ccc4ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1ccc2c(c1)ccc1ccc(-c3ccc4ccc(-c5ccc6ccc7cccnc7c6n5)cc4c3)nc12]

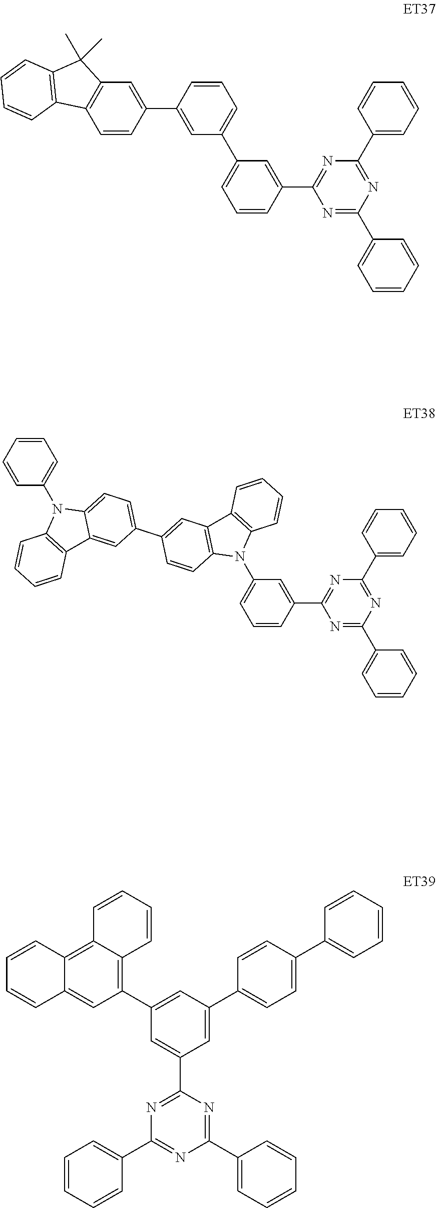 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1]

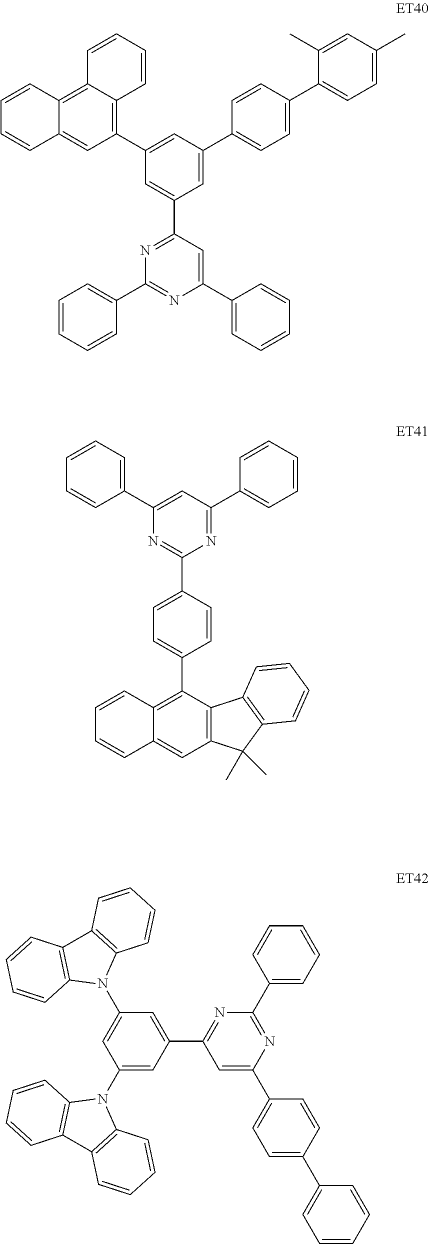 [SMILES: Cc1ccc(-c2ccc(-c3cc(-c4cc(-c5ccccc5)nc(-c5ccccc5)n4)cc(-c4cc5ccccc5c5ccccc45)c3)cc2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

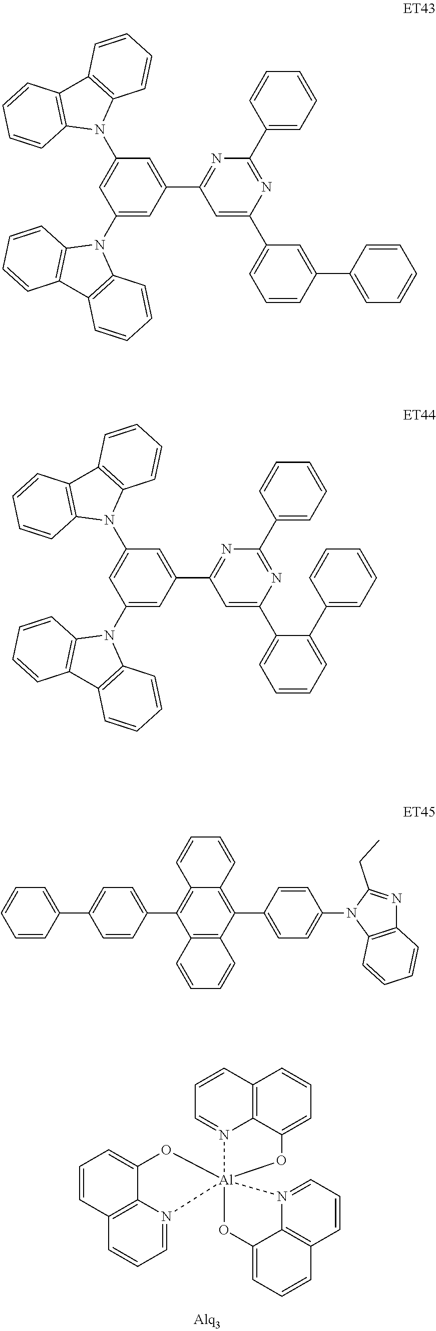

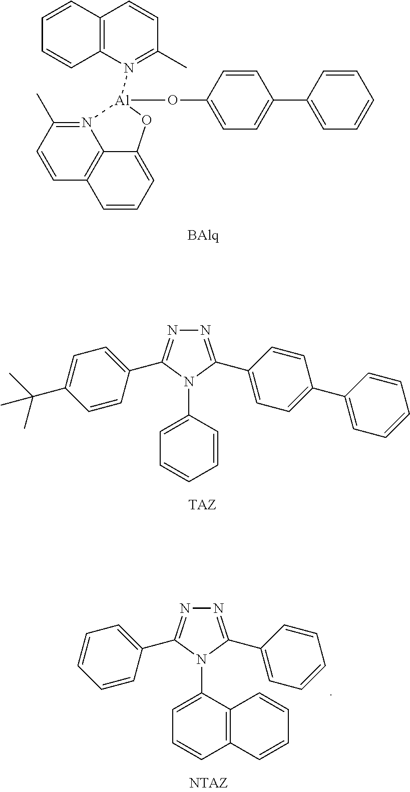

A thickness of the electron transport region may be from about 50 Å to about 5,000 Å, for example, from about 100 Å to about 4,000 Å. When the electron transport region includes a buffer layer, a hole blocking layer, an electron transport layer, or any combination thereof, the buffer layer and the hole blocking layer may each independently have a thickness of about 20 Å to about 1,000 Å, for example, about 30 Å to about 300 Å, and the electron transport layer may have a thickness of about 100 Å to about 1,000 Å, for example, about 150 Å to about 500 Å. When the thicknesses of the buffer layer, the hole blocking layer and/or the electron transport layer are within these ranges, suitable or satisfactory electron transport characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. The metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) and/or ET-D2:

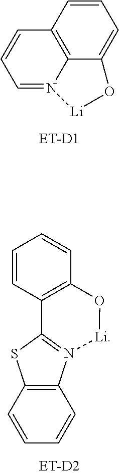

The electron transport region may include an electron injection layer that facilitates the injection of electrons. The electron injection layer may be in direct contact with the cathode, which is the counter electrode.

The electron injection layer may have: i) a single-layered structure consisting of a single layer consisting of a single material, ii) a single-layered structure consisting of a single layer consisting of a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (for example, fluorides, chlorides, bromides, or iodides), or tellurides of the alkali metal, the alkaline earth metal, and the rare earth metal, or any combination thereof.

The alkali metal-containing compound may include: alkali metal oxides, such as Li₂O, Cs₂O, and/or K₂O; alkali metal halides, such as LiF, NaF, CsF, KF, LiI, NaI, CsI, and/or KI; or any combination thereof. The alkaline earth metal-containing compound may include an alkaline earth metal compound, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include lanthanide metal telluride. Examples of the lanthanide metal telluride are LaTe, CeTe, PrTe, NdTe, PmTe, SmTe, EuTe, GdTe, TbTe, DyTe, HoTe, ErTe, TmTe, YbTe, LuTe, La₂Te₃, Ce₂Tes, Pr₂Te₃, Nd₂Te₃, Pm₂Te₃, Sm₂Te₃, Eu₂Te₃, Gd₂Te₃, Tb₂Te₃, Dy₂Te₃, HO₂Te₃, Er₂Tes, Tm₂Te₃, Yb₂Te₃, and Lu₂Te₃.

The alkali metal complex, the alkaline earth-metal complex, and the rare earth metal complex may include i) one of ions of the alkali metal, the alkaline earth metal, and the rare earth metal and ii), as a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

The electron injection layer may include or consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

In one or more embodiments, the electron injection layer may include or consist of: i) an alkali metal-containing compound (for example, an alkali metal halide); or ii) a) an alkali metal-containing compound (for example, an alkali metal halide), and b) an alkali metal, an alkaline earth metal, a rare earth metal, or any combination thereof. For example, the electron injection layer may be a KI:Yb co-deposited layer, an RbI:Yb co-deposited layer, and/or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

A thickness of the electron injection layer may be in a range of about 1 Å to about 100 Å, and, for example, about 3 Å to about 90 Å. When the thickness of the electron injection layer is within the ranges described above, suitable or satisfactory electron injection characteristics may be obtained without a substantial increase in driving voltage.

### Emission Layer

The emission layer may include a host and a dopant. The dopant may include a phosphorescent dopant, a fluorescent dopant, or any combination thereof.

The amount of the dopant in the emission layer may be from about 0.01 part by weight to about 15 parts by weight based on 100 parts by weight of the host.

In one or more embodiments, the emission layer may include a quantum dot.

In some embodiments, the emission layer may include a delayed fluorescence material. The delayed fluorescence material may act as a host or a dopant in the emission layer.

A thickness of the emission layer may be in a range of about 100 Å to about 1,000 Å, for example, about 200 Å to about 600 Å. When the thickness of the emission layer is within these ranges, excellent light-emission characteristics may be obtained without a substantial increase in driving voltage.

### Host

In one or more embodiments, the host may include a compound represented by Formula 301:

[Ar₃₀₁]_{xb11}-[(L₃₀₁)_{xb1}-R₃₀₁]_{xb21} Formula 301

wherein, in Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xb11 may be 1, 2, or 3,

xb1 may be an integer from 0 to 5,

R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),

xb21 may be an integer from 1 to 5, and

Q₃₀₁ to Q₃₀₃ are each the same as described herein with respect to Q₁.

For example, when xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or any combination thereof:

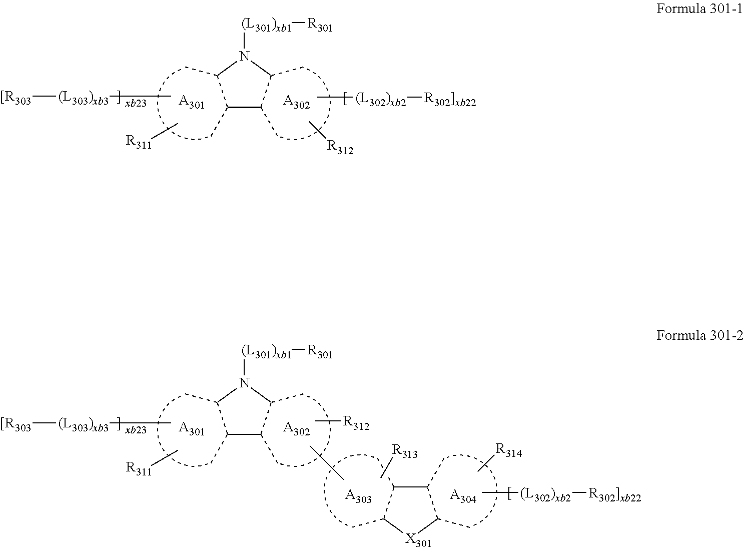

wherein, in Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

X₃₀₁ may be O, S, N-[(L₃₀₄) xb4-R₃₀₄], C(R₃₀₄) (R₃₀₅), or Si(R₃₀₄) (R₃₀₅), xb22 and xb23 may each independently be 0, 1, or 2,

L₃₀₁, xb1, and R₃₀₁ may each be the same as described herein,

L₃₀₂ to L₃₀₄ may each independently be the same as described herein with respect to with L₃₀₁,

xb2 to xb4 may each independently be the same as described herein with respect to xb1, and

R₃₀₂ to R₃₀₅ and R₃₁₁ to R₃₁₄ may each be the same as described herein with respect to R₃₀₁.

In one or more embodiments, the host may include an alkali earth metal complex, a post-transition metal complex, or any combination thereof. For example, the host may include a Be complex (for example, Compound H55), an Mg complex, a Zn complex, or any combination thereof.

In one or more embodiments, the host may include one of Compounds H1 to H128, 9,10-di(2-naphthyl)anthracene (ADN), 2-methyl-9,10-bis(naphthalen-2-yl) anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

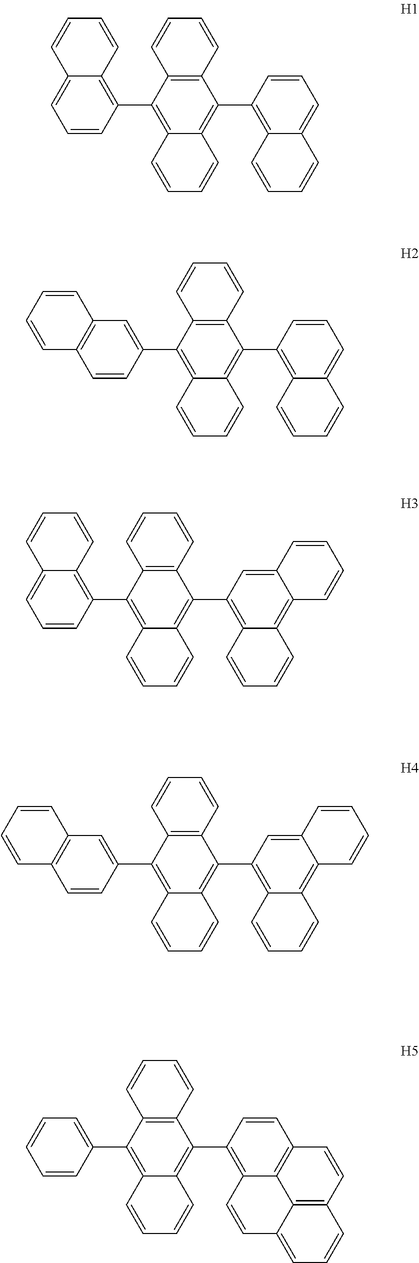

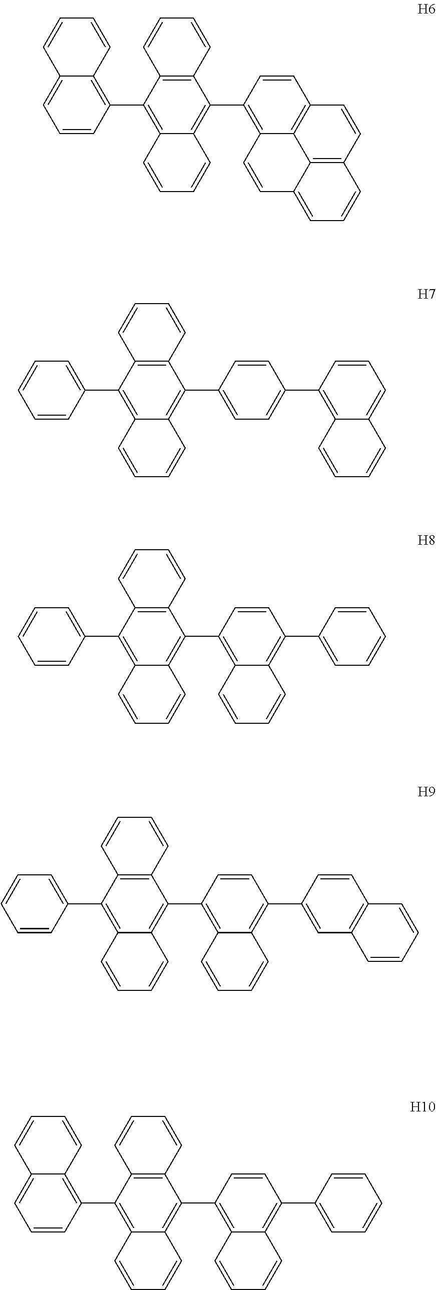

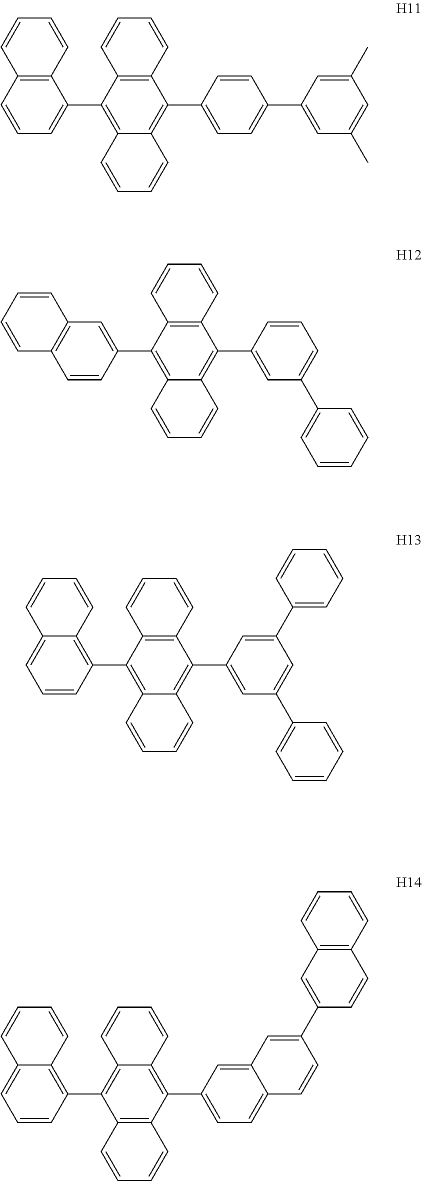

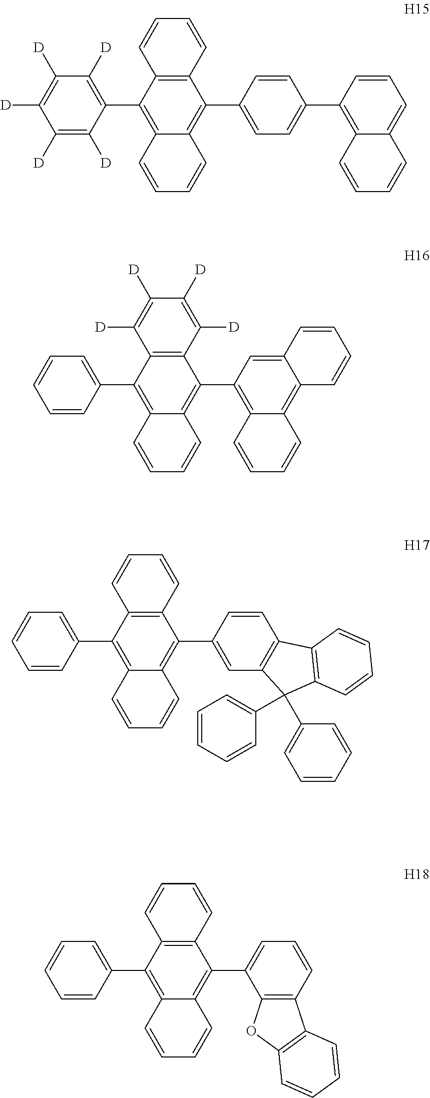

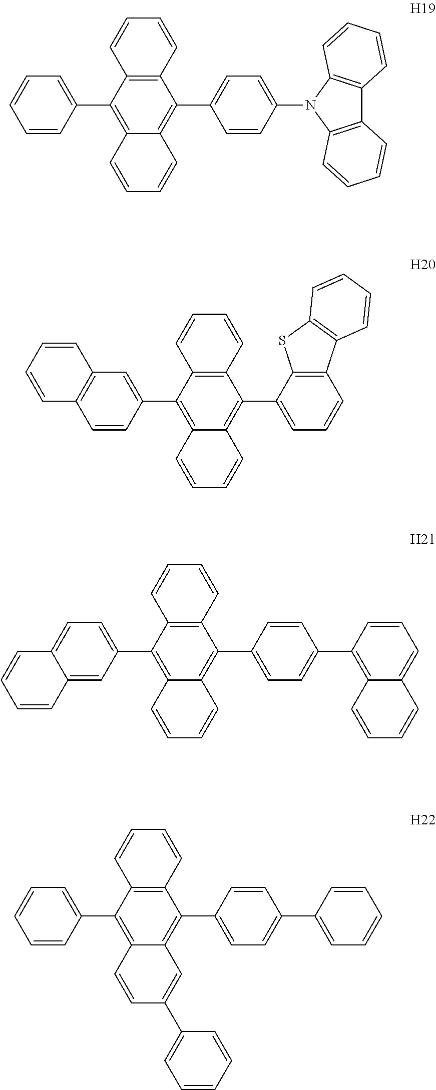

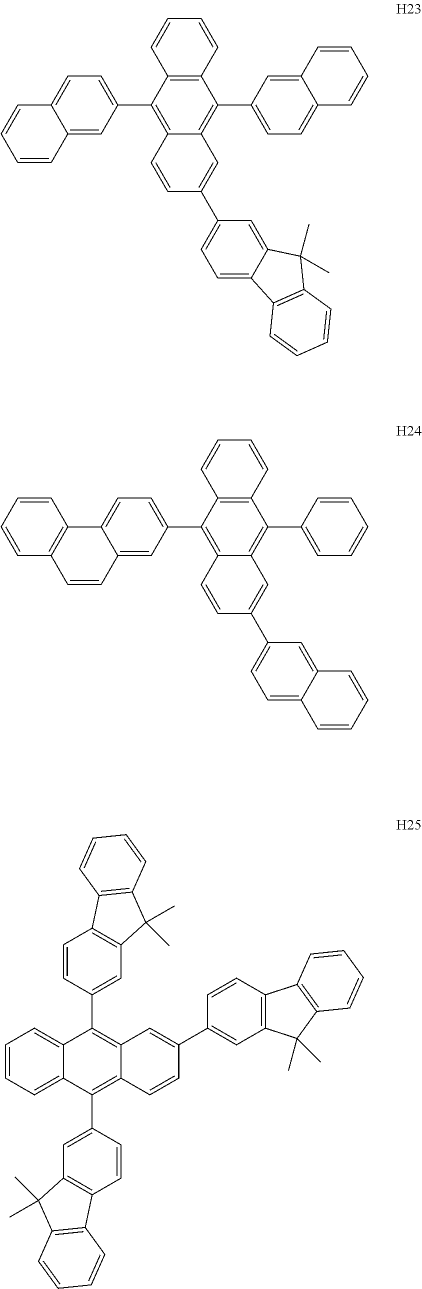

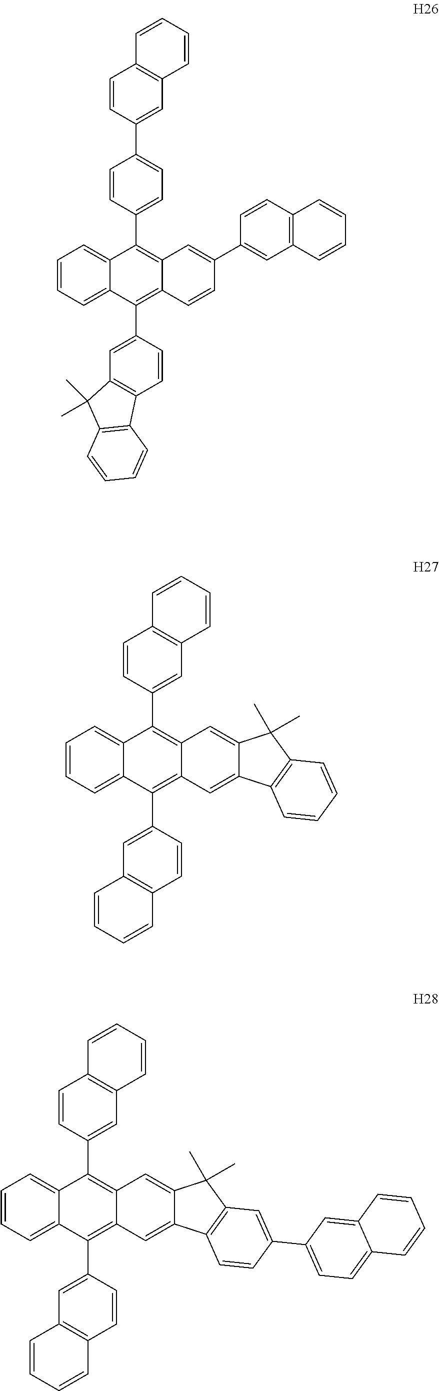

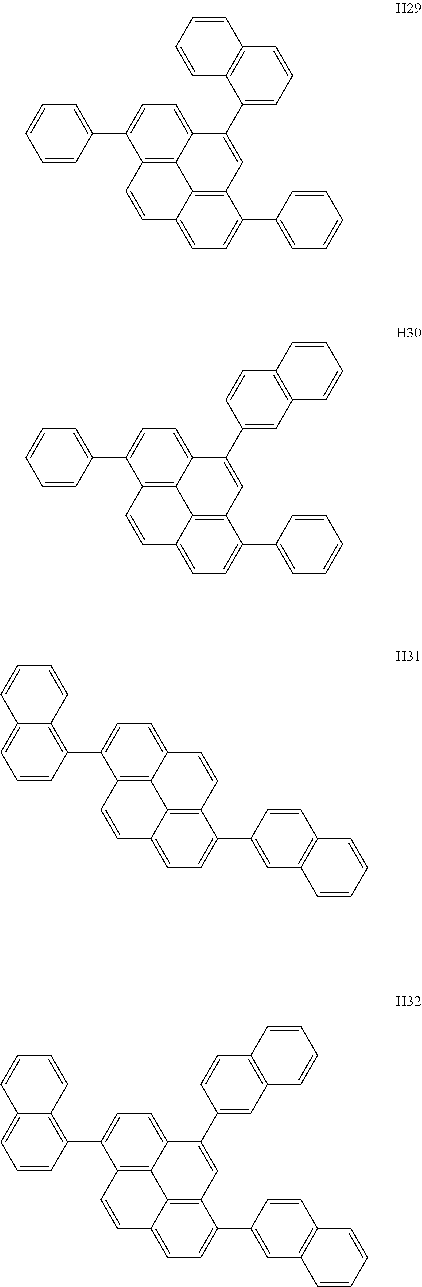

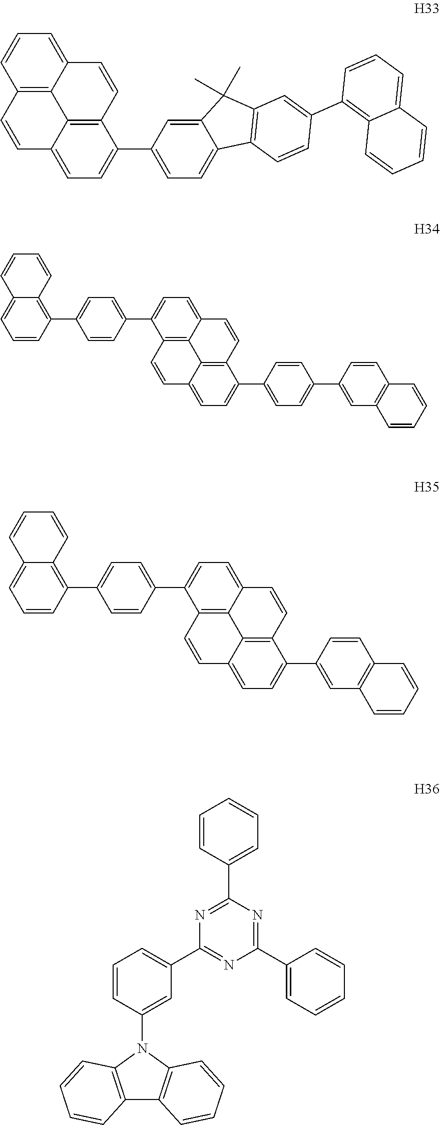

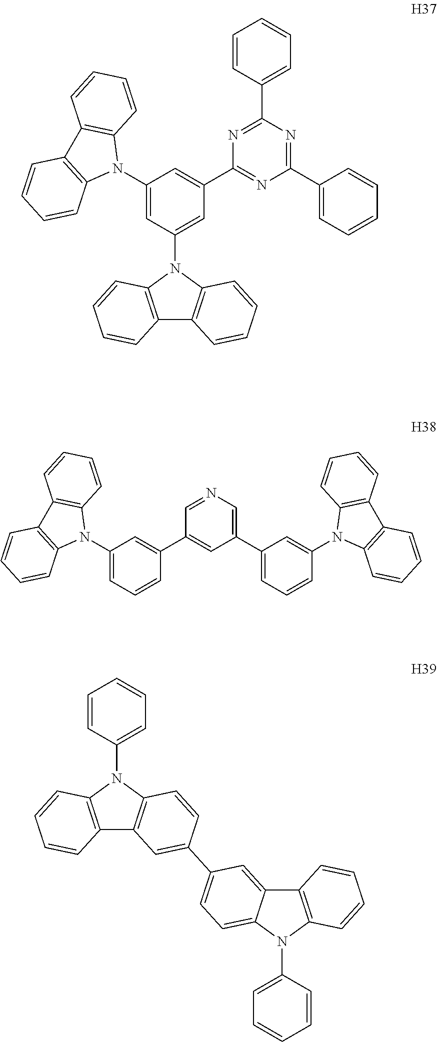 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

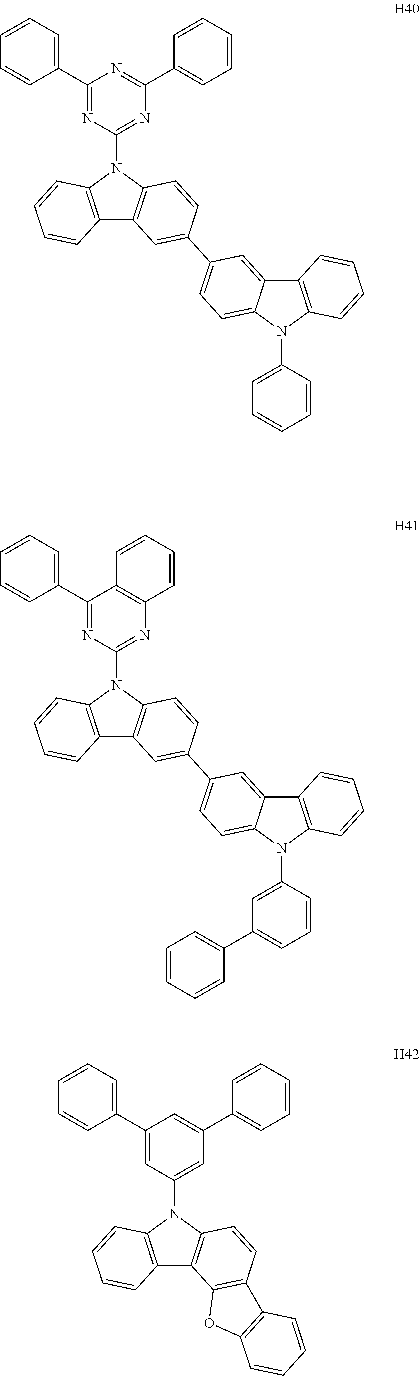 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

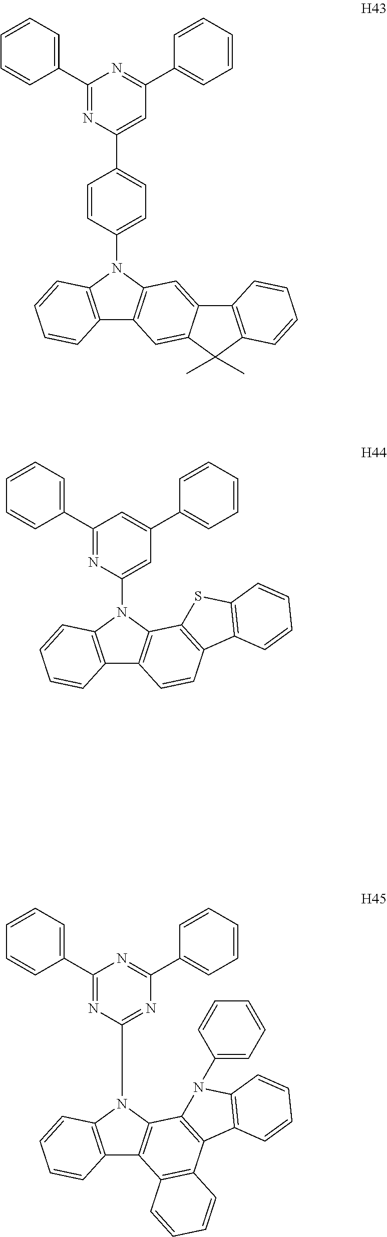 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1]

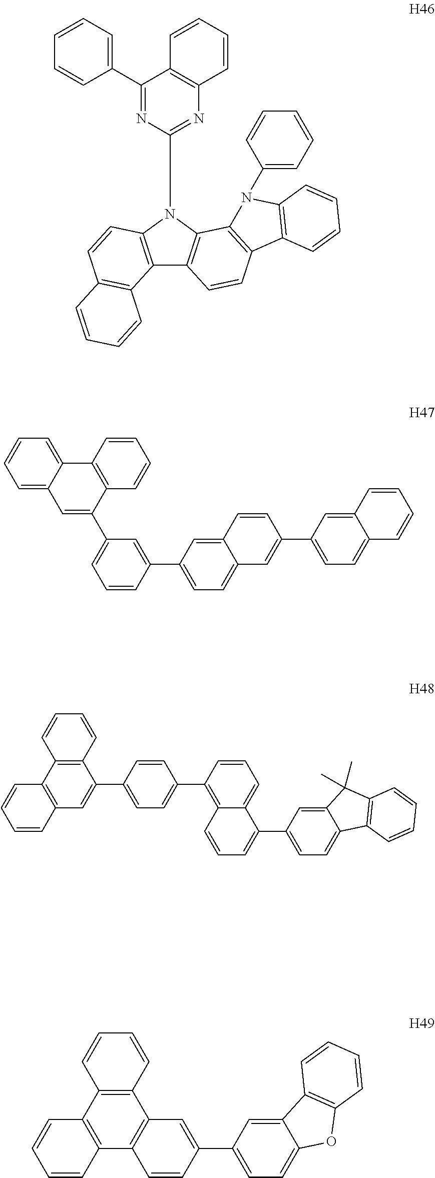

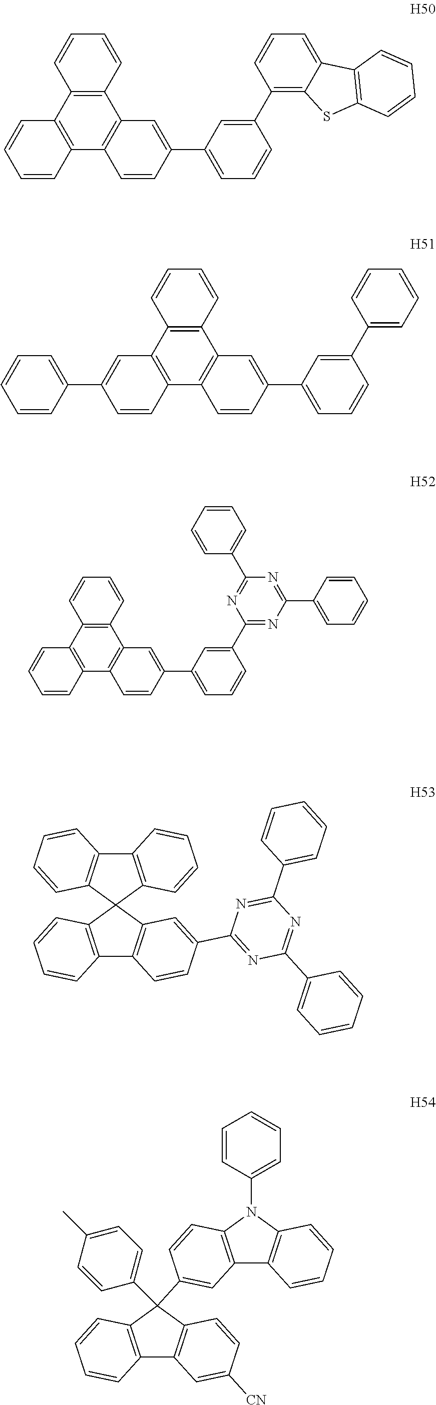

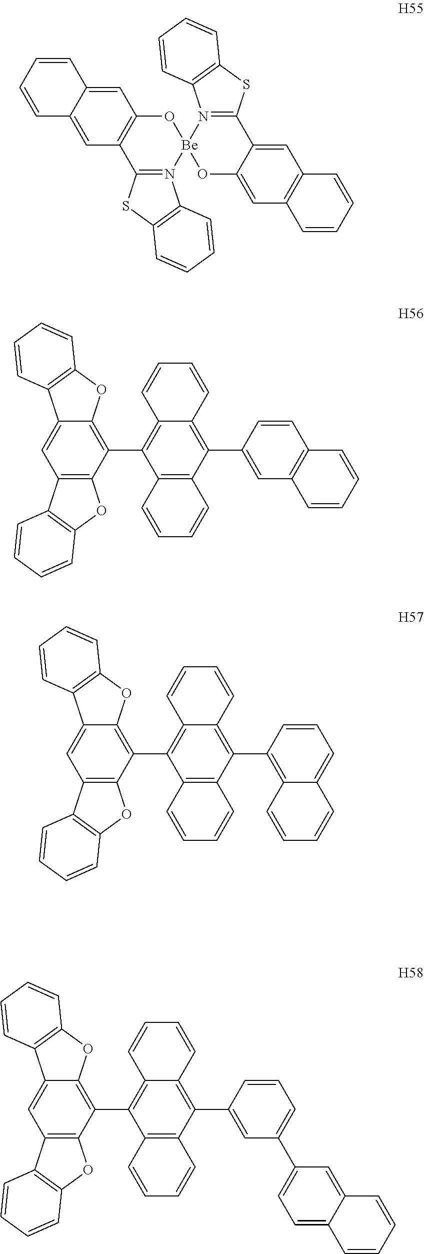

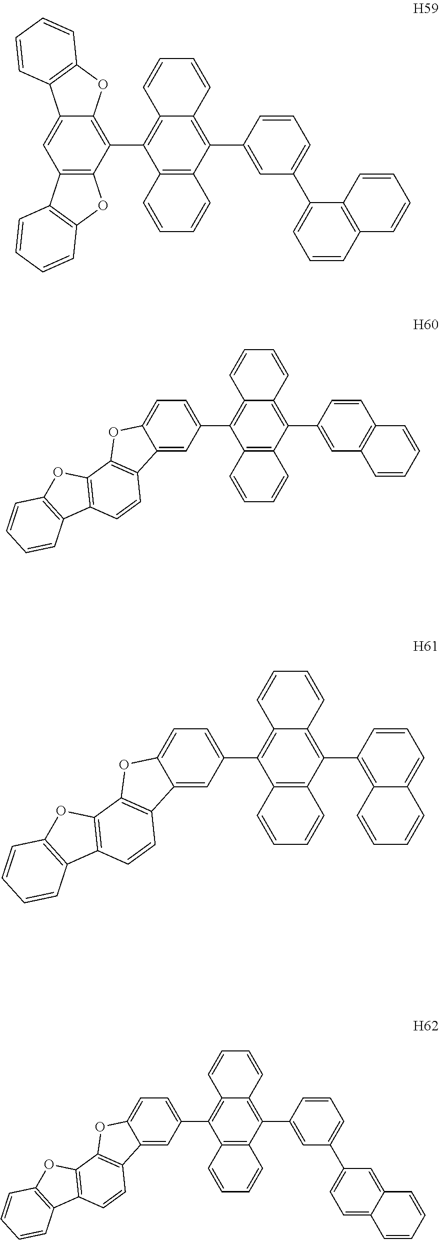 [SMILES: c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1]

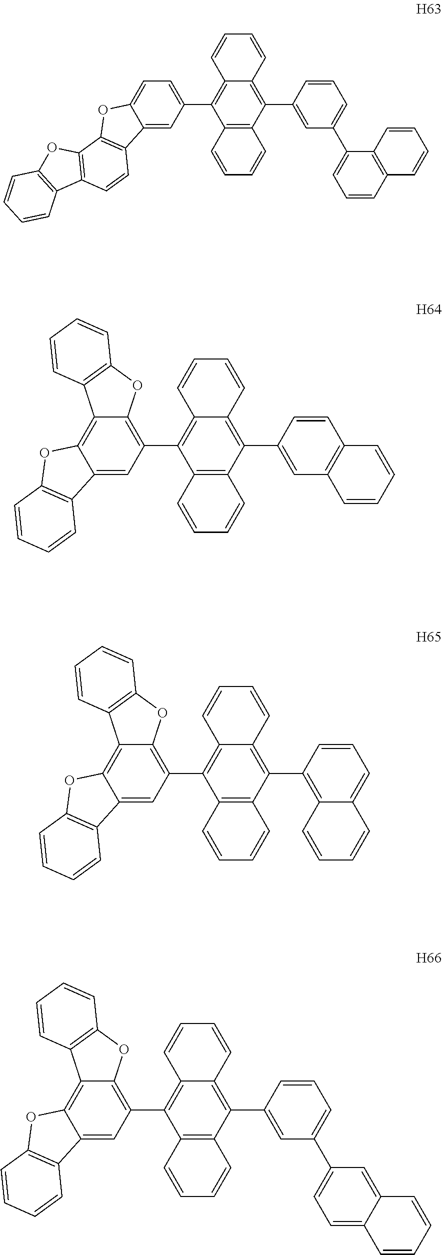 [SMILES: c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1]

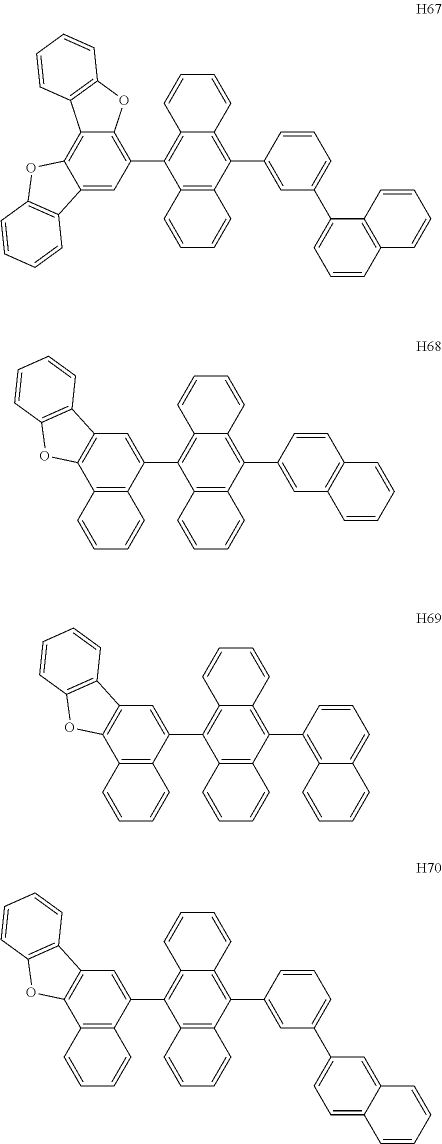 [SMILES: c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1]

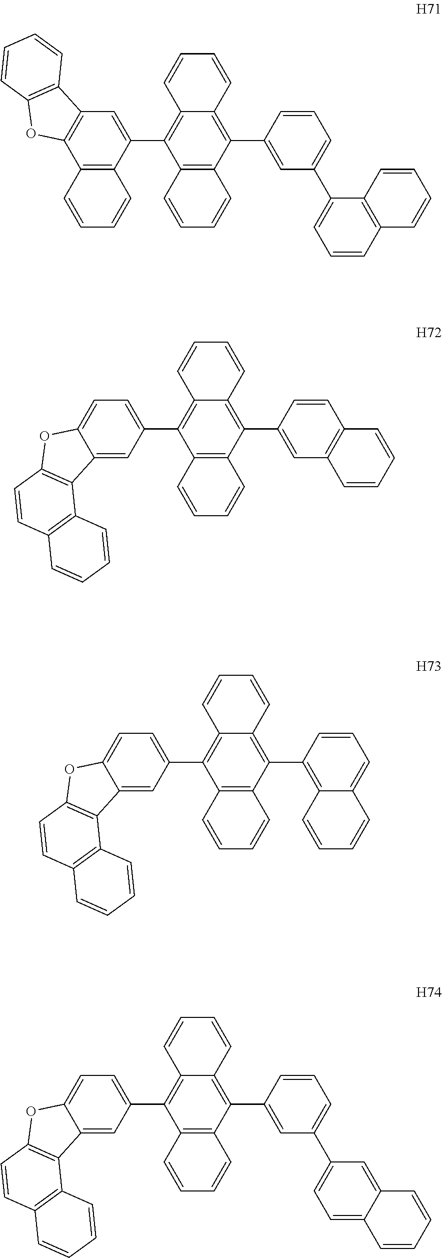 [SMILES: c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1]

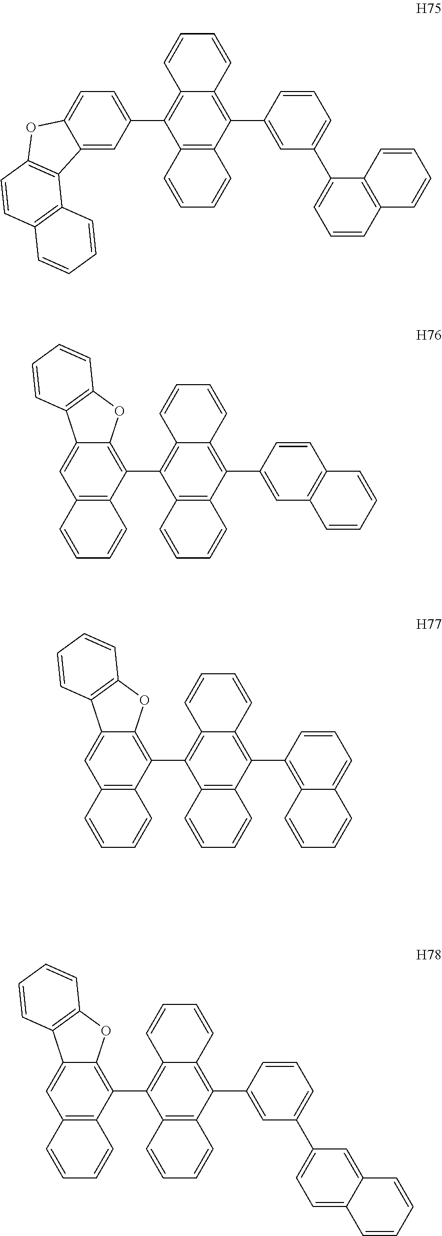 [SMILES: c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1]

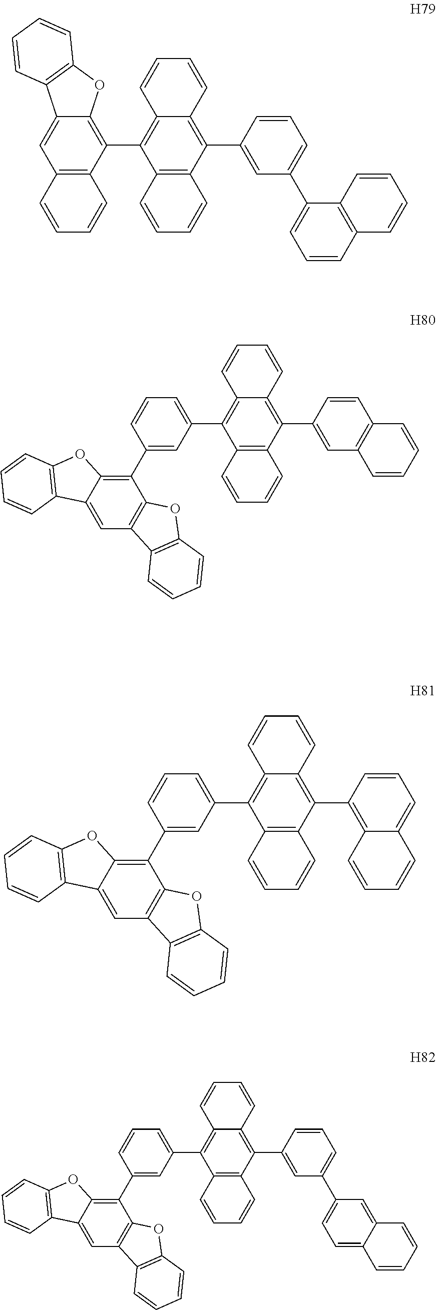 [SMILES: c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1]

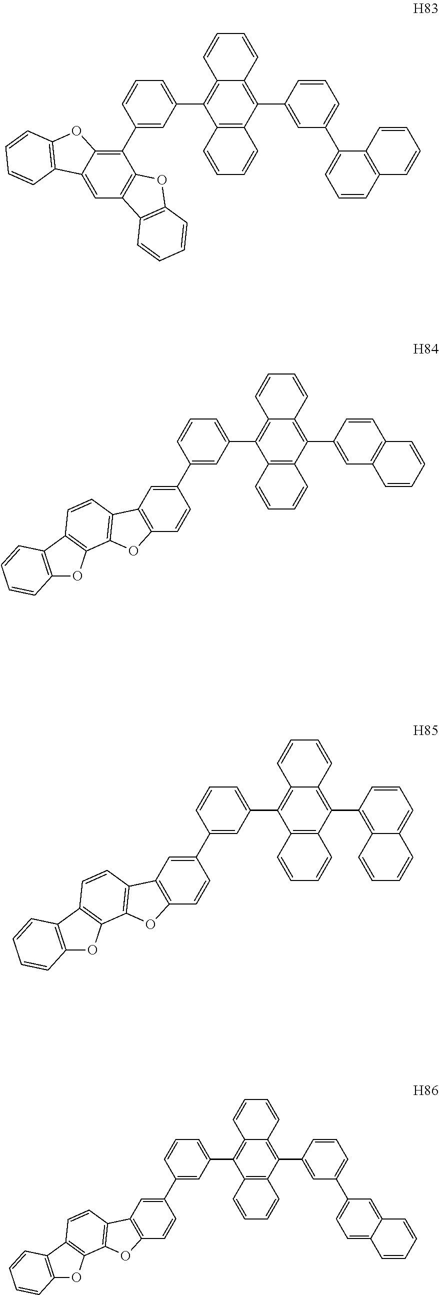 [SMILES: c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1]

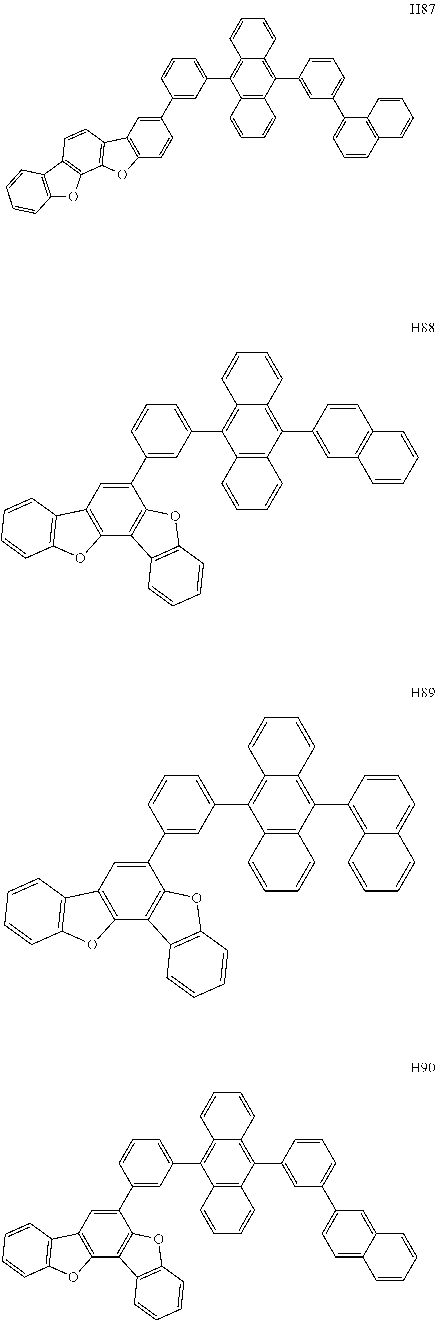 [SMILES: c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1]

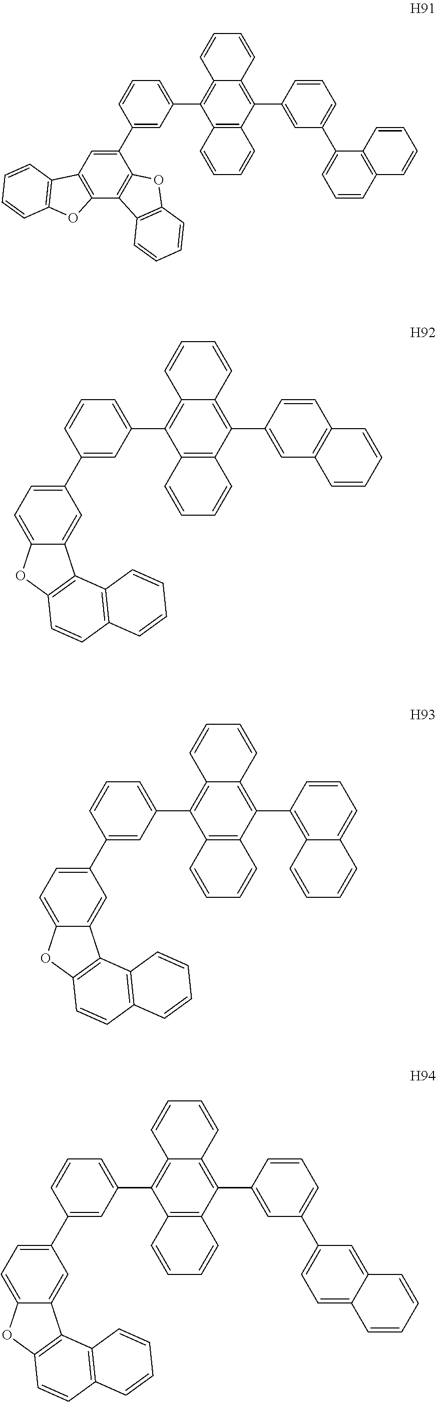 [SMILES: c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1]

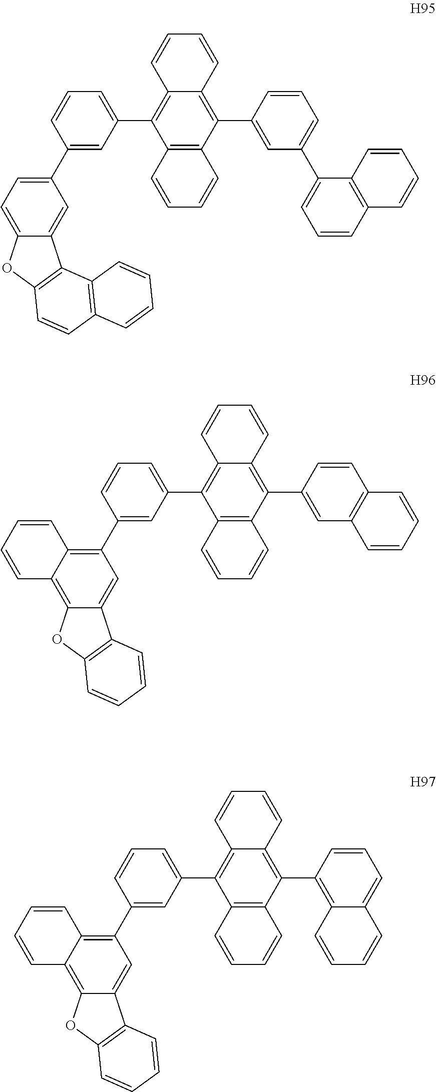 [SMILES: c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1]

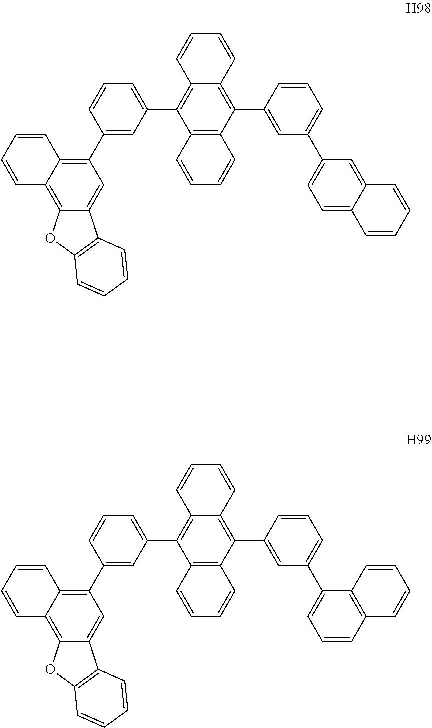 [SMILES: c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

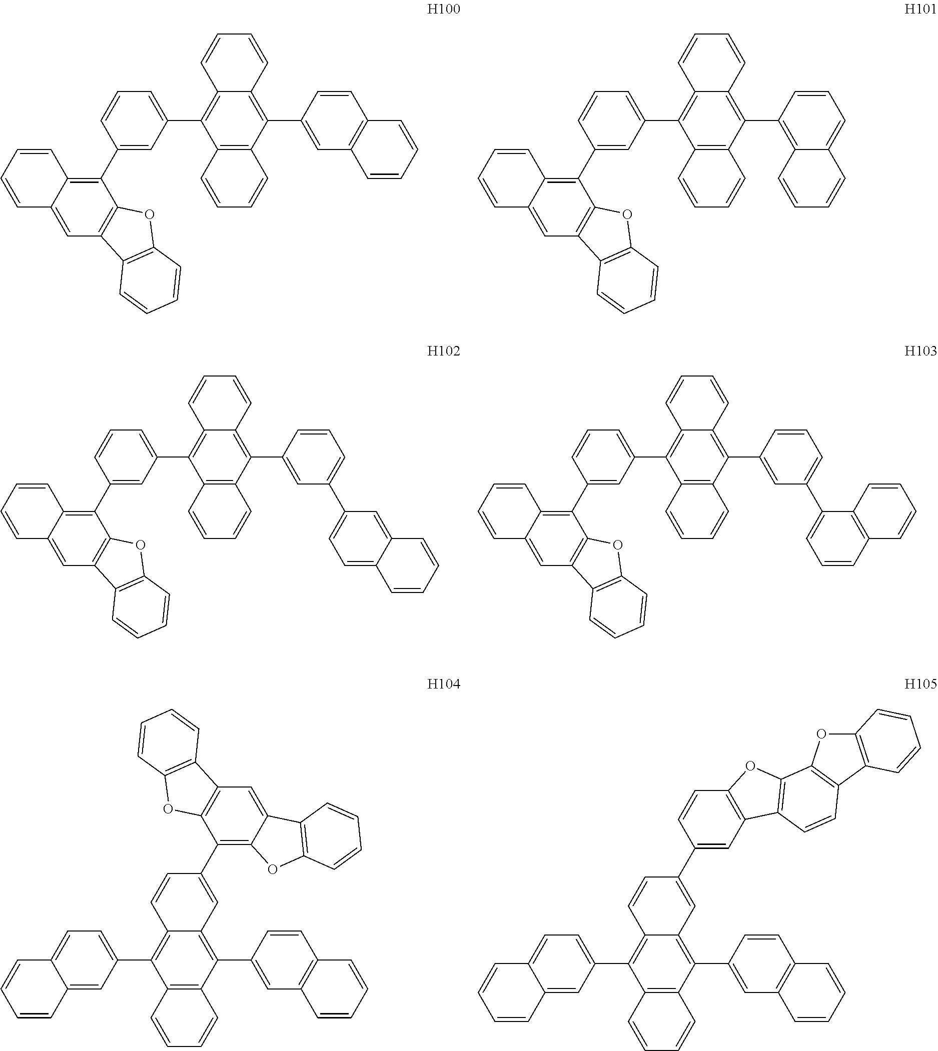

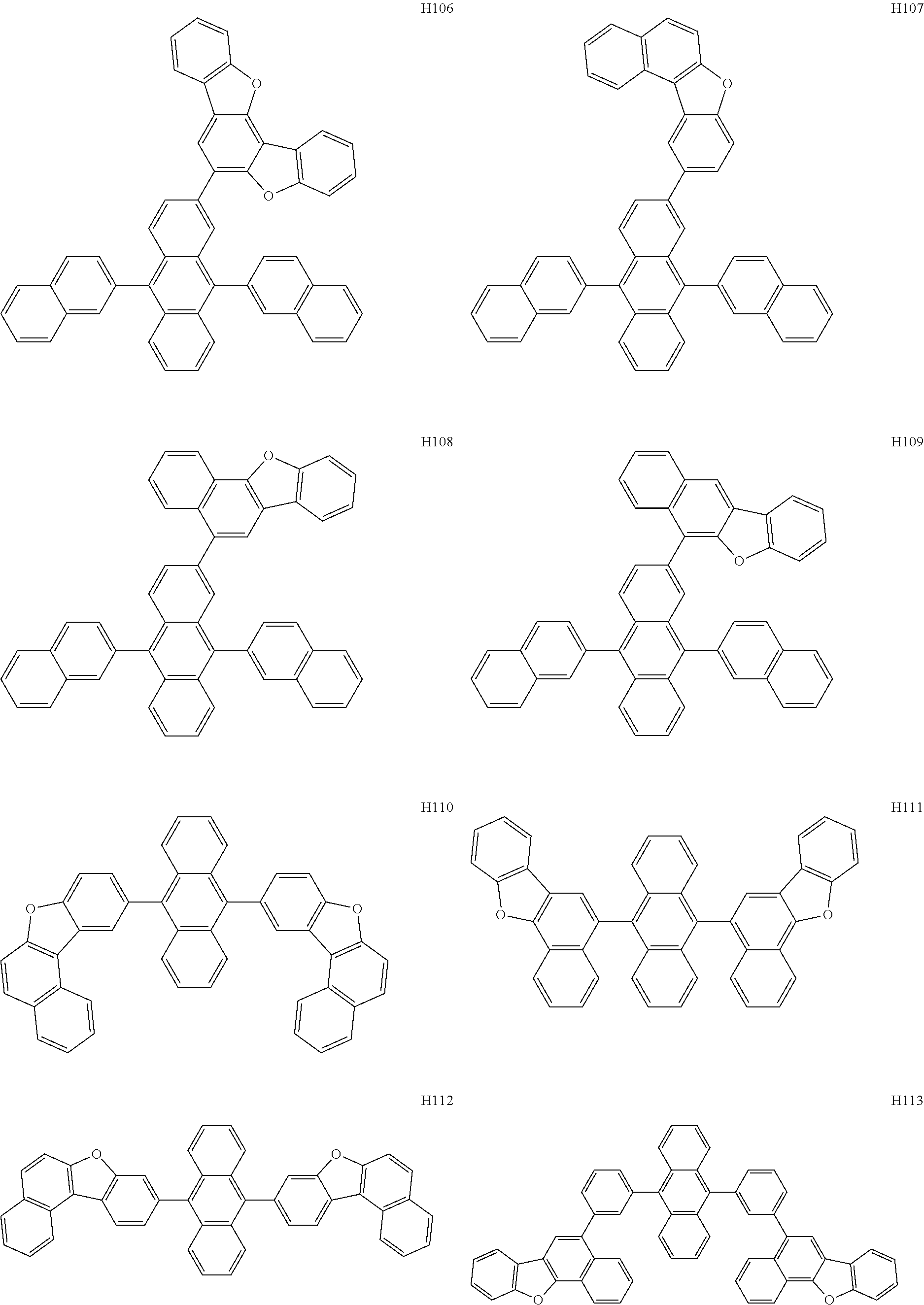

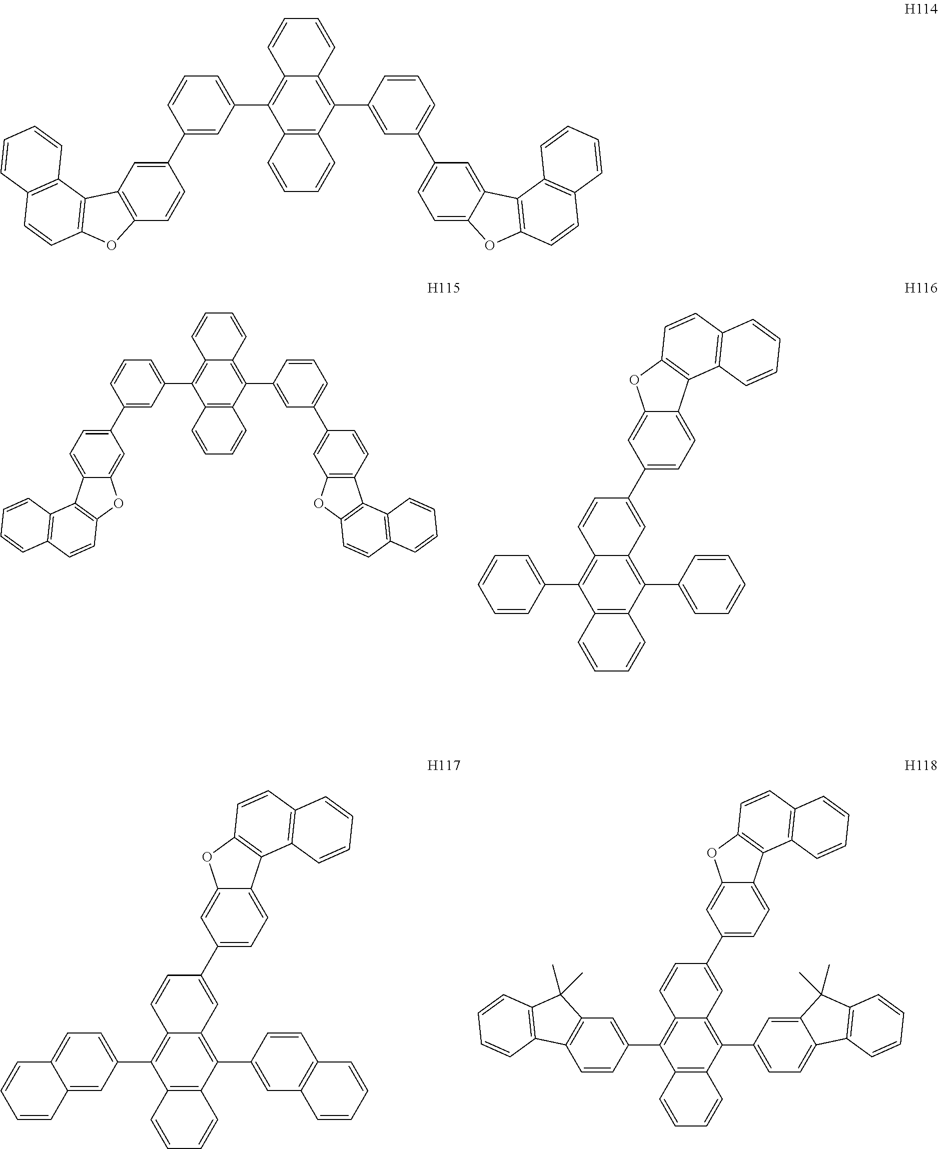 [SMILES: c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

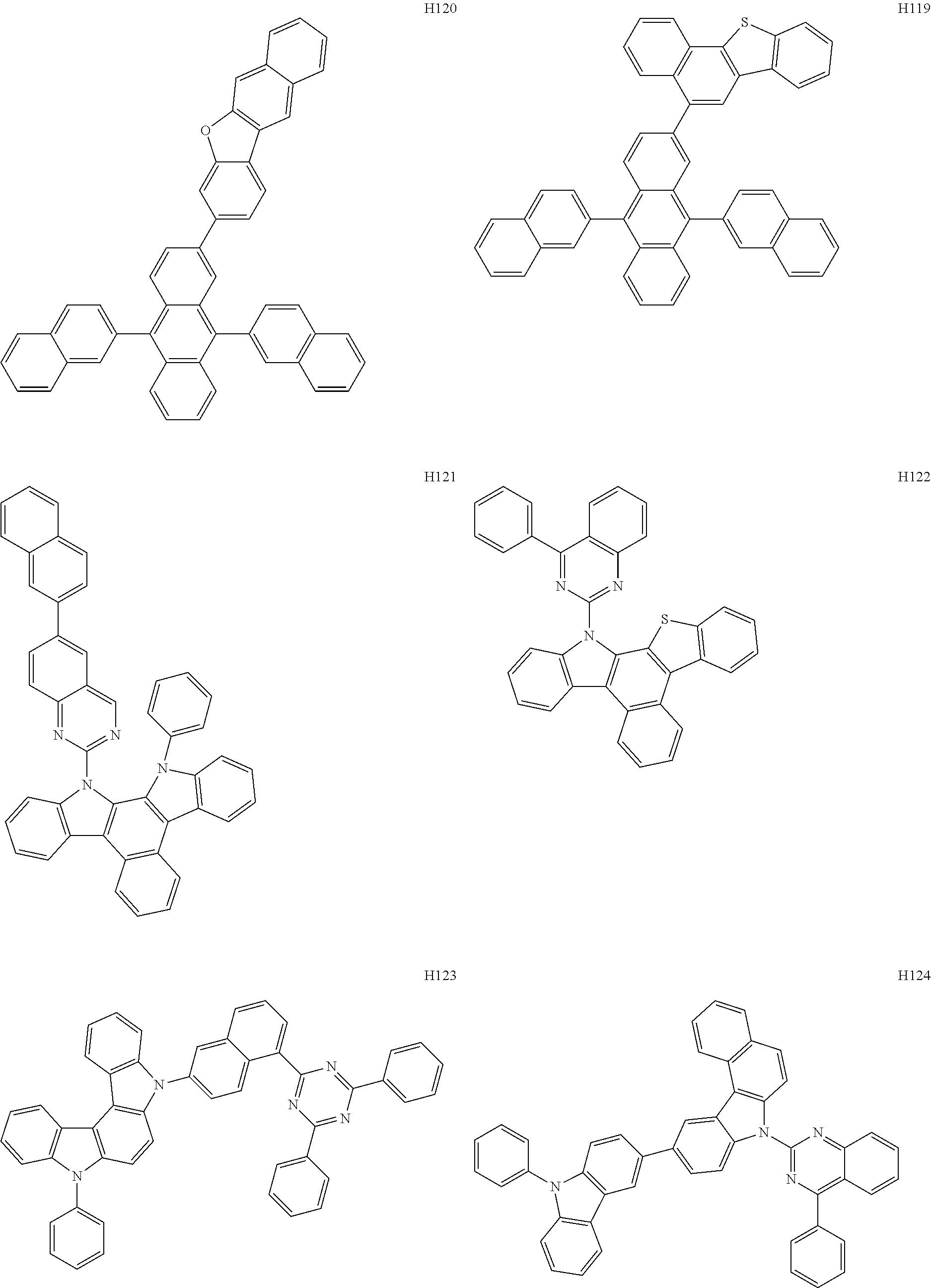

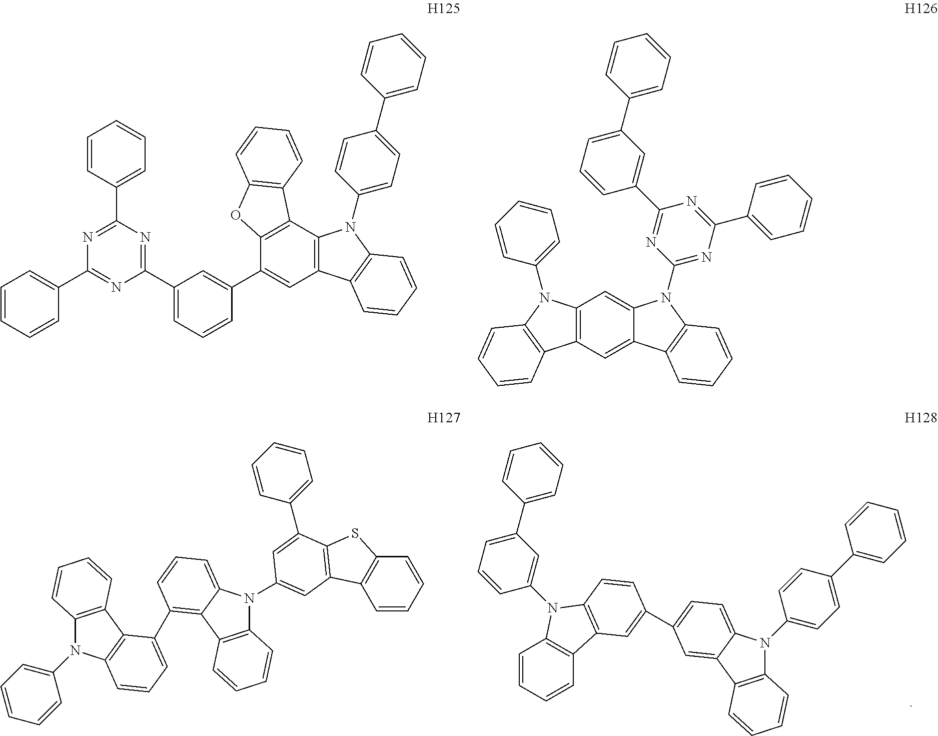 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### Phosphorescent Dopant

In one or more embodiments, the phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

For example, the phosphorescent dopant may include an organometallic compound represented by Formula 401:

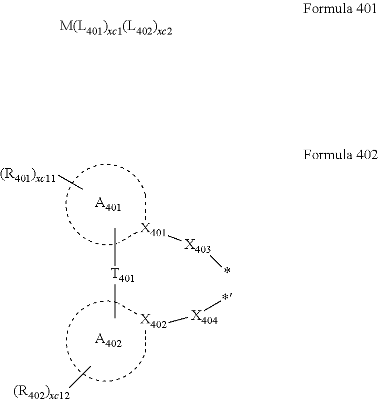

wherein, in Formulae 401 and 402,

M may be transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),

L₄₀₁ may be a ligand represented by Formula 402, and xc1 may be 1, 2, or 3, wherein when xc1 is two or more, two or more of L₄₀₁(s) may be identical to or different from each other,

L₄₀₂ may be an organic ligand, and xc2 may be 0, 1, 2, 3, or 4, and when xc2 is 2 or more, two or more of L₄₀₂(s) may be identical to or different from each other,

X₄₀₁ and X₄₀₂ may each independently be nitrogen or carbon, ring A₄₀₁ and ring A₄₀₂ may each independently be a C₃-C₆₀ carbocyclic group or a C₁-C₆₀ heterocyclic group,

T₄₀₁ may be a single bond, —O—, —S—, —C(═O)—, —N(Q₄₁₁)-, —C(Q₄₁₁)(Q₄₁₂)-, —C(Q₄₁₁)=C(Q₄₁₂)-, —C(Q₄₁₁)=, or ═C═,

X₄₀₃ and X₄₀₄ may each independently be a chemical bond (for example, a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄),

Q₄₁₁ to Q₄₁₄ may each be the same as described herein with respect to Q₁,

R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),

Q₄₀₁ to Q₄₀₃ may each be the same as described herein with respect to Q₁,

xc11 and xc12 may each independently be an integer from 0 to 10, and

* and *′ in Formula 402 each indicate a binding site to M in Formula 401.

For example, in Formula 402, i) X₄₀₁ may be nitrogen, and X₄₀₂ may be carbon, or ii) each of X₄₀₁ and X₄₀₂ may be nitrogen.

In an embodiment, when xc1 in Formula 401 is 2 or more, two ring A₄₀₁(s) among two or more of L₄₀₁ may optionally be bonded to each other via T₄₀₂, which is a linking group, and two ring A₄₀₂(s) among two or more of L₄₀₁ may optionally be bonded to each other via T₄₀₃, which is a linking group (see Compounds PD1 to PD4 and PD7). T₄₀₂ and T₄₀₃ may each be the same as described herein with respect to T₄₀₁.

L₄₀₂ in Formula 401 may be an organic ligand. For example, L₄₀₂ may include a halogen group, a diketone group (for example, an acetylacetonate group), a carboxylic acid group (for example, a picolinate group), —C(═O), an isonitrile group, —CN group, a phosphorus group (for example, a phosphine group, a phosphite group, etc.), or any combination thereof.

In a ligand of the organometallic compound, adjacent substituents may optionally be bonded to each other to form a ring.

The phosphorescent dopant may include, for example, one of compounds PD1 to PD39, or any combination thereof:

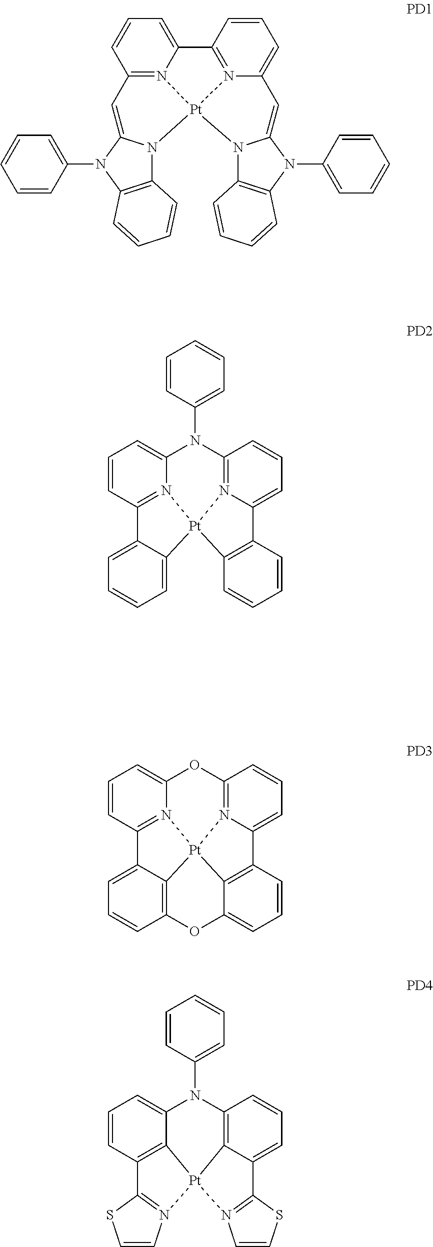

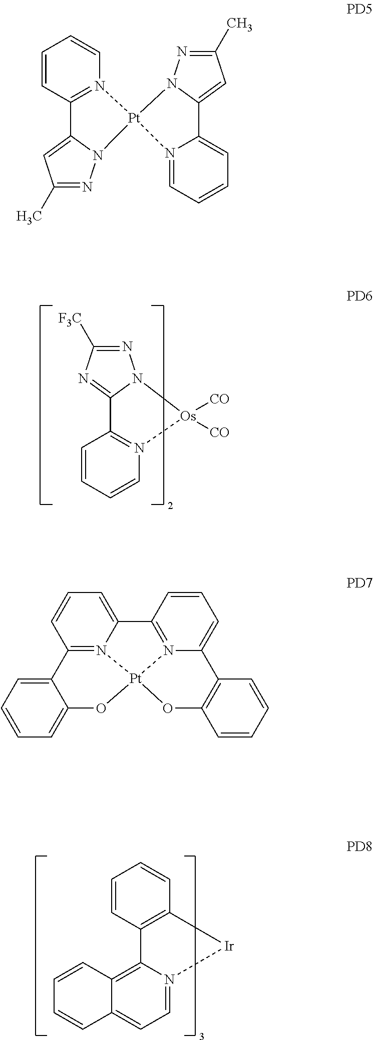

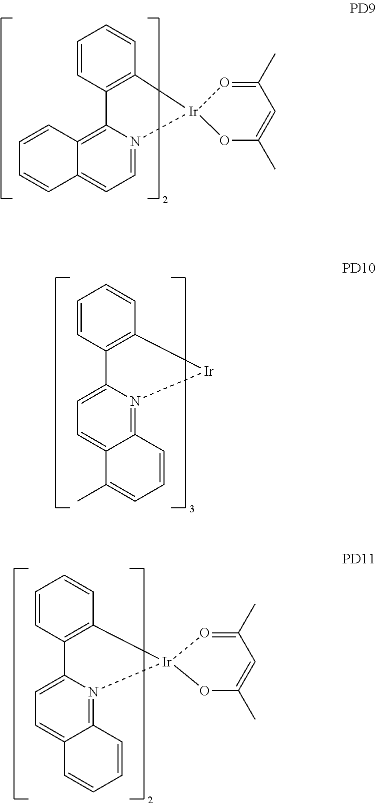

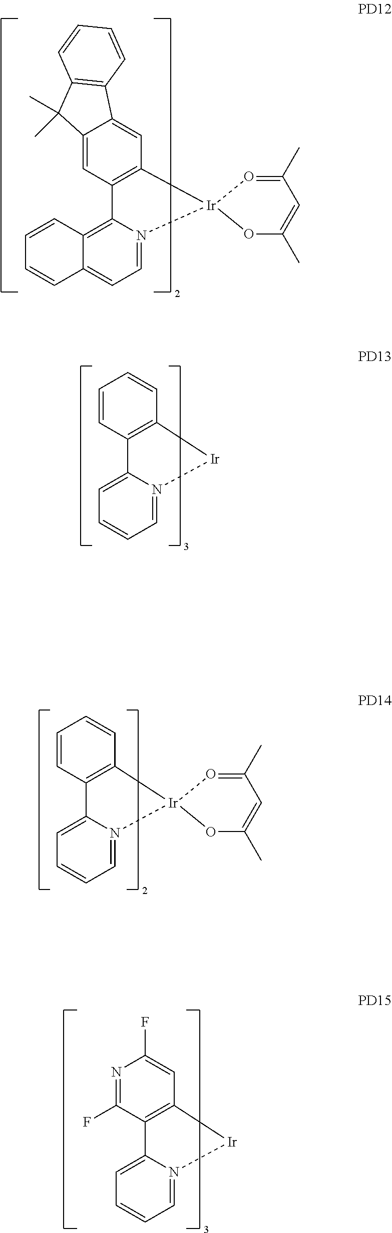

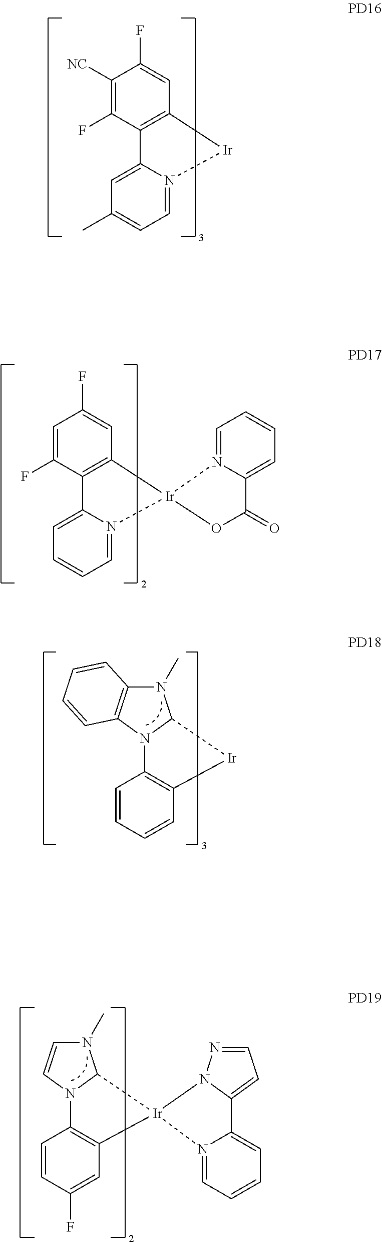

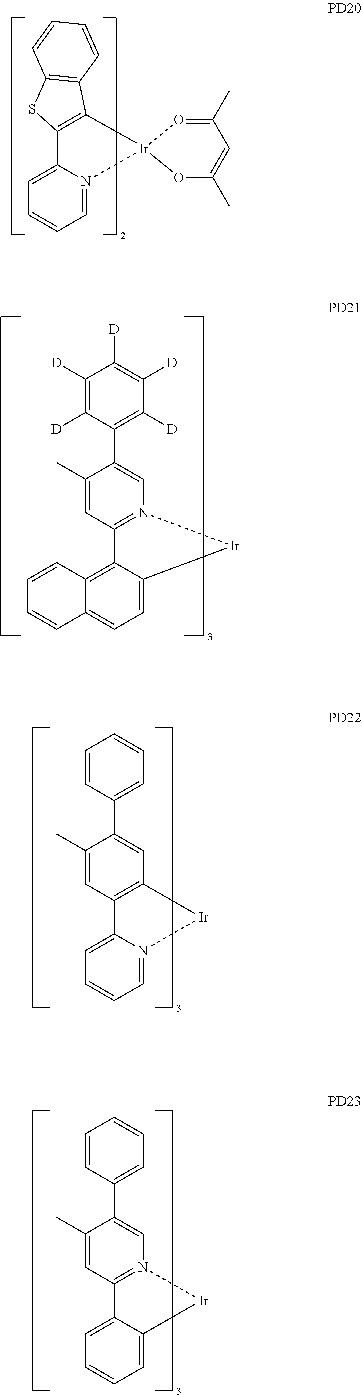

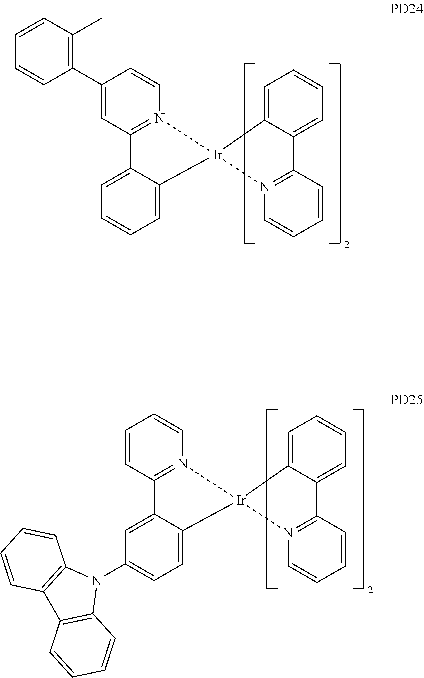

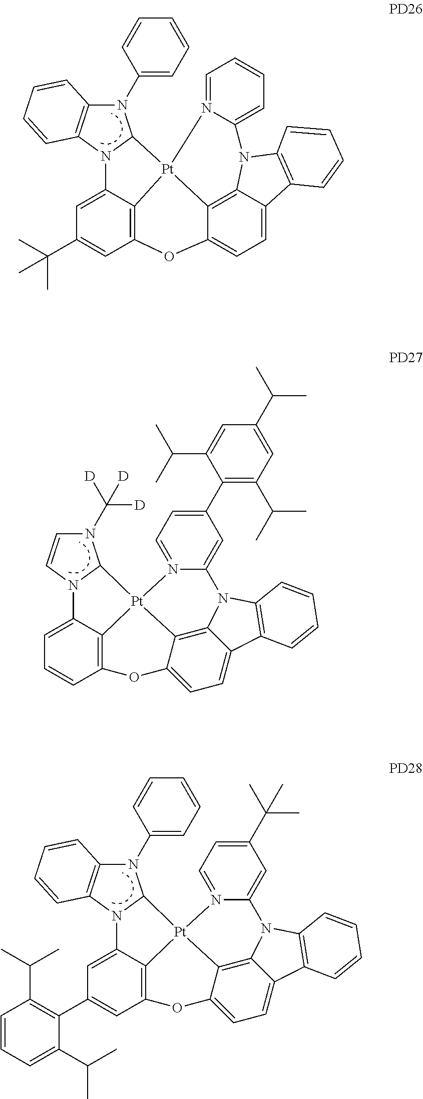

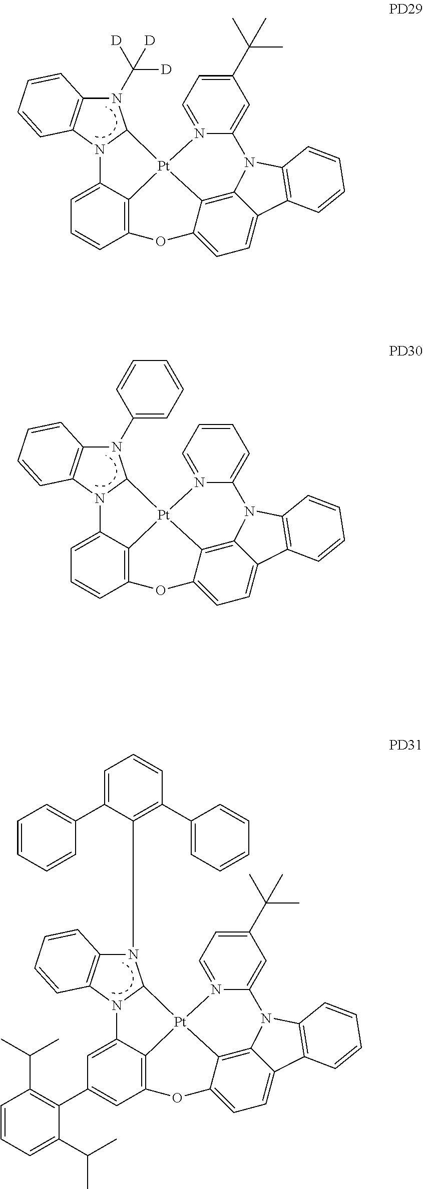

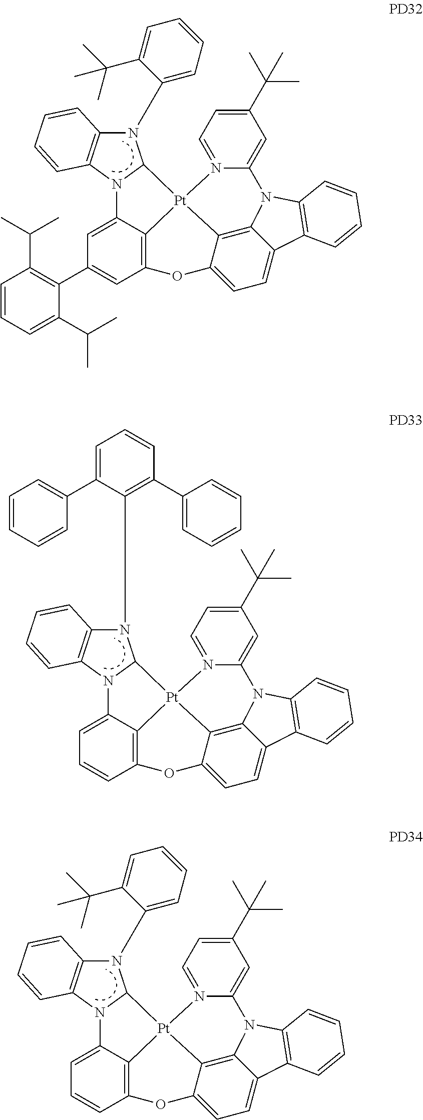

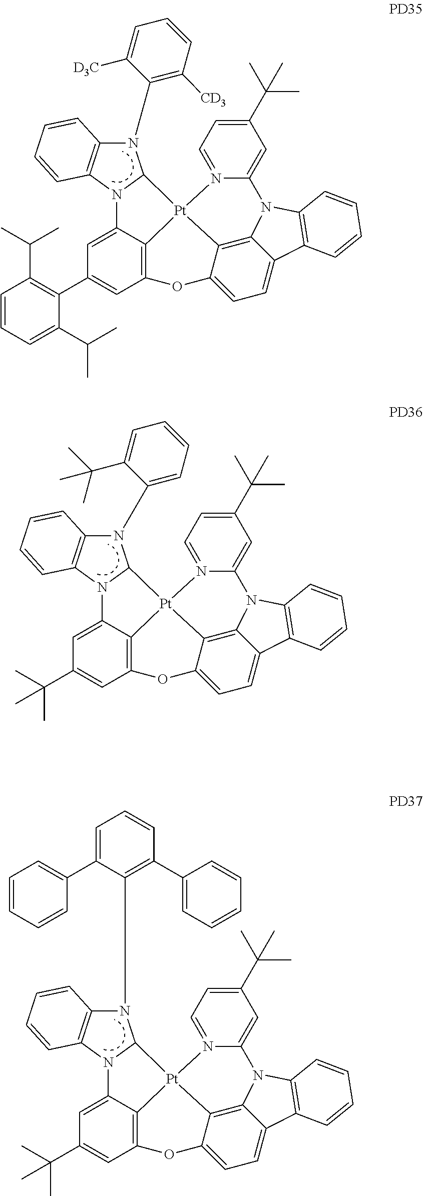

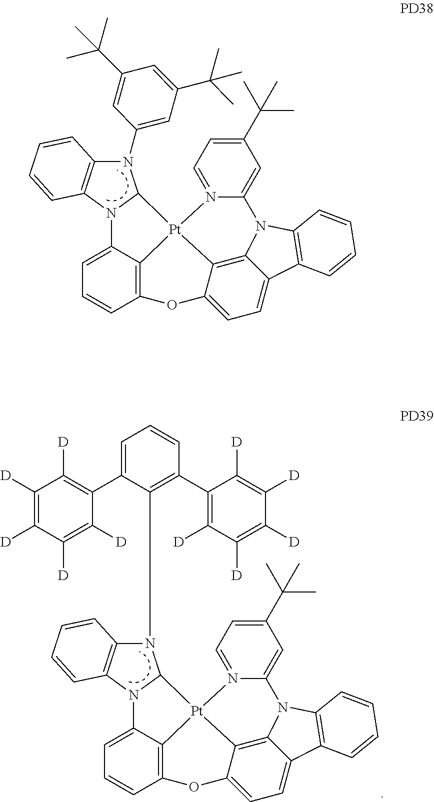

### Fluorescent Dopant

The fluorescent dopant may include an amine group-containing compound, a styryl group-containing compound, or any combination thereof.

For example, the fluorescent dopant may include a compound represented by Formula 501:

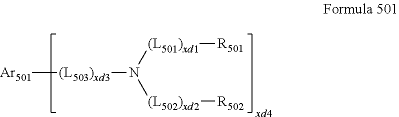

wherein, in Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

For example, Ar₅₀₁ in Formula 501 may be a condensed cyclic group (for example, an anthracene group, a chrysene group, or a pyrene group) in which three or more monocyclic groups are condensed together.

In one or more embodiments, xd4 in Formula 501 may be 2.

In an embodiment, the fluorescent dopant may include: one of Compounds FD1 to FD37; DPVBi; DPAVBi; or any combination thereof:

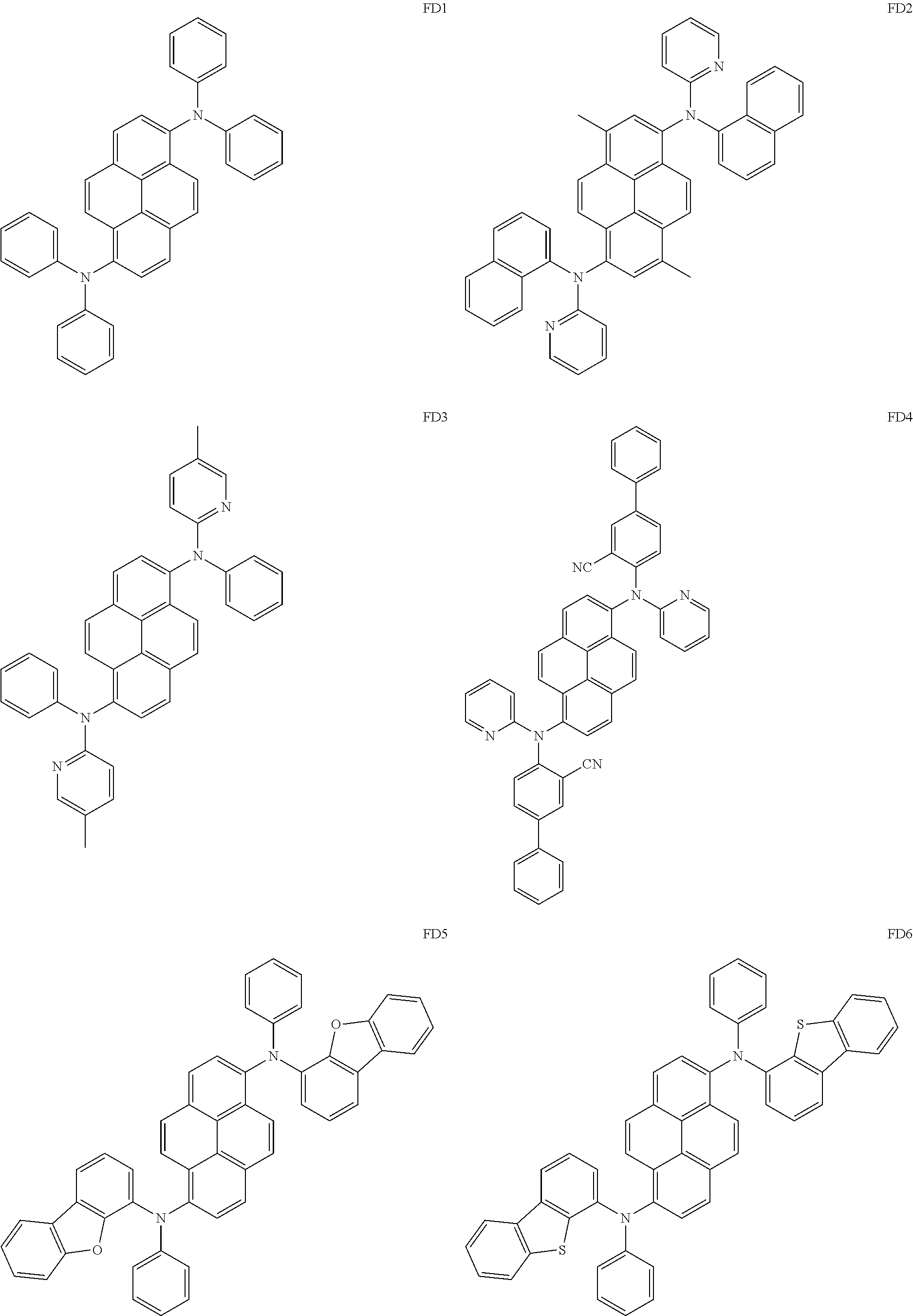

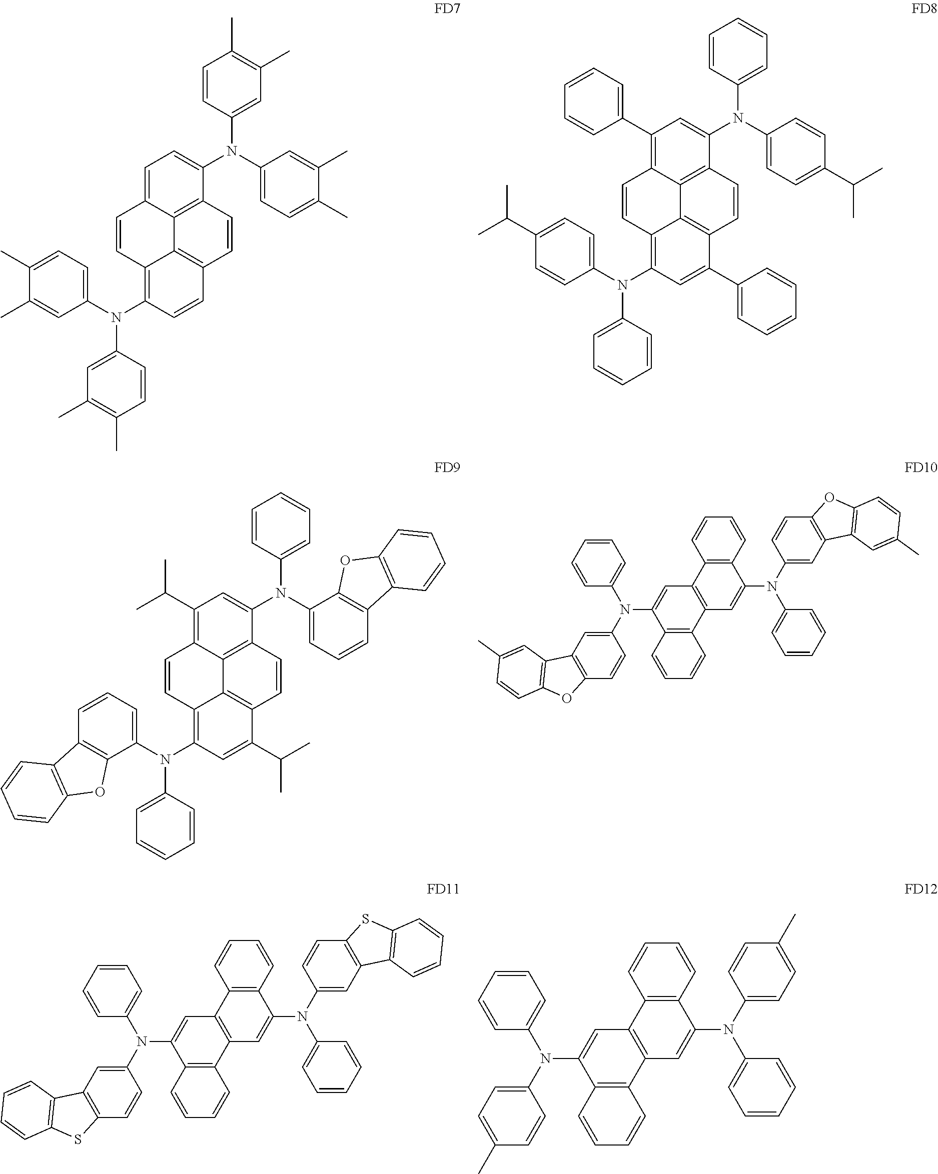

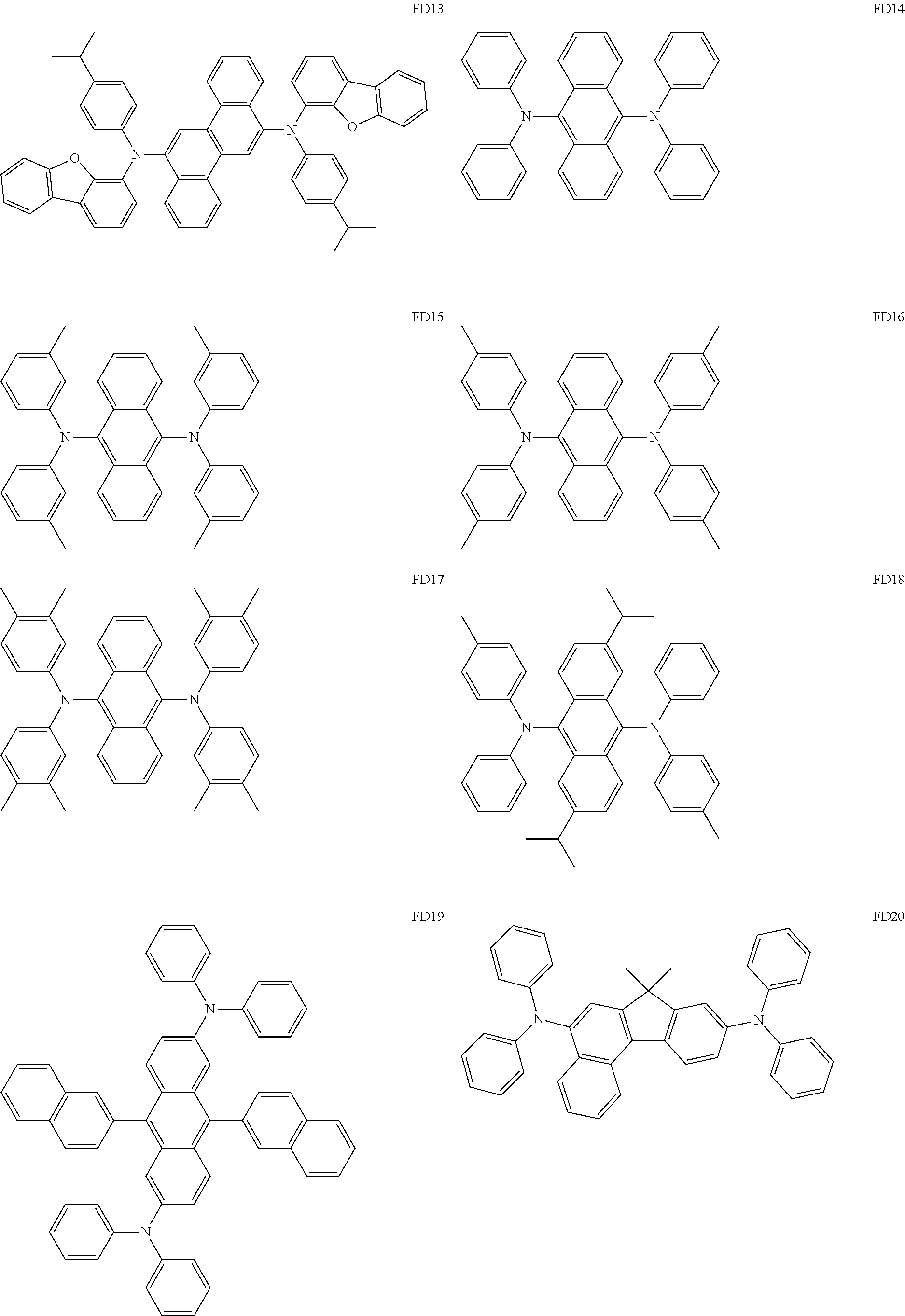

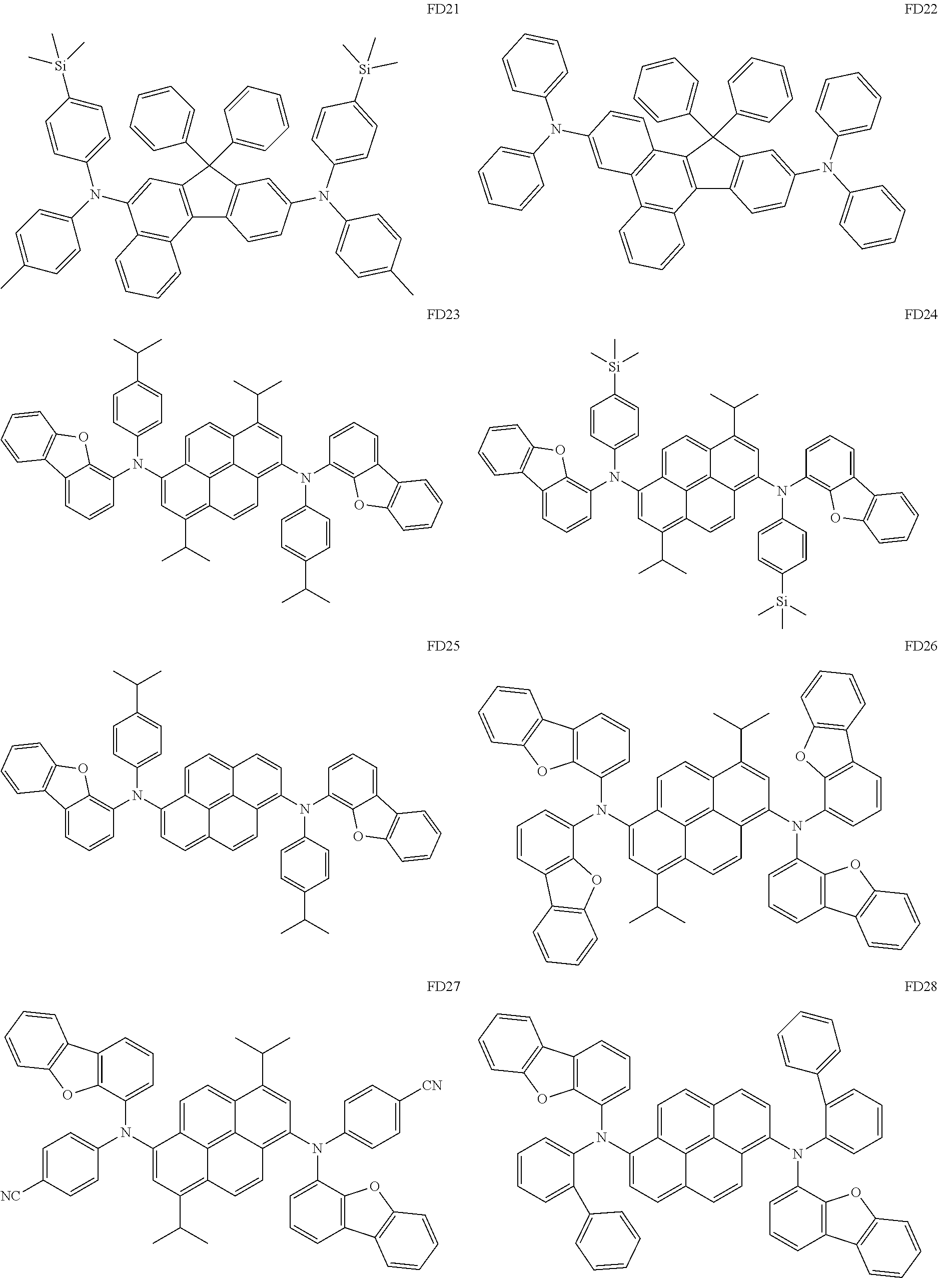

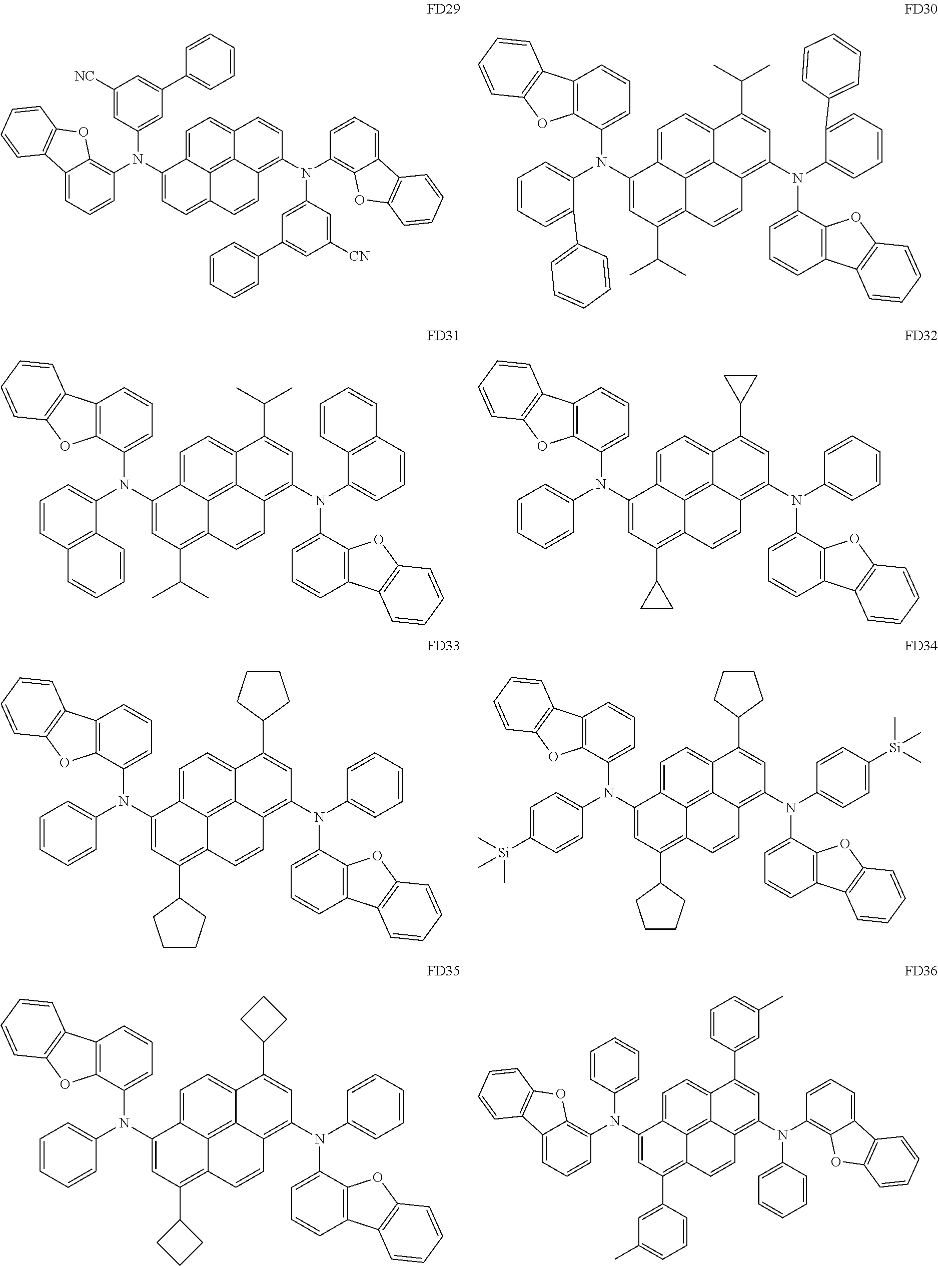

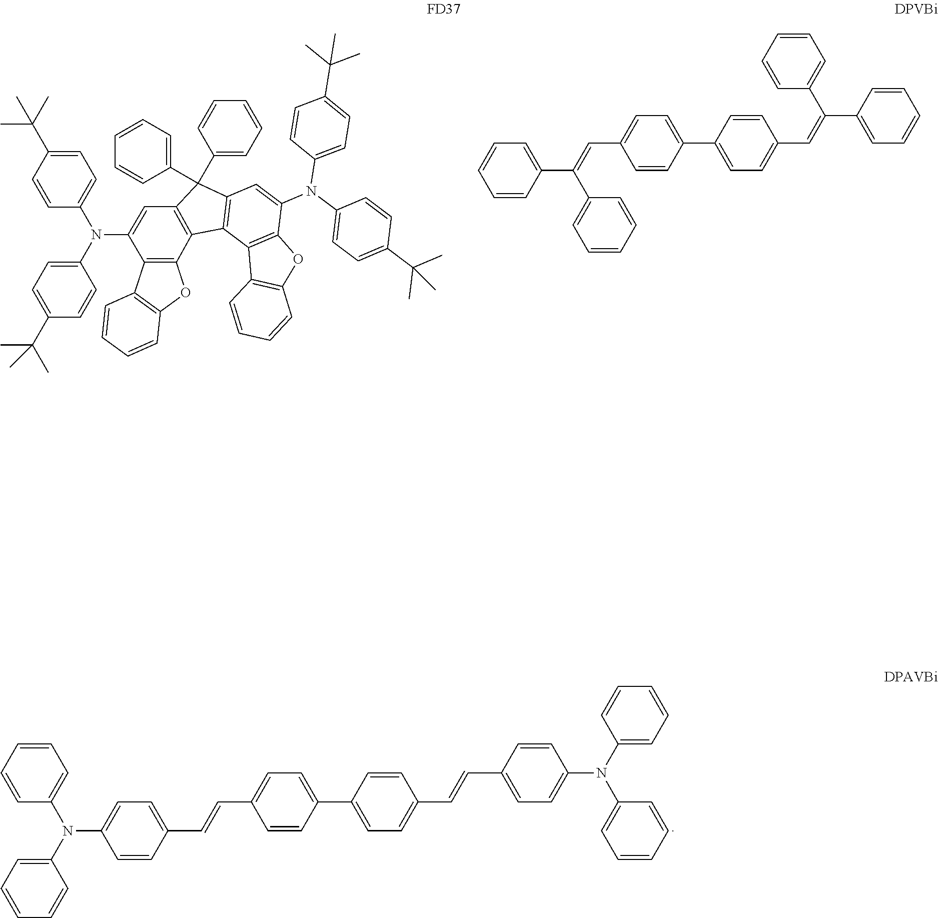

Delayed fluorescence material

The emission layer may include a delayed fluorescence material.

In the present specification, the delayed fluorescence material may be selected from compounds capable of emitting delayed fluorescent light based on a delayed fluorescence emission mechanism.

The delayed fluorescence material included in the emission layer may act as a host or a dopant depending on the type (or kind) of other materials included in the emission layer.

In one or more embodiments, the difference between the triplet energy level (eV) of the delayed fluorescence material and the singlet energy level (eV) of the delayed fluorescence material may be greater than or equal to 0 eV and less than or equal to 0.5 eV. When the difference between the triplet energy level (eV) of the delayed fluorescence material and the singlet energy level (eV) of the delayed fluorescence material satisfies the above-described range, up-conversion from the triplet state to the singlet state of the delayed fluorescence materials may effectively occur, and thus, the luminescence efficiency of the light-emitting device 10 may be improved.

For example, the delayed fluorescence material may include i) a material including at least one electron donor (for example, a IT electron-rich C₃-C₆₀ cyclic group, such as a carbazole group) and at least one electron acceptor (for example, a sulfoxide group, a cyano group, or a Ir electron-deficient nitrogen-containing C₁-C₆₀ cyclic group), and ii) a material including a C₈-C₆₀ polycyclic group in which two or more cyclic groups are condensed together while sharing boron (B).

Examples of the delayed fluorescence material may include at least one of Compounds DF1 to DF14:

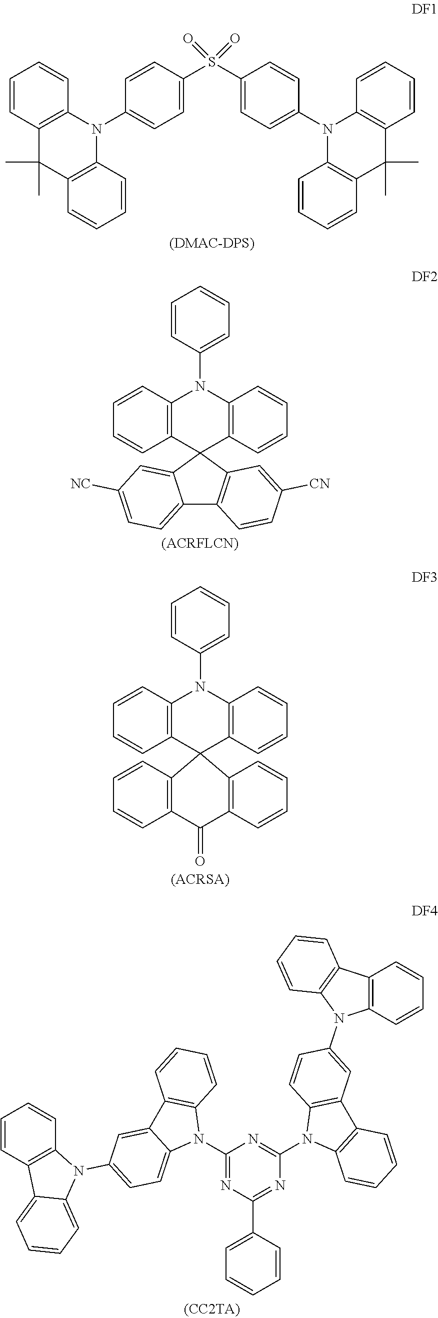

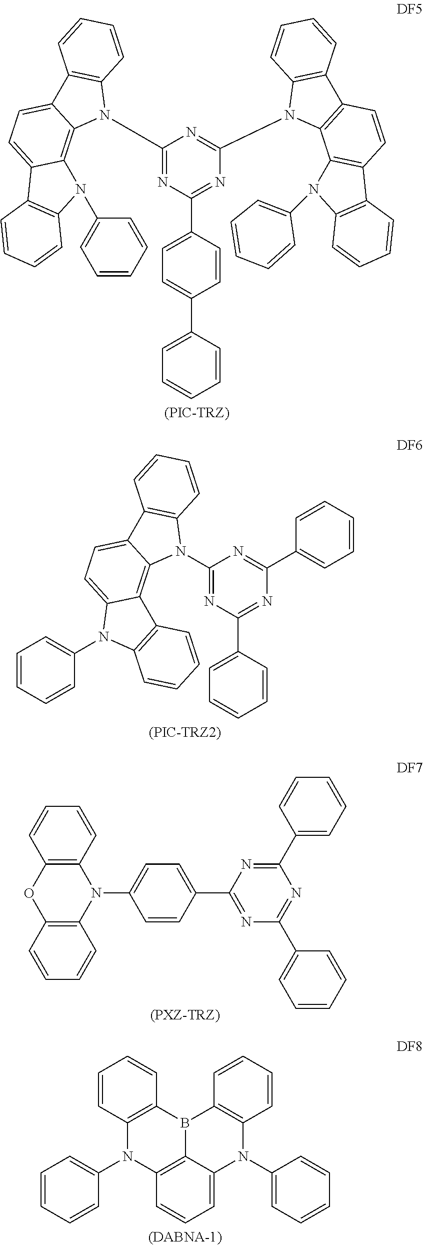

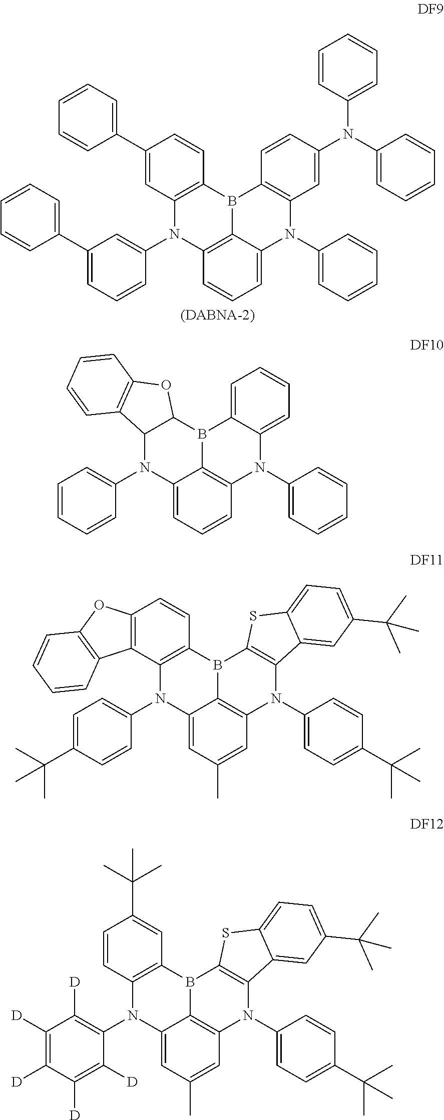

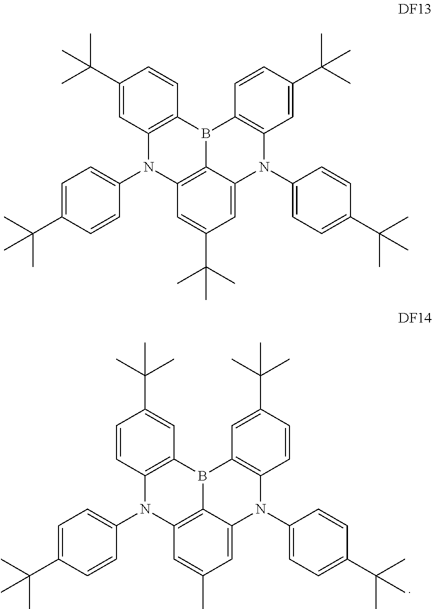

### Quantum Dot

The emission layer may include a quantum dot.

The term “quantum dots” as used herein refers to crystals of a semiconductor compound, and may include any suitable material capable of emitting light of various suitable emission wavelengths according to the size of the crystals. Quantum dots may emit light of various suitable emission wavelengths by adjusting a ratio of elements in the quantum dot compounds.

A diameter of the quantum dot may be, for example, in a range of about 1 nm to about 10 nm.

The quantum dot may be synthesized by a wet chemical process, a metal organic chemical vapor deposition process, a molecular beam epitaxy process, and/or any process similar thereto.

The wet chemical process is a method including mixing a precursor material together with an organic solvent and then growing a quantum dot particle crystal. When the crystal grows, the organic solvent naturally acts as a dispersant coordinated on the surface of the quantum dot crystal and controls the growth of the crystal so that the growth of quantum dot particles can be controlled through a process which costs lower, and is easier than vapor deposition methods, such as metal organic chemical vapor deposition (MOCVD) or molecular beam epitaxy (MBE).

The quantum dot may include Group II-VI semiconductor compounds, Group III-V semiconductor compounds, Group III-VI semiconductor compounds, Group I-III-VI semiconductor compounds, Group IV-VI semiconductor compounds, a Group IV element or compound, or any combination thereof.

Examples of the Group II-VI semiconductor compound are a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or any combination thereof.

Examples of the Group III-V semiconductor compound may include: a binary compound, such as GaN, GaP, GaAs, GaSb, AlN, AlP, AlAs, AlSb, InN, InP, InAs, and/or InSb; a ternary compound, such as GaNP, GaNAs, GaNSb, GaPAs, GaPSb, AlNP, AlNAs, AlNSb, AlPAS, AlPSb, InGaP, InNP, InAlP, InNAs, InNSb, InPAs, and/or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb; or any combination thereof. Meanwhile, the Group III-V semiconductor compound may further include a Group II element. Examples of the Group III-V semiconductor compound further including a Group II element are InZnP, InGaZnP, InAlZnP, etc.

Examples of the Group III-VI semiconductor compound are: a binary compound, such as GaS, GaSe, Ga₂Se₃, GaTe, InS, InSe, In₂S₃, In₂Se₃, and/or InTe; a ternary compound, such as InGaS₃, and/or InGaSe₃; and any combination thereof.

Examples of the Group I-III-VI semiconductor compound may include ternary compounds, such as AgInS, AgInS₂, CuInS, CuInS₂, CuGaO₂, AgGaO₂, and/or AgAlO₂; or any combination thereof, such as AgInGaS and/or AgInGaS₂.

Examples of the Group IV-VI semiconductor compound are: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or any combination thereof.

The Group IV element or compound may include: a single element, such as Si and/or Ge; a binary compound, such as SiC and/or SiGe; or any combination thereof.

Each element included in a multi-element compound such as the binary compound, the ternary compound, and the quaternary compound may be present at a uniform concentration or non-uniform concentration in a particle.

In some embodiments, the quantum dot may have a single structure in which the concentration of each element in the quantum dot is uniform (e.g., substantially uniform), or a core-shell dual structure. For example, the material included in the core and the material included in the shell may be different from each other.

The shell of the quantum dot may act as a protective layer that prevents or reduces chemical degeneration of the core to maintain semiconductor characteristics, and/or as a charging layer that imparts electrophoretic characteristics to the quantum dot. The shell may be a single layer or a multi-layer. The interface between the core and the shell may have a concentration gradient in which the concentration of an element existing in the shell decreases along a direction toward the center of the core. Examples of the shell of the quantum dot may be an oxide of metal,

metalloid, and/or non-metal, a semiconductor compound, and any combination thereof. Examples of the oxide of metal, metalloid, and/or non-metal are a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgAl₂O₄, CoFe₂O₄, NiFe₂O₄, and/or CoMn₂O₄; and any combination thereof. Examples of the semiconductor compound are, as described herein, a Group II-VI semiconductor compound; a Group III-V semiconductor compound; a Group III-VI semiconductor compound; a Group I-III-VI semiconductor compound; a Group IV-VI semiconductor compound; and any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of the emission wavelength spectrum of the quantum dot may be about 45 nm or less, for example, about 40 nm or less, for example, about 30 nm or less, and within these ranges, color purity and/or color reproducibility may be increased. In addition, because the light emitted through the quantum dot is emitted in all (e.g., substantially all) directions, the wide viewing angle may be improved.

In addition, the quantum dot may be in the form of a spherical particle, a pyramidal particle, a multi-arm particle, a cubic nanoparticle, a nanotube particle, a nanowire particle, a nanofiber particle, and/or a nanoplate particle.

Because the energy band gap may be adjusted by controlling the size of the quantum dot, light having various suitable wavelength bands may be obtained from the quantum dot emission layer. Accordingly, by using quantum dots of different sizes, a light-emitting device that emits light of various suitable wavelengths may be implemented. In one or more embodiments, the size of the quantum dot may be selected to emit red, green and/or blue light. In addition, the size of the quantum dot may be configured to emit white light by combination of light of various suitable colors.

### Second Electrode 170

The second electrode 170 is on an upper surface of the electron transport region as described above. The second electrode 190 may be a cathode, and as the material for the second electrode 190, a metal, an alloy, an electrically conductive compound, or any combination thereof, each having a low work function, may be used.

The second electrode 170 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 170 may be a transmissive electrode, a semi-transmissive electrode, or a reflective electrode.

The second electrode 170 may have a single-layered structure or a multi-layered structure including a plurality of layers.

### Capping Layer

A first capping layer may be outside of the 2-1 pixel electrode, the 2-2 pixel electrode, the 2-3 pixel electrode, and the first pixel electrode, and/or a second capping layer may be outside of the cathode, which is a counter electrode.

The first capping layer and/or the second capping layer may prevent or reduce penetration of impurities, such as water and/or oxygen, to the electronic apparatus to thereby improve reliability of the electronic apparatus.

Each of the first capping layer and the second capping layer may include a material having a refractive index of 1.6 or more (at a wavelength of 589 nm).

The first capping layer and the second capping layer may each independently be an organic capping layer including an organic material, an inorganic capping layer including an inorganic material, or an organic-inorganic composite capping layer including an organic material and an inorganic material.

At least one selected from the first capping layer and the second capping layer may each independently include carbocyclic compounds, heterocyclic compounds, amine group-containing compounds, porphine derivatives, phthalocyanine derivatives, a naphthalocyanine derivatives, alkali metal complexes, alkaline earth metal complexes, or any combination thereof. Optionally, the carbocyclic compound, the heterocyclic compound, and the amine group-containing compound may be substituted with a substituent including O, N, S, Se, Si, F, Cl, Br, I, or any combination thereof. In one or more embodiments, at least one selected from the first capping layer and the second capping layer may each independently include an amine group-containing compound.

For example, at least one selected from the first capping layer and the second capping layer may each independently include a compound represented by Formula 201, a compound represented by Formula 202, or any combination thereof.

In one or more embodiments, at least one selected from the first capping layer and the second capping layer may each independently include one selected from Compounds HT28 to HT33, one of Compounds CP1 to CP6, β-NPB, or any combination thereof:

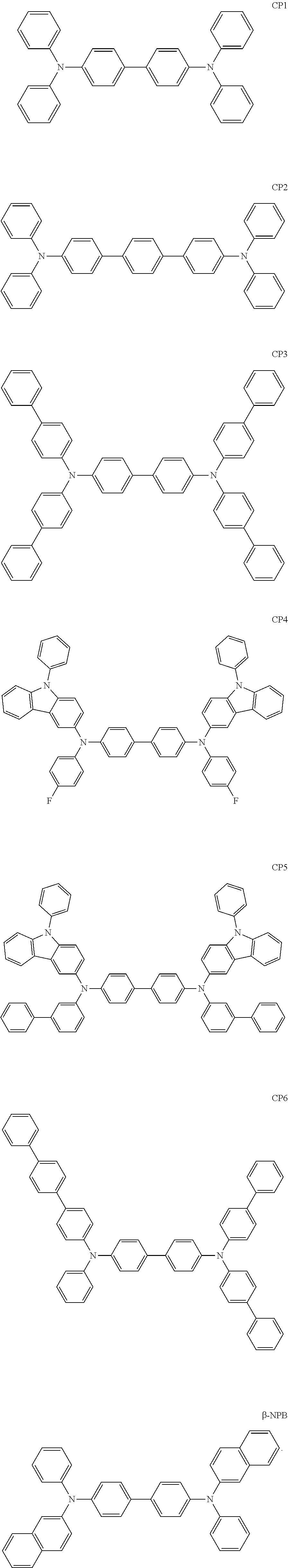

In an embodiment, the active layer may include a p-type semiconductor compound.

The p-type semiconductor compound may include a compound represented by Formula 1:

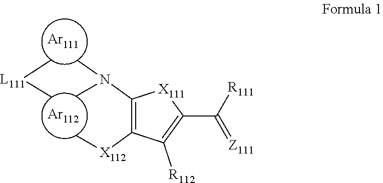

wherein, in Formula 1,

Ar₁₁₁ and Ar₁₁₂ may each independently be a C₆-C₃₀ arylene group that is unsubstituted or substituted with at least one R₁₀ₐ or a C₃-C₃₀ heteroarylene group that is unsubstituted or substituted with at least one R₁₀ₐ,

X₁₁₁ may be selected from —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, and —Ge(Q₁₁₁)(Q₁₁₂)-,

X₁₁₂ and L₁₁₁ may each be selected from —O—, —S—, —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))—, and —(C(Q₁₁₁)=N))—,

when L₁₁₁ is selected from —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂)-, and —(C(Q₁₁₁)=N))—, L₁₁₁ may optionally be linked to Ar₁₁₁ or Ar₁₁₂ to form a condensed ring,

Z₁₁₁ may be a C₆-C₃₀ carbocyclic group that is unsubstituted or substituted with at least one R₁₀ₐ and has at least one functional group selected from C═O, C═S, C═Se, and C═Te, or a C₁-C₃₀ heterocyclic group that is unsubstituted or substituted with at least one R₁₀ₐ and has at least one functional group selected from C═O, C═S, C=Se, and C=Te, and

R₁₁₁ to R₁₁₆ may each independently be hydrogen, deuterium, a halogen, a cyano group, a nitro group, a hydroxy group, a C₁-C₃₀ alkyl group unsubstituted or substituted with at least one R₁₀ₐ, a C₁-C₃₀ alkoxy group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, a C₂-C₃₀ acyl group unsubstituted or substituted with at least one R₁₀ₐ, or any combination thereof,

R₁₀ₐ may be:

deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

Q₁₁ to Q₁₃, Q₂₁ to Q₂₃, Q₃₁, Q₃₂, Q₁₁₁, and Q₁₁₂ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, Z₁₁₁ of Formula 1 may be represented by any one selected from Formulae 111A to 111F:

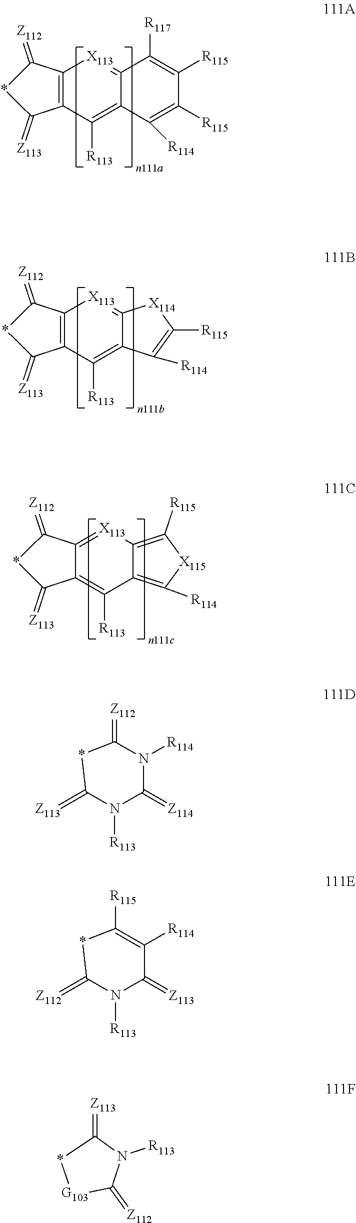

wherein, in Formulae 111A to 111F,

Z₁₁₂ to Z₁₁₄ may each be O, S, Se, or Te,

X₁₁₃ may be N or C(Q₁₁₃), and

X₁₁₄ and X₁₁₅ may each independently be O, S, Se, Te, Si(Q₁₁₁)(Q₁₁₂), or Ge(Q₁₁₁)(Q₁₁₂),

n₁₁₁ₐ to n_{111c} may each be an integer from 0 to 3,

R₁₁₃ to R₁₁₇ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof, and Q₁₁₁ to Q₁₁₃ are each as defined above in connection with Q₁₁₁.

In an embodiment, the p-type semiconductor compound may include any one of compounds of Groups 1 to 3:

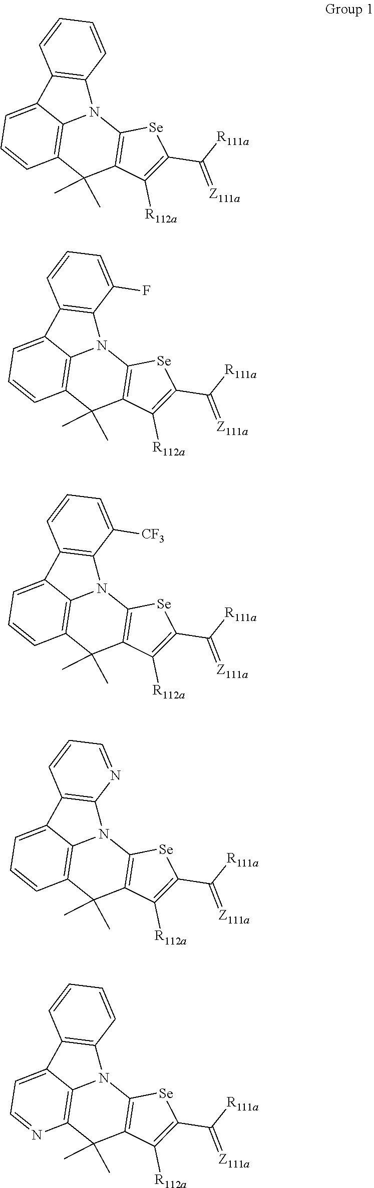

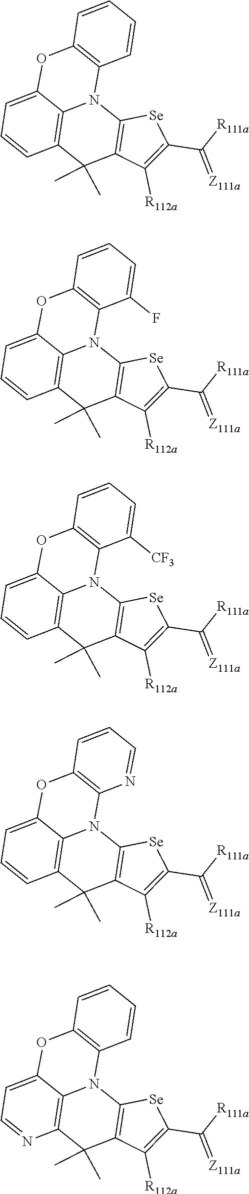

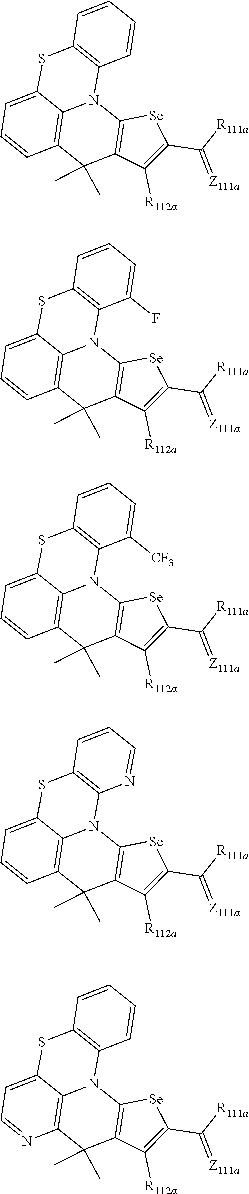

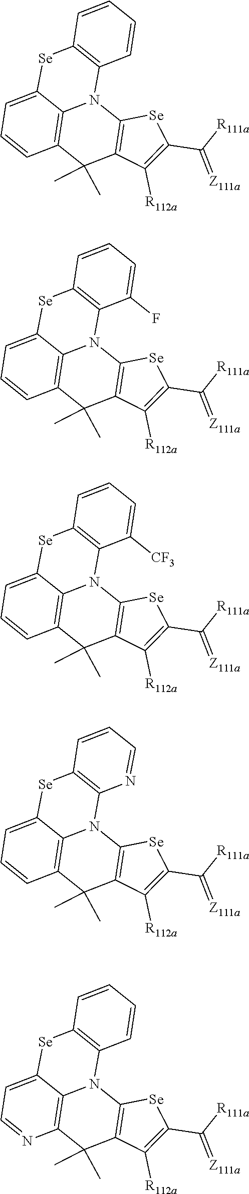

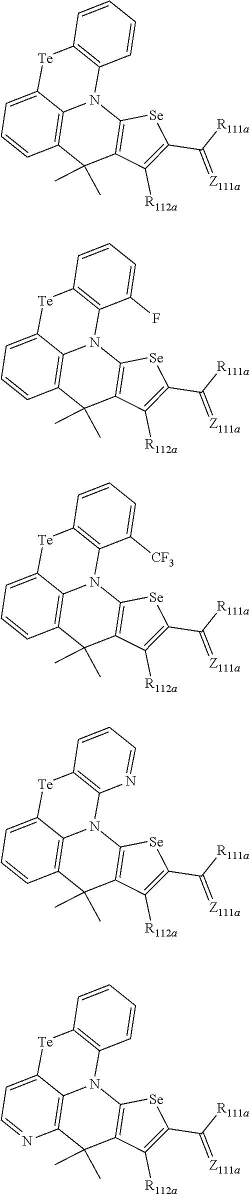

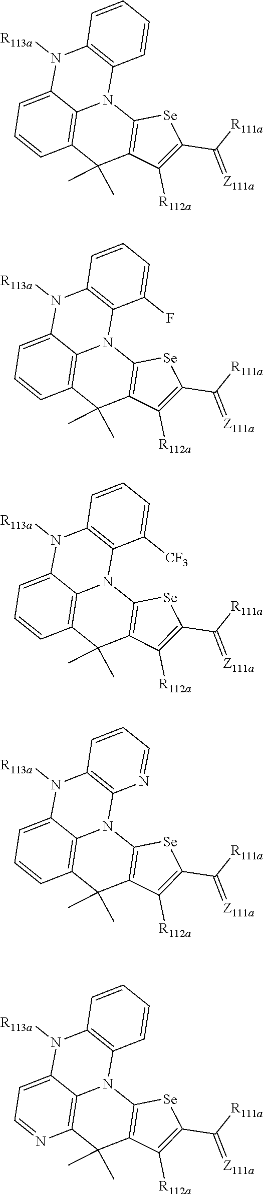

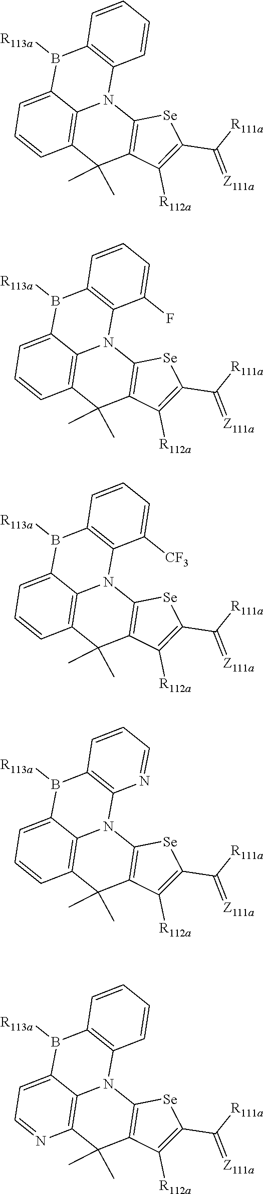

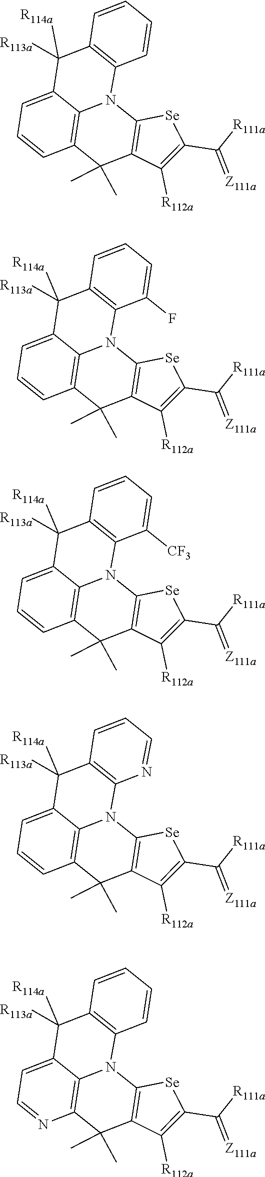

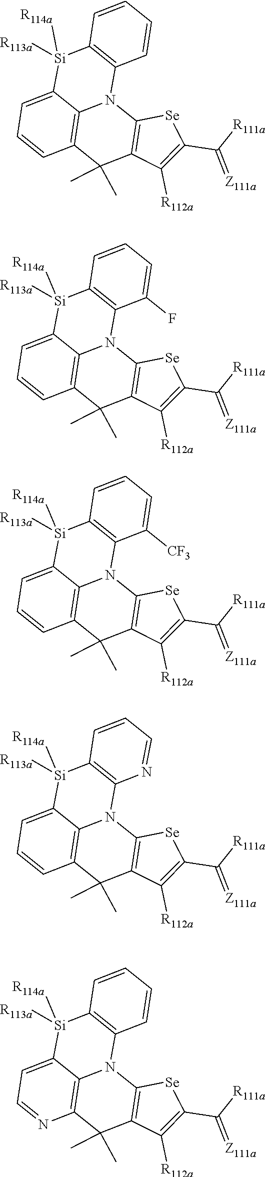

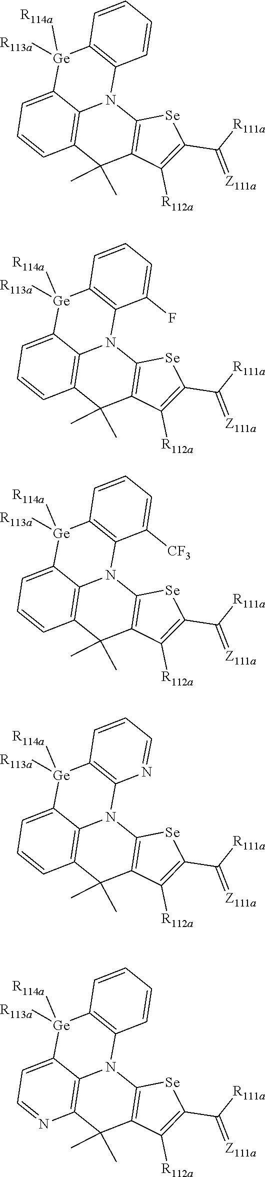

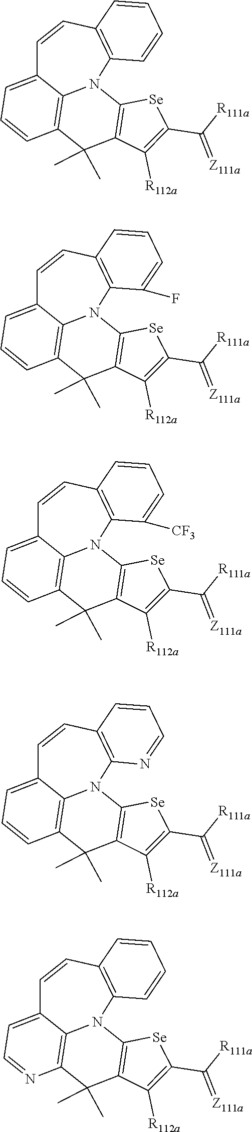

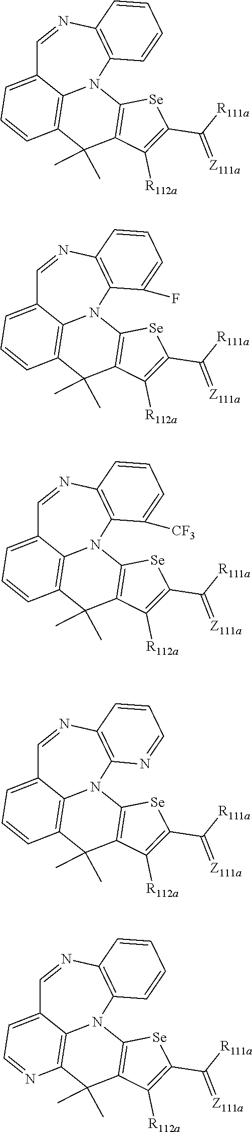

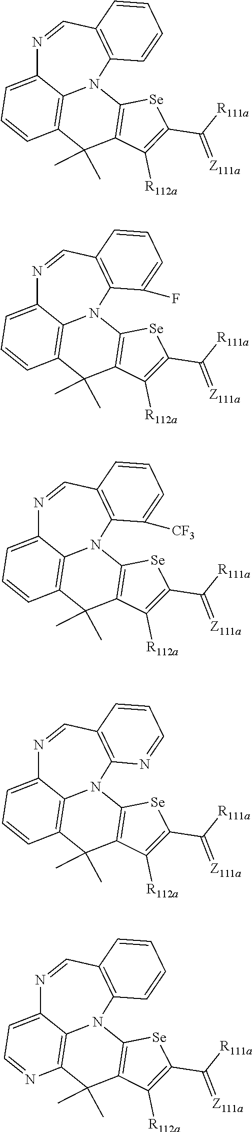

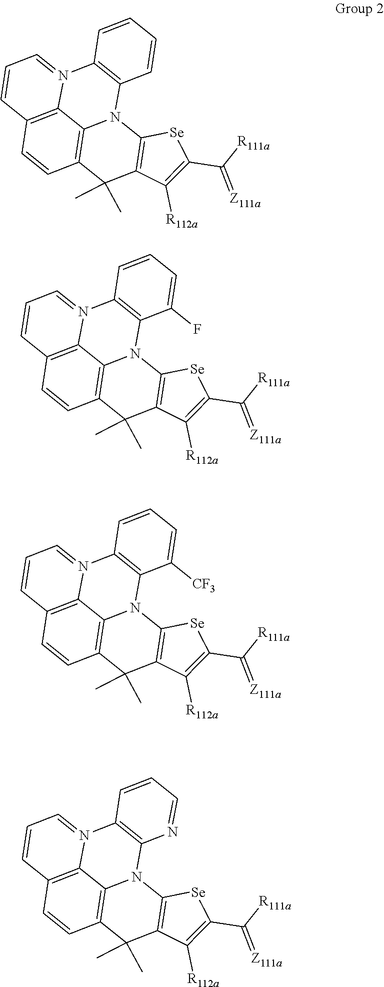

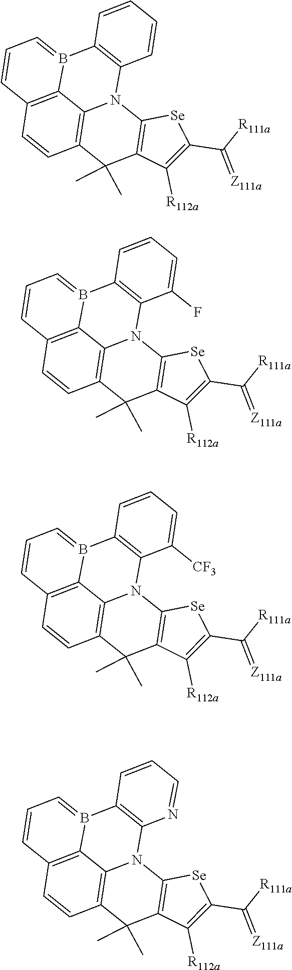

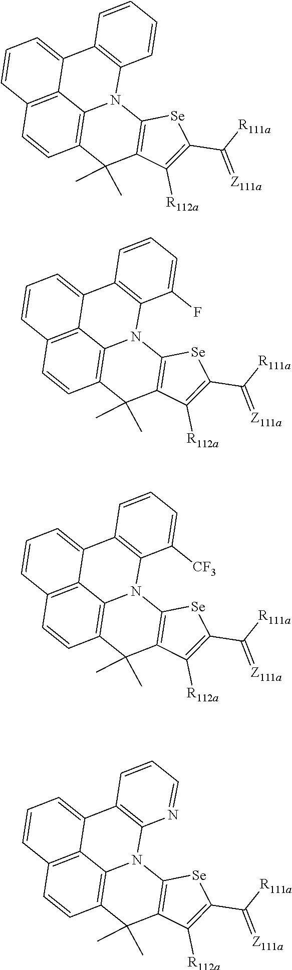

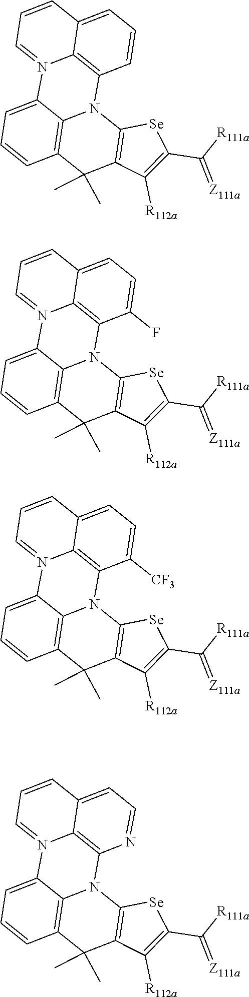

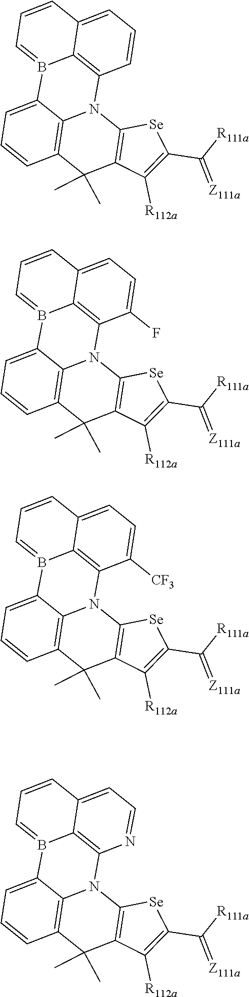

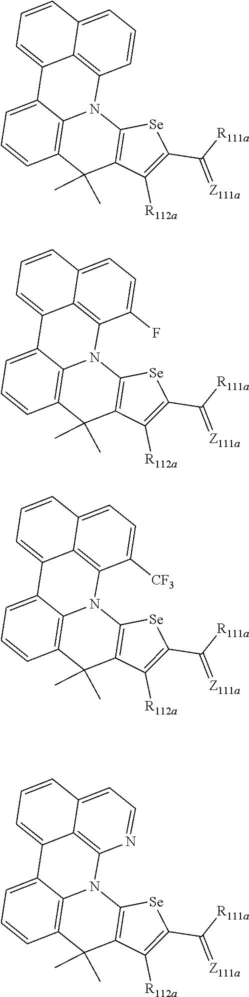

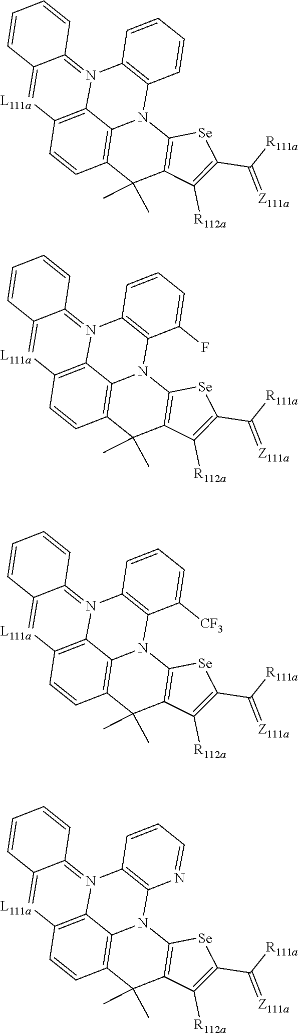

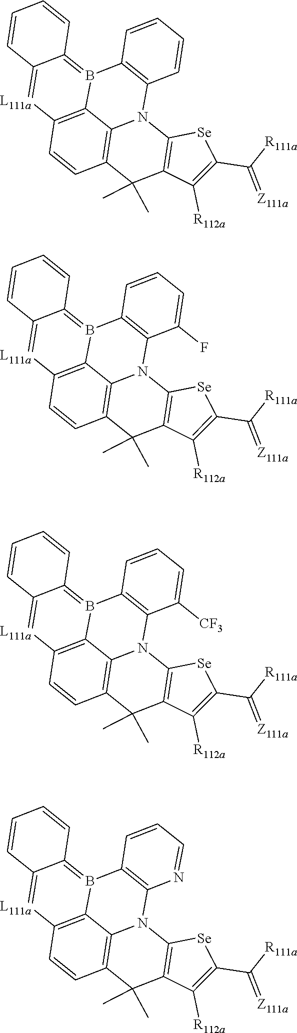

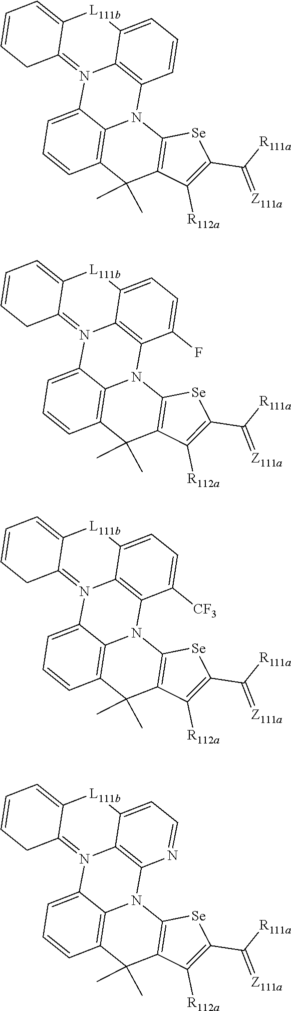

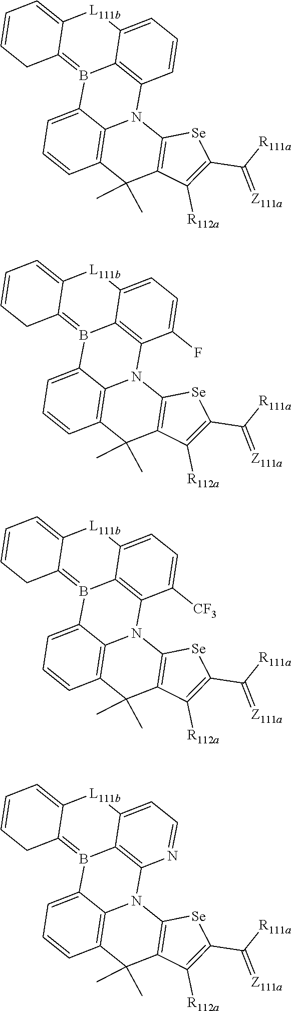

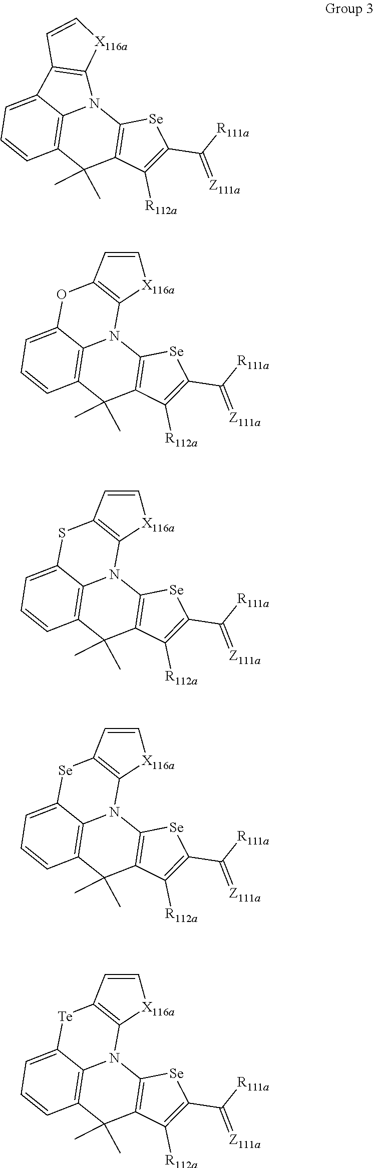

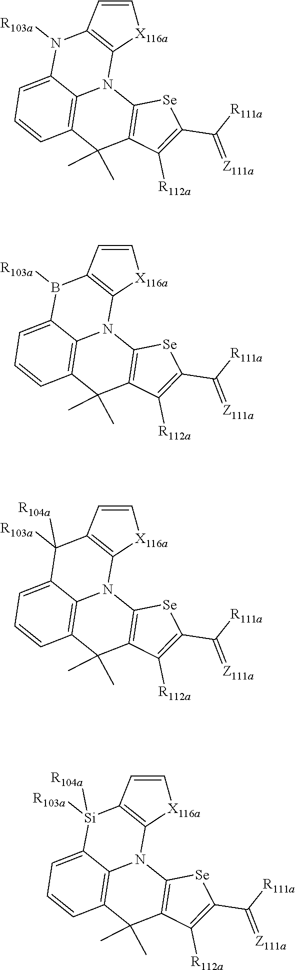

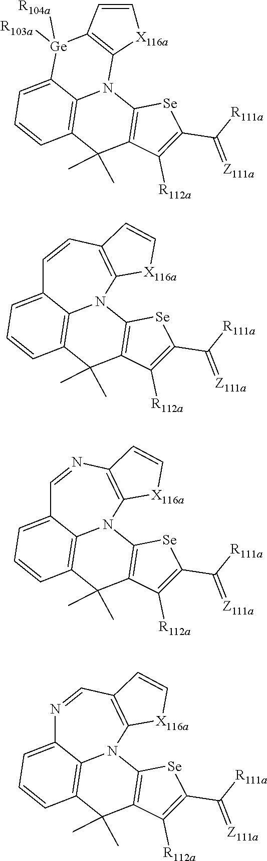

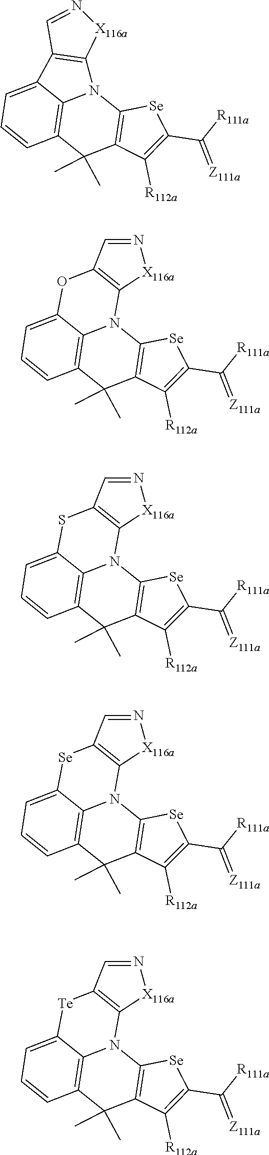

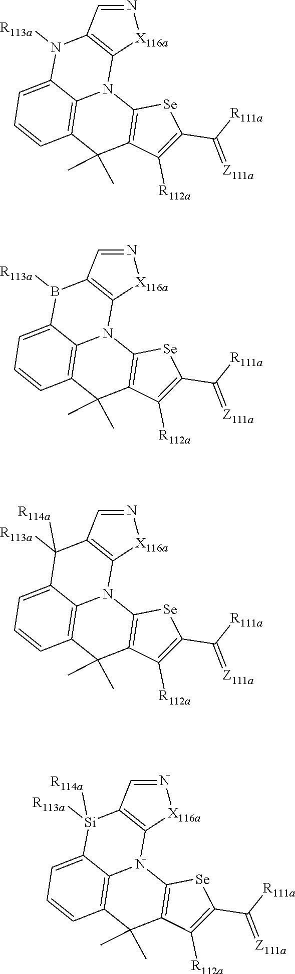

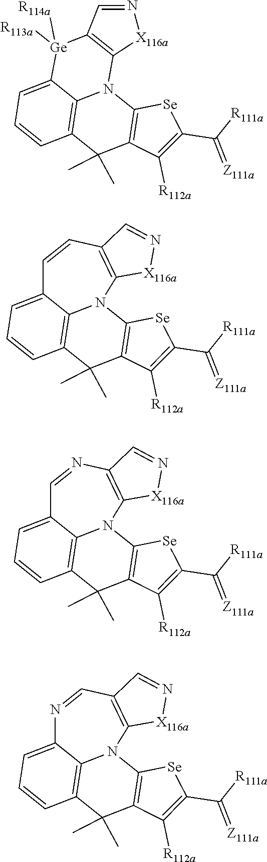

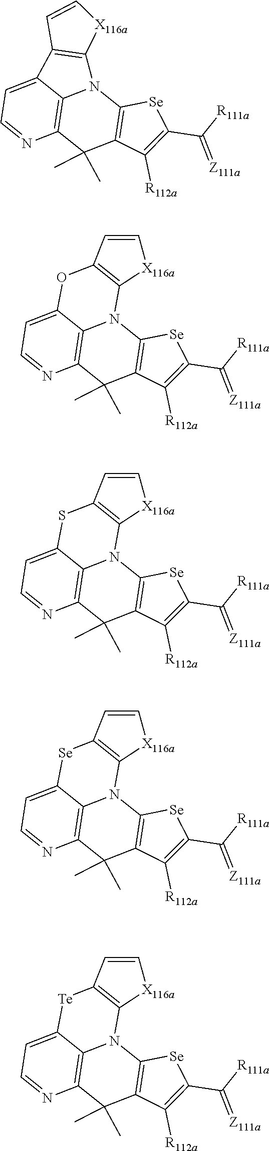

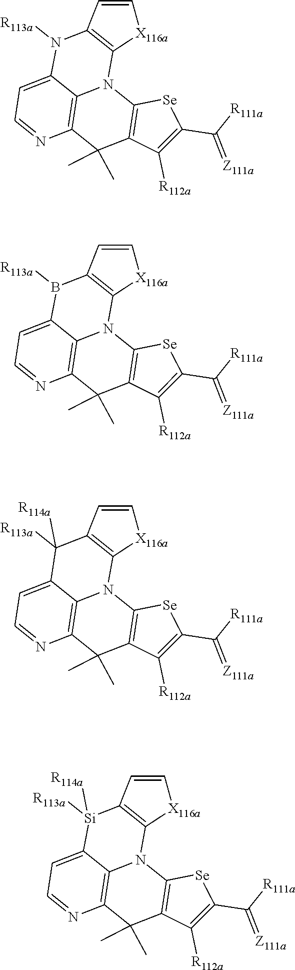

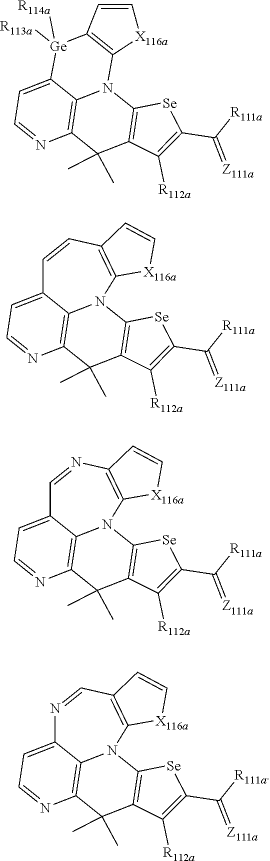

In the compounds of Groups 1 to 3,

R₁₁₁ₐ to R₁₁₄ₐ are each as defined in connection with R₁₁₁ of Formula 1,

Z₁₁₁ₐ is as defined in connection with Z₁₁₁ of Formula 1, and

X₁₁₆ₐ is as defined in connection with X₁₁₁ of Formula 1.

In an embodiment, the active layer may include a p-type semiconductor compound, and

The p-type semiconductor compound may include a compound represented by Formula 2:

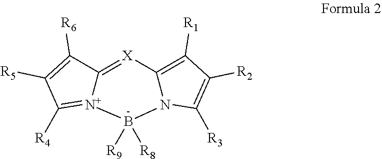

wherein, in Formula 2,

X may be CR₇ or N,

R₁ to R₉ may each independently be hydrogen, deuterium, a halogen, a cyano group, a nitro group, a hydroxy group, a C₁-C₃₀ alkyl group unsubstituted or substituted with at least one R₁₀ₐ, a C₁-C₃₀ alkoxy group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or any combination thereof,

At least one selected from R₈ and R₉ may include fluorine or a cyano group, R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

Q₁₁ to Q₁₃, Q₂₁ to Q₂₃, Q₃₁, Q₃₂, Q₁₁₁, and Q₁₁₂ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, the p-type compound may include any one selected from the following compounds:

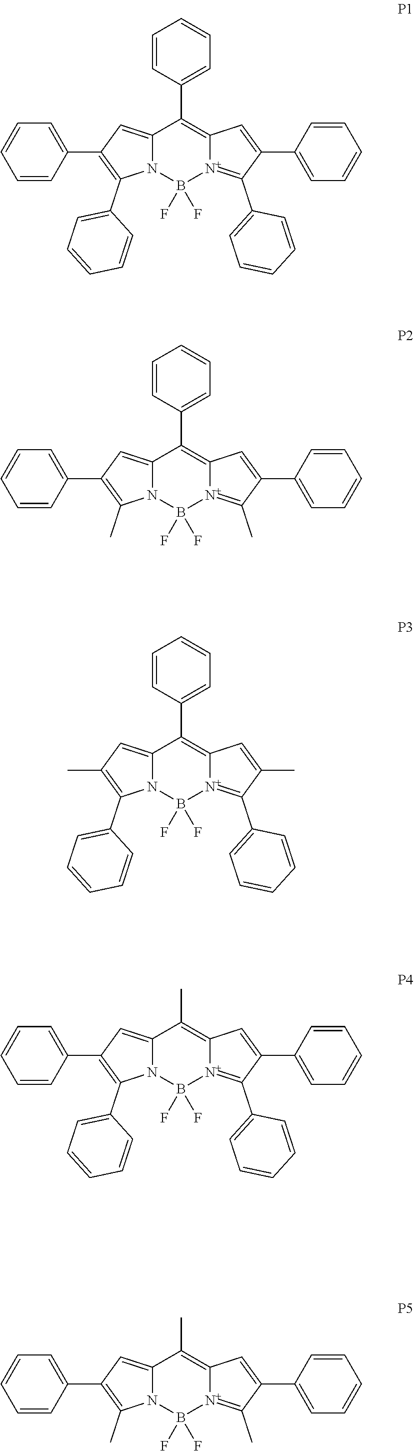

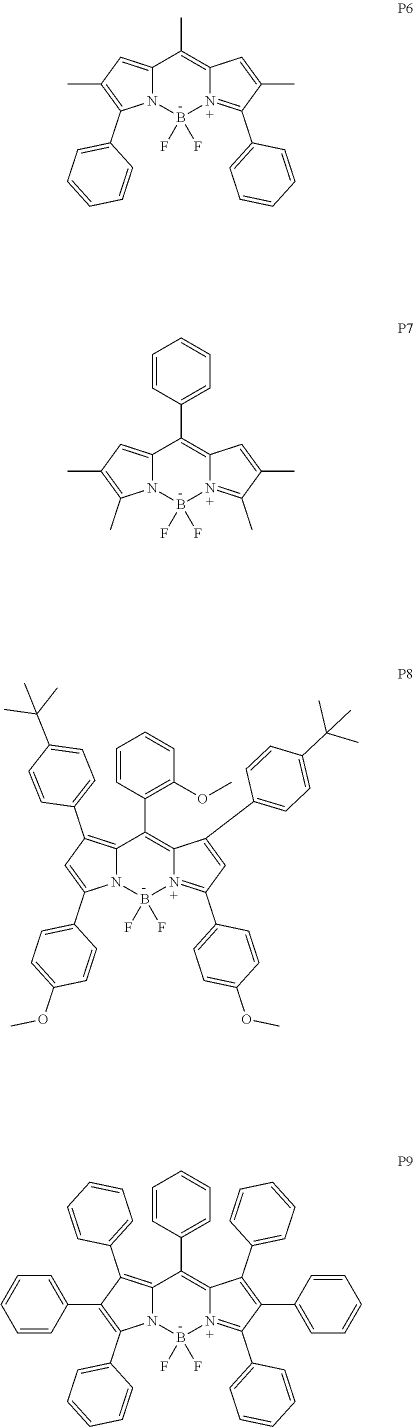

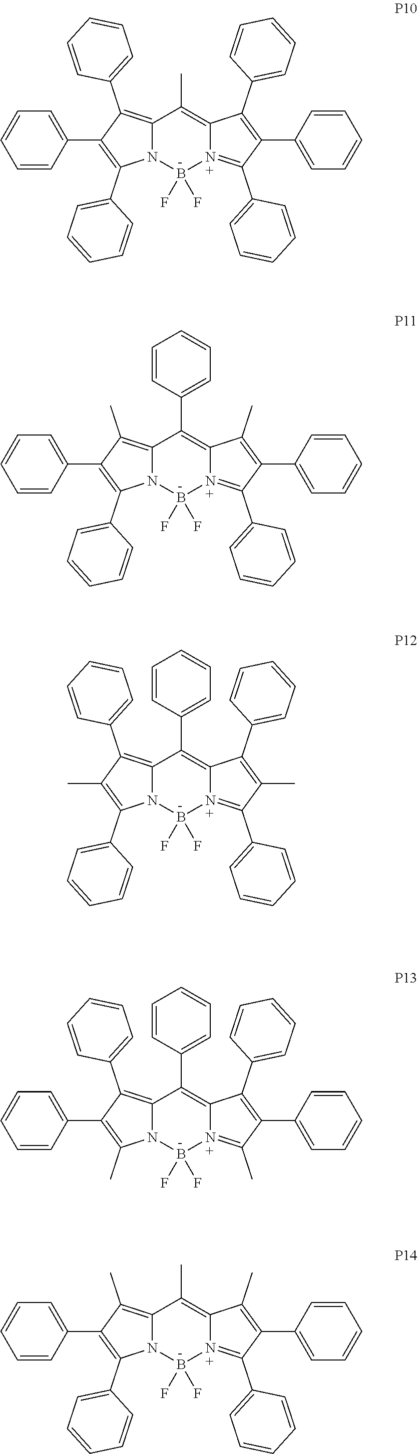

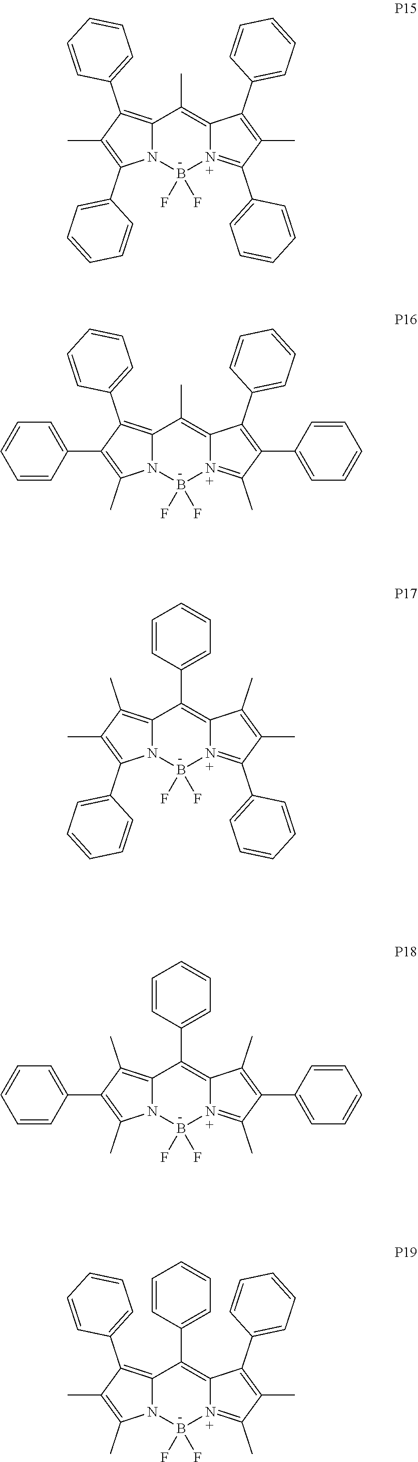

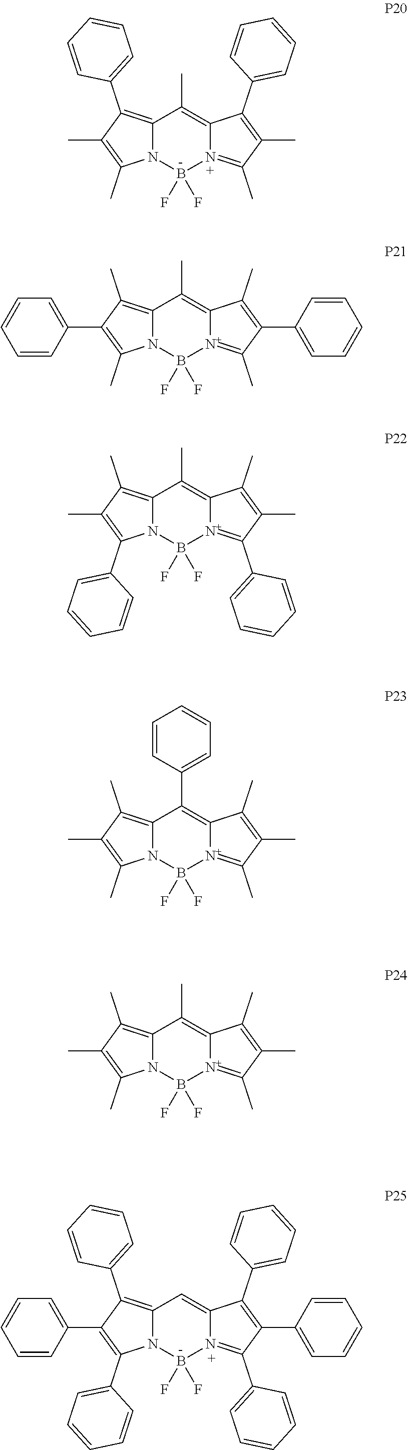

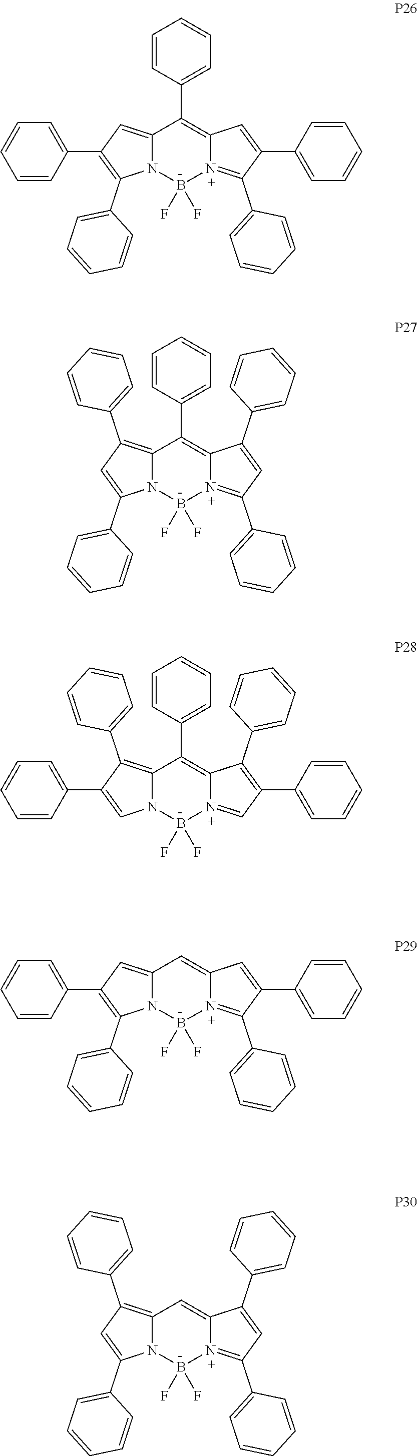

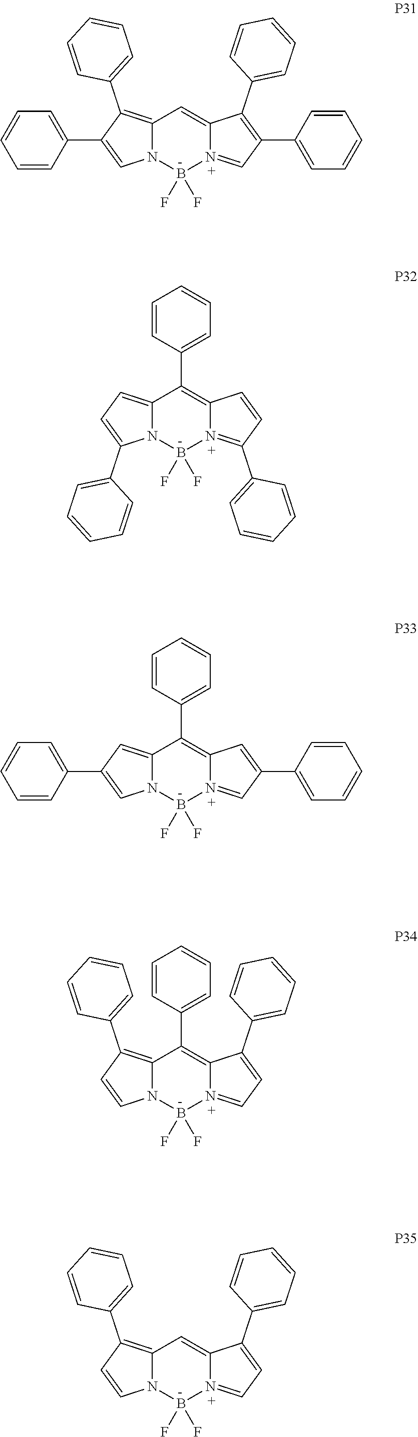

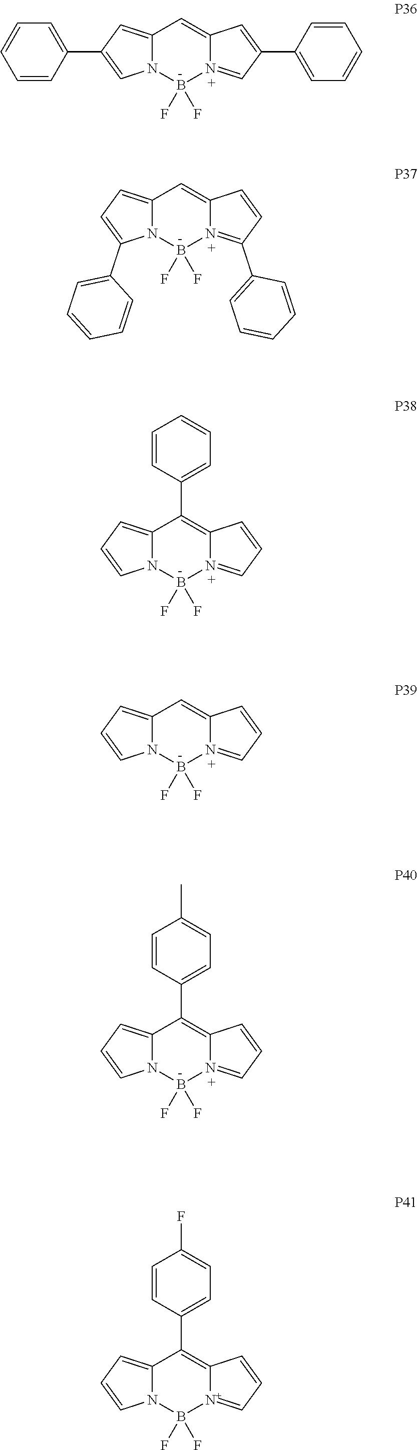

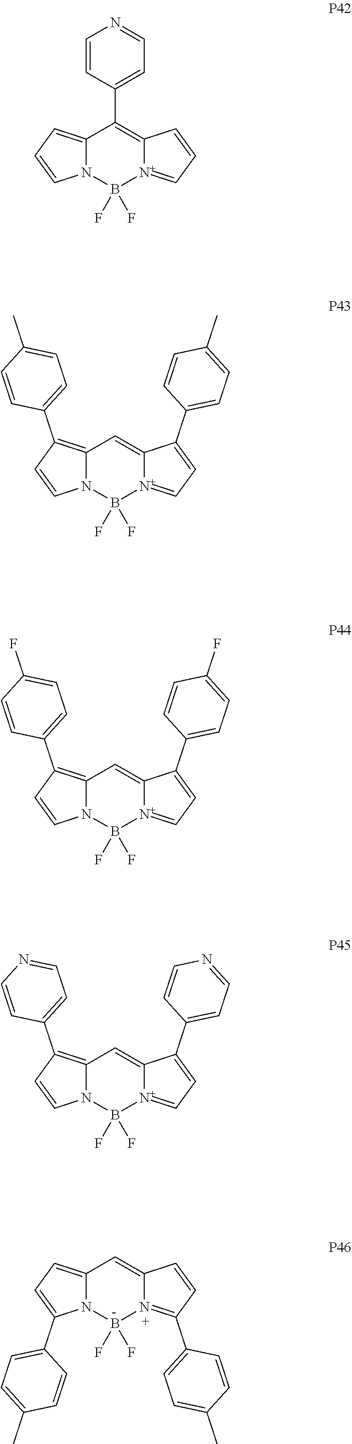

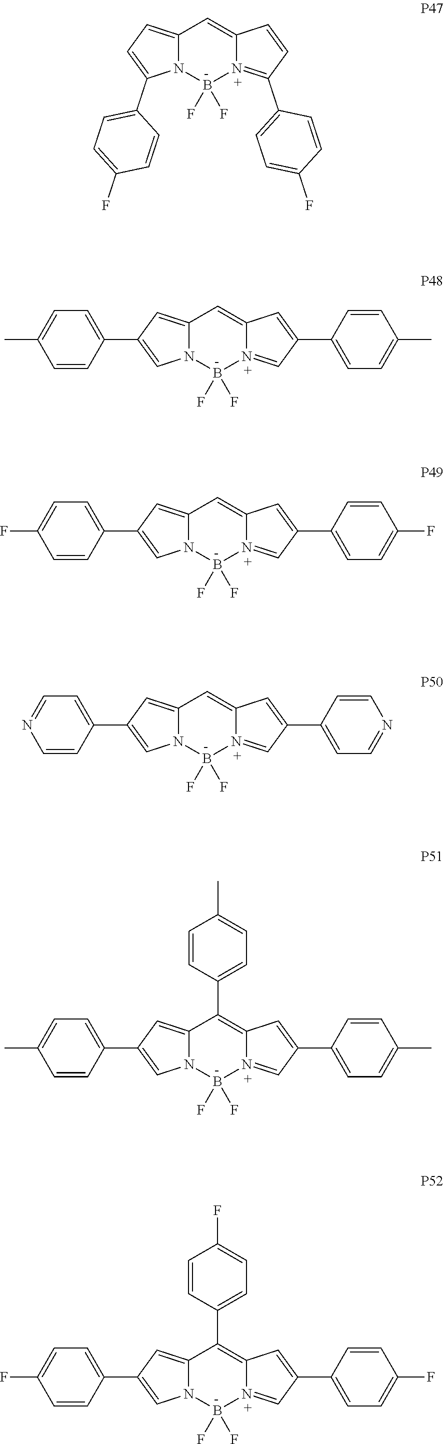

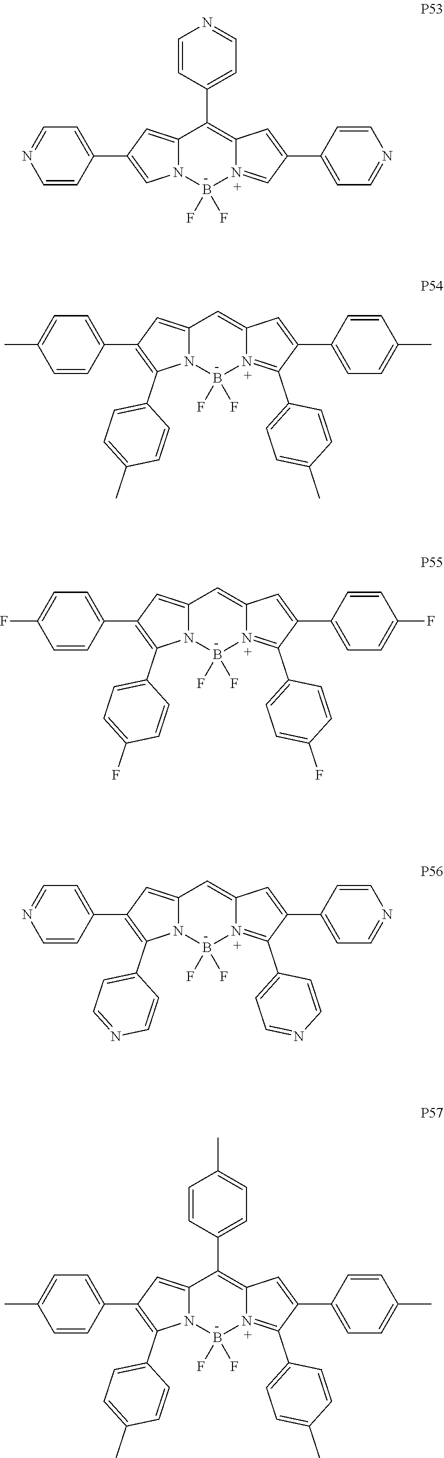

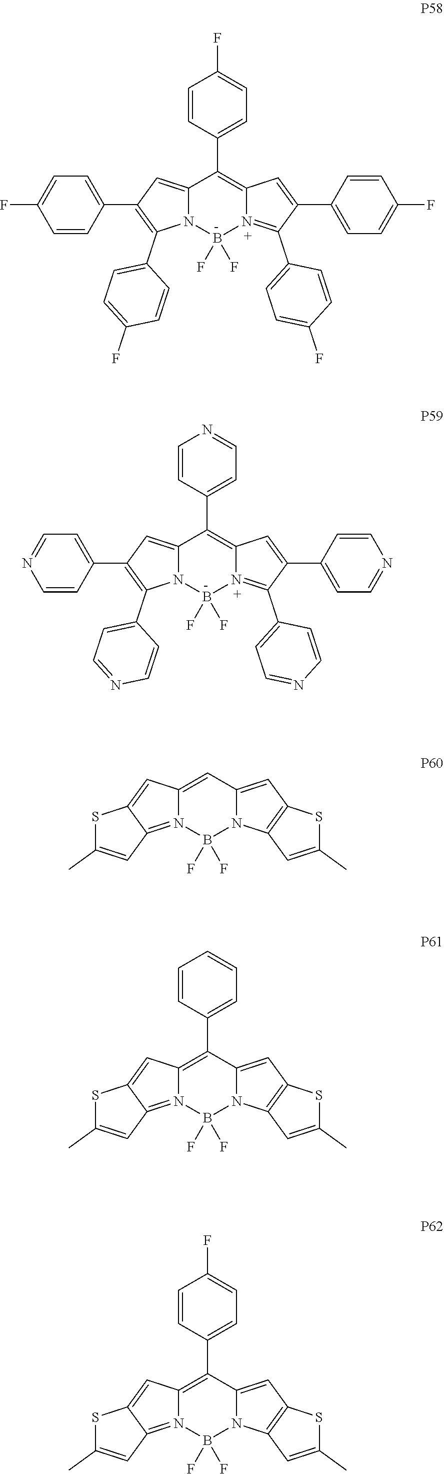

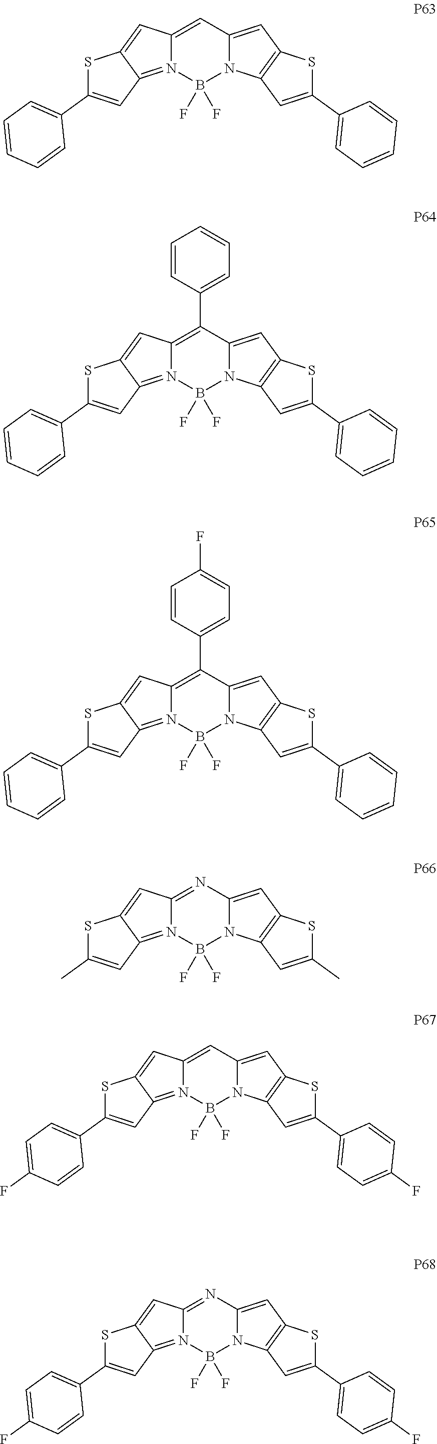

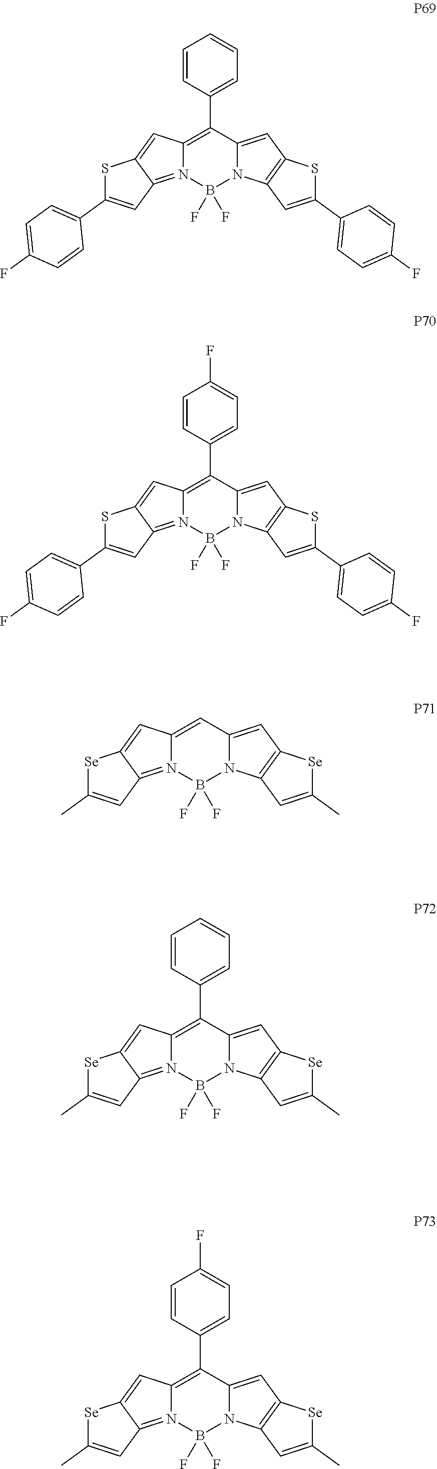

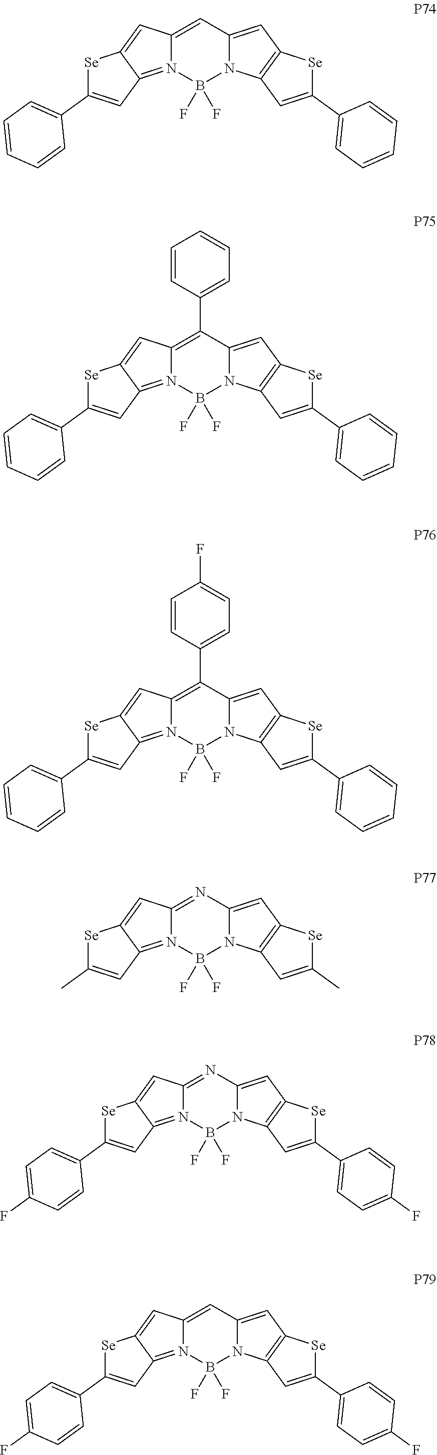

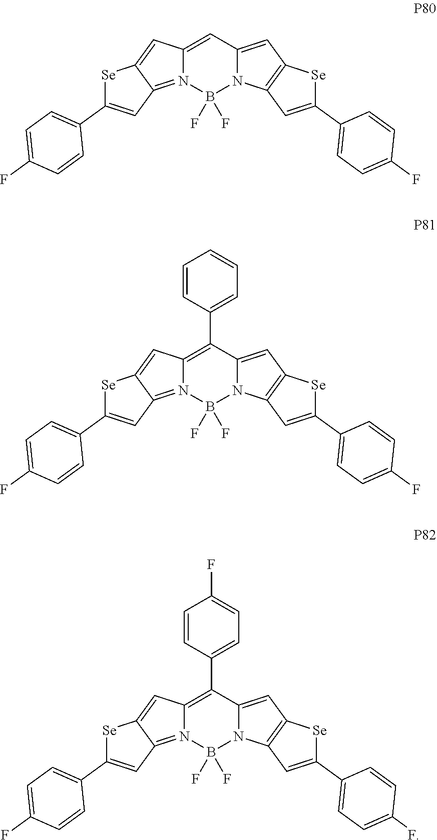

In an embodiment, the active layer may include an n-type semiconductor compound, and

the n-type semiconductor compound may include a compound represented by Formula 3 or 4:

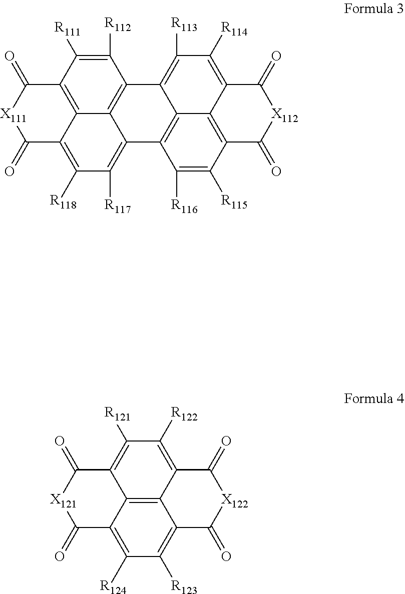

wherein, in Formula 3,

X₁₁₁ and X₁₁₂ may each independently be O or NR₁₁₉,

R₁₁₁ to R₁₁₉ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof, wherein, in Formula 4,

X₁₂₁ and X₁₂₂ may each independently be O or NR₁₂₅, and

R₁₂₁ to R₁₂₅ may each independently be hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof, wherein, in Formulae 3 and 4,

R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₅-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

Q₁₁ to Q₁₃, Q₂₁ to Q₂₃, Q₃₁, and Q₃₂ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group; a C₇-C₆₀ arylalkyl group; or a C₂-C₆₀ heteroarylalkyl group, each unsubstituted or substituted with deuterium,—F, a cyano group, a C₁-C₆₀ alkyl group, a C₁-C₆₀ alkoxy group, a phenyl group, a biphenyl group, or any combination thereof.

In an embodiment, the n-type compound may include any one selected from

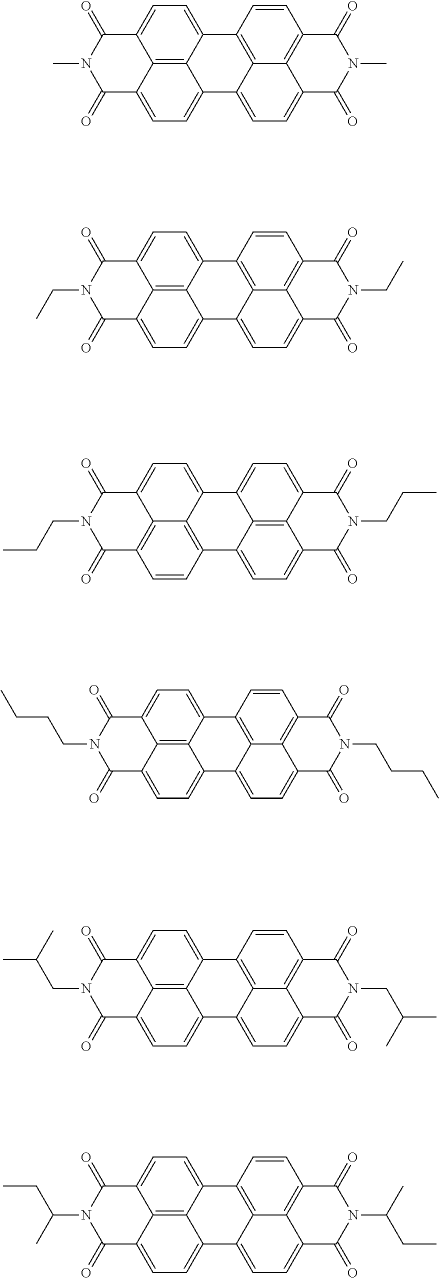

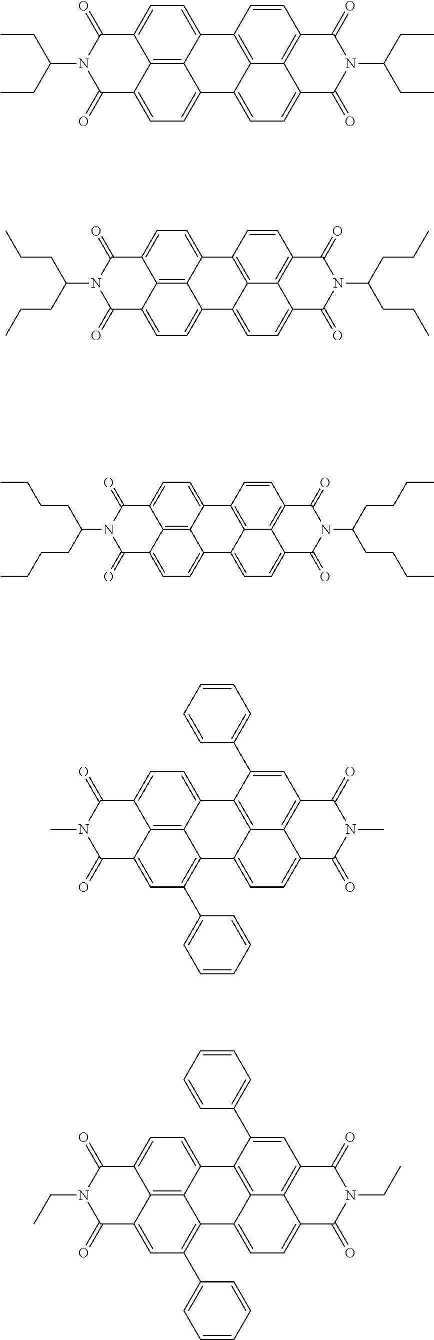

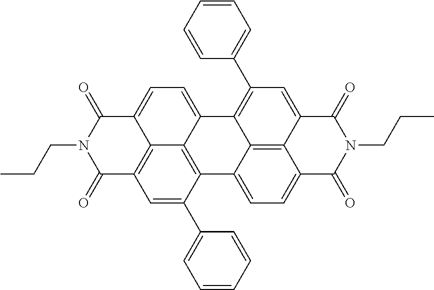 [SMILES: CCCN1C(=O)c2ccc3c4c(-c5ccccc5)cc5c6c(ccc(c7c(-c8ccccc8)cc(c2c37)C1=O)c64)C(=O)N(CCC)C5=O]

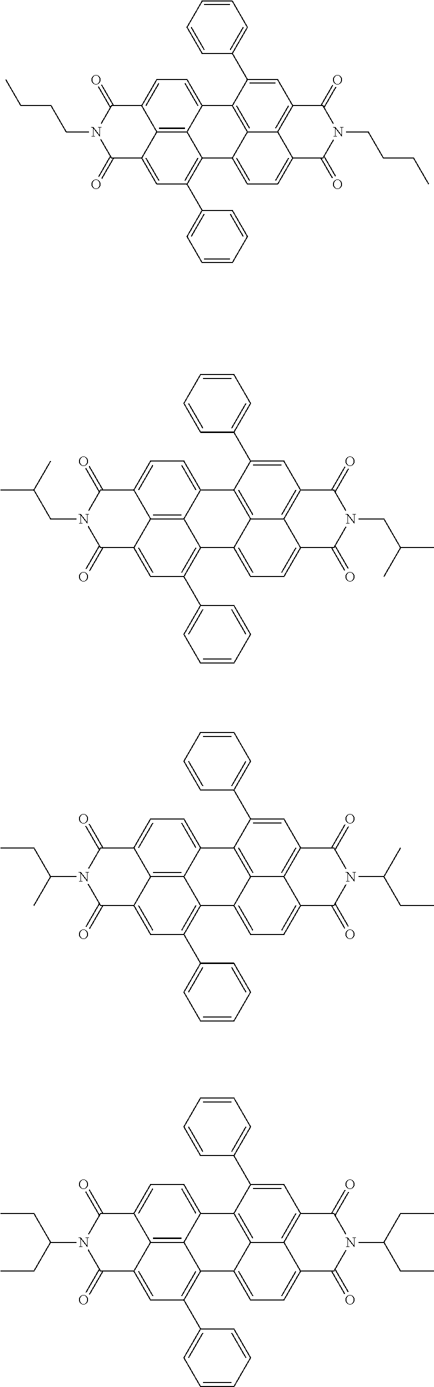

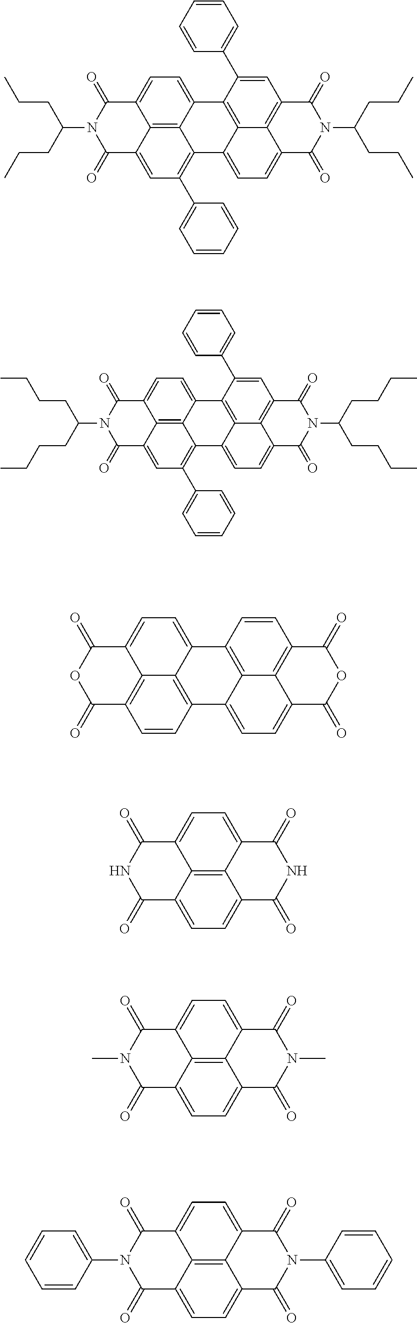

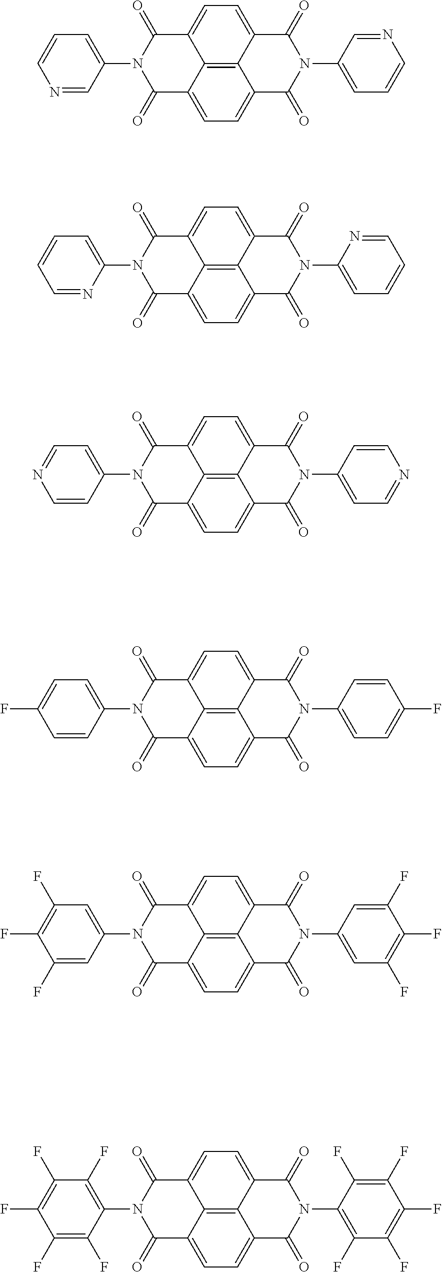 [SMILES: O=C1c2ccc3c4c(ccc(c24)C(=O)N1c1cccnc1)C(=O)N(c1cccnc1)C3=O ; O=C1c2ccc3c4c(ccc(c24)C(=O)N1c1ccccn1)C(=O)N(c1ccccn1)C3=O ; O=C1c2ccc3c4c(ccc(c24)C(=O)N1c1ccncc1)C(=O)N(c1ccncc1)C3=O ; O=C1c2ccc3c4c(ccc(c24)C(=O)N1c1ccc(F)cc1)C(=O)N(c1ccc(F)cc1)C3=O ; O=C1c2ccc3c4c(ccc(c24)C(=O)N1c1cc(F)c(F)c(F)c1)C(=O)N(c1cc(F)c(F)c(F)c1)C3=O ; O=C1c2ccc3c4c(ccc(c24)C(=O)N1c1c(F)c(F)c(F)c(F)c1F)C(=O)N(c1c(F)c(F)c(F)c(F)c1F)C3=O]

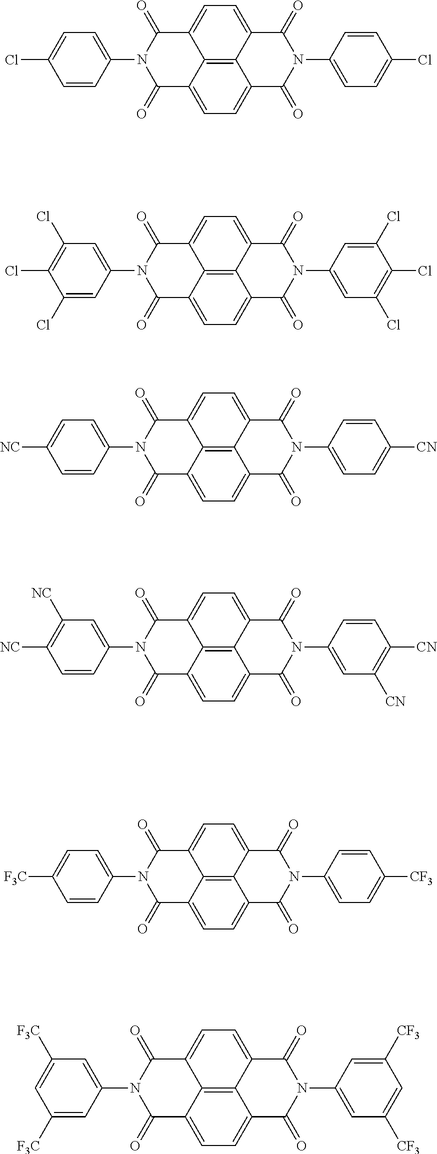 [SMILES: O=C1c2ccc3c4c(ccc(c24)C(=O)N1c1ccc(Cl)cc1)C(=O)N(c1ccc(Cl)cc1)C3=O ; O=C1c2ccc3c4c(ccc(c24)C(=O)N1c1cc(Cl)c(Cl)c(Cl)c1)C(=O)N(c1cc(Cl)c(Cl)c(Cl)c1)C3=O ; N#Cc1ccc(N2C(=O)c3ccc4c5c(ccc(c35)C2=O)C(=O)N(c2ccc(C#N)cc2)C4=O)cc1 ; N#Cc1ccc(N2C(=O)c3ccc4c5c(ccc(c35)C2=O)C(=O)N(c2ccc(C#N)c(C#N)c2)C4=O)cc1C#N ; O=C1c2ccc3c4c(ccc(c24)C(=O)N1c1ccc(C(F)(F)F)cc1)C(=O)N(c1ccc(C(F)(F)F)cc1)C3=O ; O=C1c2ccc3c4c(ccc(c24)C(=O)N1c1cc(C(F)(F)F)cc(C(F)(F)F)c1)C(=O)N(c1cc(C(F)(F)F)cc(C(F)(F)F)c1)C3=O]

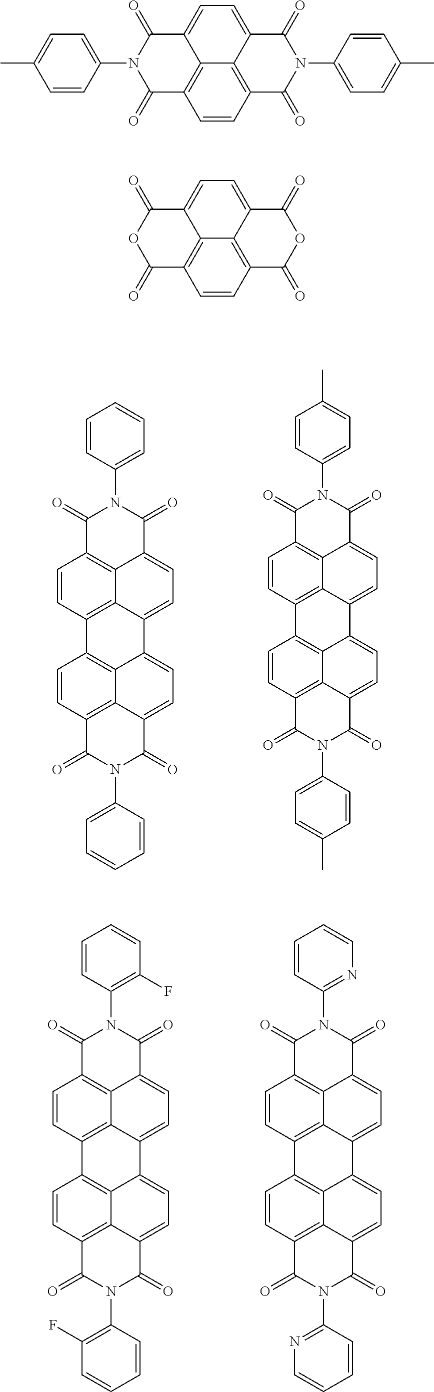

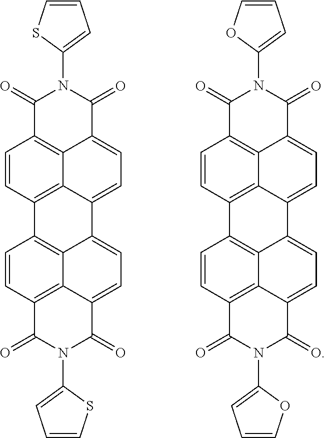 [SMILES: O=C1c2ccc3c4ccc5c6c(ccc(c7ccc(c2c37)C(=O)N1c1cccs1)c64)C(=O)N(c1cccs1)C5=O ; O=C1c2ccc3c4ccc5c6c(ccc(c7ccc(c2c37)C(=O)N1c1ccco1)c64)C(=O)N(c1ccco1)C5=O]

### Manufacturing Method

Respective layers included in the hole transport region, the emission layer, the active layer, and respective layers included in the electron transport region may be formed in a set or certain region by using one or more suitable methods selected from vacuum deposition, spin coating, casting, Langmuir-Blodgett (LB) method, ink-jet printing, laser-printing, and laser-induced thermal imaging (LITI).

When layers constituting the hole transport region, an emission layer, and layers constituting the electron transport region are formed by vacuum deposition, the deposition may be performed at a deposition temperature of about 100° C. to about 500° C., a vacuum degree of about 10-8 torr to about 10-3 torr, and a deposition speed of about 0.01 Å/sec to about 100 Å/sec, depending on a material to be included in a layer to be formed and the structure of a layer to be formed.

When layers constituting the hole transport region, an emission layer, and layers constituting the electron transport region are formed by spin coating, the spin coating may be performed at a coating speed of about 2,000 rpm to about 5,000 rpm and at a heat treatment temperature of about 80° C. to about 200° C. by taking into account a material to be included in a layer to be formed and the structure of a layer to be formed.

### Definition of Terms

The term “C₃-C₆₀ carbocyclic group” as used herein refers to a cyclic group consisting of carbon only as a ring-forming atom and having three to sixty carbon atoms, and the term “C₁-C₆₀ heterocyclic group” as used herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed together with each other. For example, the C₁-C₆₀ heterocyclic group has 3 to 61 ring-forming atoms.

The “cyclic group” as used herein may include the C₃-C₆₀ carbocyclic group, and the C₁-C₆₀ heterocyclic group.

The term “π electron-rich C₃-C₆₀ cyclic group” as used herein refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

For example, the C₃-C₆₀ carbocyclic group may be i) Group T1 or ii) a condensed cyclic group in which two or more Groups T1 are condensed together with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) Group T2, ii) a condensed cyclic group in which two or more Groups T2 are condensed together with each other, or iii) a condensed cyclic group in which at least one Group T2 and at least one Group T1 are condensed together with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

the π electron-rich C₃-C₆₀ cyclic group may be i) Group T1, ii) a condensed cyclic group in which two or more Groups T1 are condensed together with each other, iii) Group T3, iv) a condensed cyclic group in which two or more Groups T3 are condensed with each other, or v) a condensed cyclic group in which at least one Group T3 and at least one Group T1 are condensed together with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),

the π electron-deficient nitrogen-containing C₁-C₆₀ cyclic group may be i) Group T4, ii) a condensed cyclic group in which two or more Groups T4 are condensed together with each other, iii) a condensed cyclic group in which at least one Group T4 and at least one Group T1 are condensed together with each other, iv) a condensed cyclic group in which at least one Group T4 and at least one Group T3 are condensed together with each other, or v) a condensed cyclic group in which at least one Group T4, at least one Group T1, and at least one Group T3 are condensed together with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

Group T3 may be a furan group, a thiophene group, a 1H-pyrrole group, a silole group, or a borole group, and

Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the IT electron-deficient nitrogen-containing C₁-C₆₀ cyclic group” as used herein refer to a group condensed to any cyclic group, a monovalent group, or a polyvalent group (for example, a divalent group, a trivalent group, a tetravalent group, etc.) according to the structure of a formula for which the corresponding term is used. For example, the “benzene group” may be a benzo group, a phenyl group, a phenylene group, or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group are a C₅-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the divalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has one to sixty carbon atoms, and specific examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having substantially the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof are an ethenyl group, a propenyl group, and a butenyl group. The term “C₂-C₆₀ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof include an ethynyl group, a propynyl group, and the like. The term “C₂-C₆₀ alkynylene group” as used herein refers to a divalent group having substantially the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group” as used herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom, as ring-forming atoms, and examples are a 1,2,3,4-oxatriazolidinyl group, a tetrahydrofuranyl group, and a tetrahydrothiophenyl group. The term “C₁-C₁₀ heterocycloalkylene group” as used herein refers to a divalent group having substantially the same structure as the C₁-C₁₀ heterocycloalkyl group.

The term C₃-C₁₀ cycloalkenyl group used herein refers to a monovalent cyclic group that has three to ten carbon atoms and at least one carbon-carbon double bond in the ring thereof and no aromaticity (e.g., is not aromatic), and examples thereof are a cyclopentenyl group, a cyclohexenyl group, and a cycloheptenyl group. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having substantially the same structure as the C₁-C₁₀ heterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the rings may be condensed together with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed together with each other.

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure (e.g., is not aromatic when considered as a whole). Examples of the monovalent non-aromatic condensed polycyclic group are an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having substantially the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure (e.g., is not aromatic when considered as a whole). Examples of the monovalent non-aromatic condensed heteropolycyclic group are a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphtho silolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having substantially the same structure as the monovalent non-aromatic condensed heteropolycyclic group described above.

The term “C₆-C₆₀ aryloxy group” as used herein indicates —OA₁₀₂ (wherein A₁₀₂ is a C₆-C₆₀ aryl group), and the term “C₆-C₆₀ arylthio group” as used herein indicates —SA₁₀₃ (wherein A₁₀₃ is a C₆-C₆₀ aryl group).

The term “C₇-C₆₀ arylalkyl group” used herein refers to -A₁₀₄A₁₀₅ (where A₁₀₄ may be a C₁-C₅₄ alkylene group, and A₁₀₅ may be a C₆-C₅₉ aryl group), and the term C₂-C₆₀ heteroarylalkyl group” used herein refers to -A₁₀₆A₁₀₇ (where A₁₀₆ may be a C₁-C₅₉ alkylene group, and A₁₀₇ may be a C₁-C₅₉ heteroaryl group).

The term “R₁₀ₐ” as used herein refers to:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃ and Q₃₁ to Q₃₃ used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium,—F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as used herein refers to any suitable atom other than a carbon atom. Examples of the heteroatom are O, S, N, P, Si, B, Ge, Se, and any combinations thereof.

The term “the third-row transition metal” used herein includes hafnium (Hf), tantalum (Ta), tungsten (W), rhenium (Re), osmium (Os), iridium (Ir), platinum (Pt), gold (Au), etc.

The term “Ph”, as used herein, refers to a phenyl group, the term “Me” refers to a methyl group, the term “Et” refers to an ethyl group, the term “ter-Bu” or “But” refers to a tert-butyl group, and the term “OMe” refers to a methoxy group.

The term “biphenyl group” as used herein refers to “a phenyl group substituted with a phenyl group.” In other words, the “biphenyl group” is a substituted phenyl group having a C₆-C₆₀ aryl group as a substituent.

The term “terphenyl group” as used herein refers to “a phenyl group substituted with a biphenyl group”. In other words, the “terphenyl group” is a substituted phenyl group having, as a substituent, a C₆-C₆₀ aryl group substituted with a C₆-C₆₀ aryl group.

The number of carbon atoms in the substituent definition is an example. For example, in the C₁-C₆₀ alkyl group, the number of carbon atoms, 60, is an example, and the definition for the alkyl group is equally applied to the C₁-C₂₀ alkyl group. The same applies to other embodiments.

In the compound structure of the present disclosure, any hydrogen may optionally be substituted with deuterium.

* and *′ as used herein, unless defined otherwise, each refer to a binding site to a neighboring atom in a corresponding formula.

Hereinafter, a compound and light-emitting device according to embodiments will be described in more detail with reference to Examples.

### EXAMPLES

### Manufacture of Light-Emitting Device

### Example

Referring to FIG. 4, a 115 Ω/cm² ITO/Ag/ITO (120 Å/500 Å/120 Å) glass substrate (product of Corning Inc.) on which the first pixel electrode, the 2-1 pixel electrode, the 2-2 pixel electrode, and the 2-3 pixel electrode are individually formed was sonicated with isopropyl alcohol and pure water for 5 minutes, and then cleaned by exposure to ultraviolet rays and ozone for 15 minutes. Then, the ITO/Ag/ITO glass substrate was provided to a vacuum deposition apparatus.

HT-1 was deposited on the first pixel electrode, the 2-1 pixel electrode, the 2-2 pixel electrode, and the 2-3 pixel electrode to commonly form a hole transport layer having a thickness of 300 Å.

Then, without forming auxiliary layers, a first emission unit (1), a second emission unit (1), and a third emission unit (1) were formed by forming an RGB emission layer per each subpixel in an emission region.

Red emission layer (1)—Host 1: RD (2%, 400 Å)

Green emission layer (1)—Host 1: Ir (ppy)₃ (10%, 300 Å)

Blue emission layer (1)—Host 1: BD (10%, 300 Å)

Host 1 was a mixed host of H129 and H130 (5:5).

In a light detection region, Compound 1 was deposited to a thickness of 100 Å, and then N14 was deposited to a thickness of 300 Å to form an active layer (1).

ET-1 was deposited to a thickness of 300 Å on the RGB emission layer and the active layer (1) to commonly form an electron transport layer. Subsequently, CG1 and Li were co-deposited at a weight ratio of 99:1 on the electron transport layer to commonly form an n-type charge generation layer (n-CGL) having a thickness of 50 Å, and HATCN was deposited on the n-type charge generation layer to commonly form a p-type charge generation layer (p-CGL) having a thickness of 50 Å.

HT-1 was deposited on the p-CGL to commonly form a hole transport layer having a thickness of 500 Å.

Then, without forming auxiliary layers, a first emission unit (2), a second emission unit (2), and a third emission unit (2) were formed by forming an RGB emission layer per each subpixel in an emission region.

Red emission layer (2)—Host 1: RD (2%, 400 Å)

Green emission layer (2)—Host 1: Ir (ppy) 3 (10%, 300 Å)

Blue emission layer (2)—Host 1: BD (10%, 300 Å) Host 1 was a mixed host of H129 and H130 (5:5).

In a light detection region, Compound P1 was deposited to a thickness of 100 Å, and then Compound N14 was deposited to a thickness of 300 Å to form an active layer (2).

Next, BAlq was vacuum-deposited thereon to commonly form a buffer layer having a thickness of 50 Å, and ET1 was vacuum-deposited on the buffer layer to commonly form an electron transport layer having a thickness of 300 Å.

Then, Ag and Mg were co-deposited to a thickness of 100 Å at a weight ratio of 9:1 to commonly form a cathode, and a capping layer having a thickness of 700 Å was commonly formed by CPL to manufacture a light-emitting device having a tandem structure and an organic photodetector having a tandem structure.

### Comparative Example

As in the Example, after forming a first emission unit (1), a second emission unit (1), a third emission unit (1), and an active layer (1), BAlq was vacuum-deposited to commonly form a buffer layer having a thickness of 50 Å, and ET-1 was vacuum-deposited on the buffer layer to commonly form an electron transport layer having a thickness of 300 Å.

Then, an electronic apparatus including a light-emitting device having a single structure and an organic photodetector having a single structure was manufactured in the same manner as in the Example, except for the feature that Ag and Mg were co-deposited to a thickness of 100 Å at a weight ratio of 9:1 to commonly form a cathode, and a capping layer having a thickness of 700 Å was commonly formed by CPL.

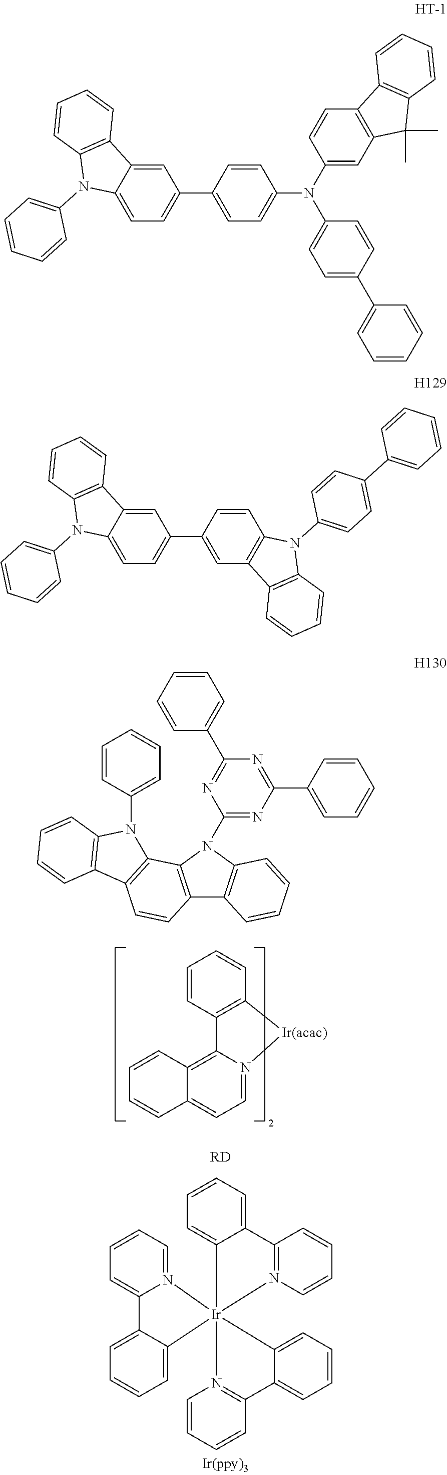

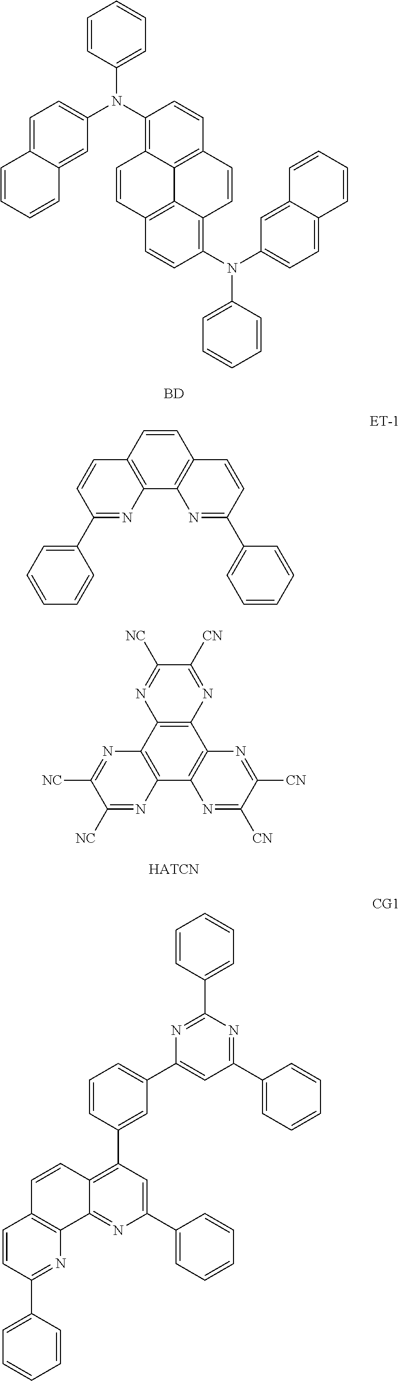

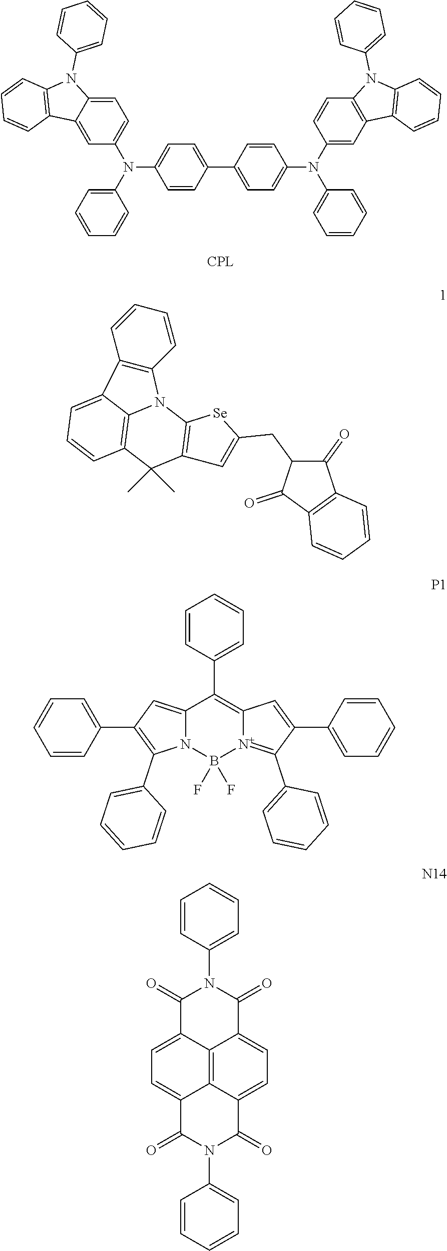

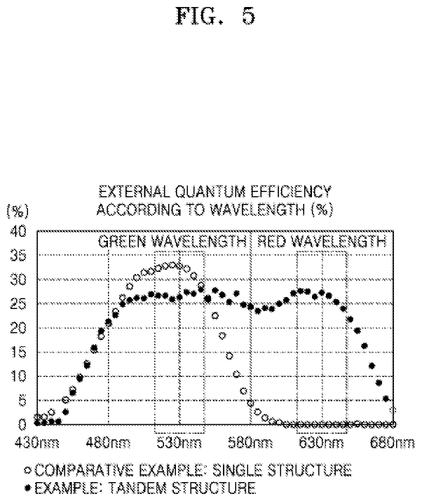

The external quantum efficiency (EQE) according to a wavelength was measured with respect to the organic photodetectors of the electronic apparatuses in the Example and the Comparative Example, and the results thereof are shown in FIG. 5.

Referring to FIG. 5, it can be seen that the organic photodetector of the electronic apparatus of the Example has an absorption peak wavelength of about 530±50 nm and about 630±50 nm, and the organic photodetector of the electronic apparatus of Comparative Example has an absorption peak wavelength of about 530±50 nm.

Referring to FIG. 5, it is can also be seen that the FWHM of the organic photodetector of the electronic apparatus of the Example increased more significantly than that of the Comparative Example did.

In addition, compared to the Comparative Example, a 70% increase in the photo-current with respect to green light and red light of the organic photodetector of the electronic apparatus of the Example was observed, which corresponds to the fact that the sum of areas at the absorption peak wavelength of about 530±50 nm and about 630±50 nm is significantly greater in the Example than in the Comparative Example.

Although the Example does not include an auxiliary layer, when the auxiliary layer is included, the auxiliary layer O′ of the organic light detection unit (1) may be co-deposited with the auxiliary layer R′ of the first emission unit (1) of the same material, and the auxiliary layer O′ of the organic light detection unit (2) may be co-deposited with the auxiliary layer G′ of the second emission unit (2) of the same material, which lead to increased efficiency in the deposition process.

An electronic apparatus according to an embodiment may have improved sensing sensitivity.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and equivalents thereof.

What is claimed is:

1. An electronic apparatus comprising:
a substrate comprising a light detection region and an emission region;
an organic photodetector on the light detection region; and
a light-emitting device on the emission region,
wherein the organic photodetector comprises a first pixel electrode, a counter electrode facing the first pixel electrode, m organic light detection units each comprising an active layer between the first pixel electrode and the counter electrode, and m−1 charge generation layers between two adjacent organic light detection units among the m organic light detection units,
the light-emitting device comprises:
a 2-1 pixel electrode, the counter electrode facing the 2-1 pixel electrode, m first emission units comprising an emission layer between the 2-1 pixel electrode and the counter electrode, and m−1 charge generation layers between two adjacent first emission units among the m first emission units,
a 2-2 pixel electrode, the counter electrode facing the 2-2 pixel electrode, m second emission units comprising an emission layer between the 2-2 pixel electrode and the counter electrode, and m−1 charge generation layers between two adjacent second emission units among the m second emission units,
a 2-3 pixel electrode, the counter electrode facing the 2-3 pixel electrode, m third emission units comprising an emission layer between the 2-3 pixel electrode and the counter electrode, and m−1 charge generation layers between two adjacent third emission units among the m third emission units,
m is an integer of 2 or more,
the m first emission units emit a first color light, the m second emission units emit a second color light, the m third emission units emit a third color light, the first to third color lights have different colors from each other,
the m organic light detection units absorb different colors of light from each other,
the first pixel electrode and the active layers are provided in correspondence with the light detection region,
the 2-1 to 2-3 pixel electrodes and the emission layers are provided in correspondence with the emission region, and
the m−1 charge generation layers and the counter electrode are provided for the entirety of the light detection region and the emission region.

2. The electronic apparatus of claim 1, wherein an organic photodetector from among the m organic light detection units comprises a hole transport region between the first pixel electrode and the counter electrode.

3. The electronic apparatus of claim 2, wherein the organic photodetector further comprises an electron transport region.

4. The electronic apparatus of claim 1, wherein an emission unit from among the m first emission units comprises a hole transport region between the 2-1 pixel electrode and the counter electrode,
an emission unit from among the m second emission units comprises a hole transport region between the 2-2 pixel electrode and the counter electrode, or
an emission unit from among the m third emission units comprises a hole transport region between the 2-3 pixel electrode and the counter electrode.

5. The electronic apparatus of claim 4, wherein the emission unit from among the m first emission units, the emission unit from among the m second emission units, or the emission unit from among the m third emission units further comprises an electron transport region.

6. The electronic apparatus of claim 2, wherein the hole transport region comprises a hole injection layer, a hole transport layer, an electron blocking layer, an auxiliary layer, or any combination thereof.

7. The electronic apparatus of claim 3, wherein the electron transport region comprises a buffer layer, a hole blocking layer, an electron transport layer, an electron injection layer, or any combination thereof.

8. The electronic apparatus of claim 2, wherein the hole transport region comprises a hole transport layer, and the hole transport layer is provided for the entirety of the light detection region and the emission region.

9. The electronic apparatus of claim 3, wherein the electron transport region comprises a buffer layer and/or an electron transport layer, and the buffer layer and/or the electron transport layer are provided for the entirety of the light detection region and the emission region.

10. The electronic apparatus of claim 1, wherein the first to third color lights are each independently any one selected from red light, green light, and blue light.

11. The electronic apparatus of claim 1, wherein m is 2, and each of the two organic light detection units of the organic photodetector absorbs red light or green light, absorbs red light or blue light, or absorbs green light or blue light, or m is 3, and each of the three organic light detection units of the organic photodetector absorbs red light, green light, or blue light.

12. The electronic apparatus of claim 1, wherein each of the m−1 charge generation layers comprises an n-type charge generation layer and a p-type charge generation layer.

13. The electronic apparatus of claim 1, wherein the active layer comprises: a layer including a p-type semiconductor compound; and a layer including an n-type semiconductor compound.

14. The electronic apparatus of claim 1, wherein the active layer comprises a p-type semiconductor compound, and
the p-type semiconductor compound comprises a compound represented by Formula 1: 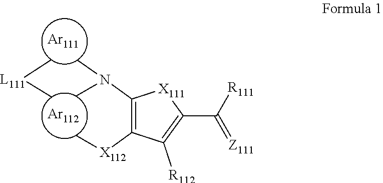
wherein, in Formula 1,
Ar₁₁₁ and Ar₁₁₂ are each independently a C₆-C₃₀ arylene group unsubstituted or substituted with at least one R₁₀ₐ or a C₃-C₃₀ heteroarylene group unsubstituted or substituted with at least one R₁₀ₐ,
X₁₁₁ is selected from —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, and -Ge(Q₁₁₁)(Q₁₁₂)-,
X₁₁₂ and L₁₁₁ are each selected from —O—, —S—, —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))—, and —(C(Q₁₁₁)=N))—,
when L₁₁₁ is selected from —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))—, and —(C(Q₁₁₁)=N))—, L₁₁₁ is optionally linked to Ar₁₁₁ or Ar₁₁₂ to form a condensed ring,
Z₁₁₁ is a C₆-C₃₀ carbocyclic group that is unsubstituted or substituted with at least one R₁₀ₐ and has at least one functional group selected from C═O, C═S, C=Se, and C=Te, or is a C₁-C₃₀ heterocyclic group that is unsubstituted or substituted with at least one R₁₀ₐ and has at least one functional group selected from C—O, C═S, C=Se, and C=Te,
R₁₁₁ to R₁₁₆ are each independently hydrogen, deuterium, a halogen, a cyano group, a nitro group, a hydroxy group, a C₁-C₃₀ alkyl group unsubstituted or substituted with at least one R₁₀ₐ, a C₁-C₃₀ alkoxy group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, a C₂-C₃₀ acyl group unsubstituted or substituted with at least one R₁₀ₐ, or any combination thereof,
R₁₀ₐ is:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, Q₃₁, Q₃₂, Q₁₁₁, and Q₁₁₂ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₅-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium,—F, a cyano group, a C₁-C₆₀ alkyl group, a C₁-C₆₀ alkoxy group, a phenyl group, a biphenyl group, or any combination thereof.

15. The electronic apparatus of claim 14, wherein Z₁₁₁ of Formula 1 is represented by any one of Formulae 111A to 111F: 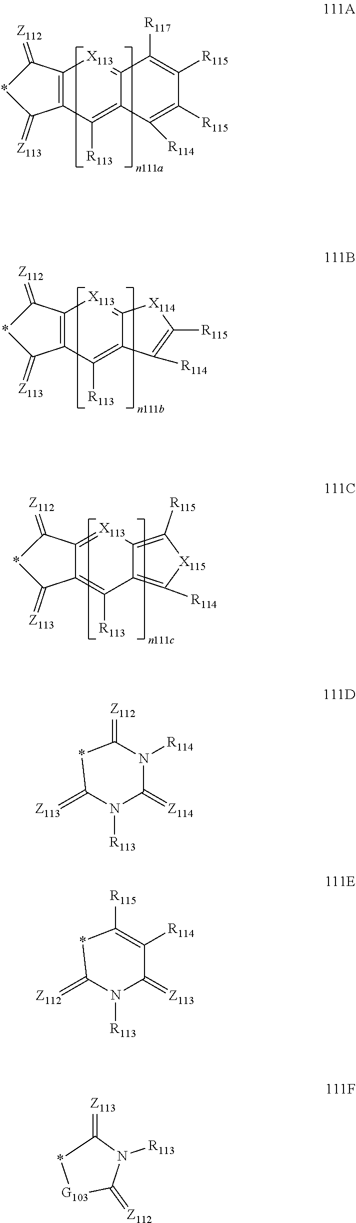
wherein, in Formulae 111A to 111F,
Z₁₁₂ to Z₁₁₄ are each O, S, Se, or Te,
X₁₁₃ is N or C(Q₁₁₃),
X₁₁₄ and X₁₁₅ are each independently O, S, Se, Te, Si(Q₁₁₁)(Q₁₁₂), or Ge(Q₁₁₁)(Q₁₁₂),
n₁₁₁ₐ to n_{111c} are each an integer from 0 to 3,
R₁₁₃ to R₁₁₇ are each independently hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof, and
Q₁₁₁ to Q₁₁₃ are each as defined in connection with Q₁₁₁ in claim 14.

16. The electronic apparatus of claim 14, wherein the p-type semiconductor compound comprises any one of compounds of Groups 1 to 3: 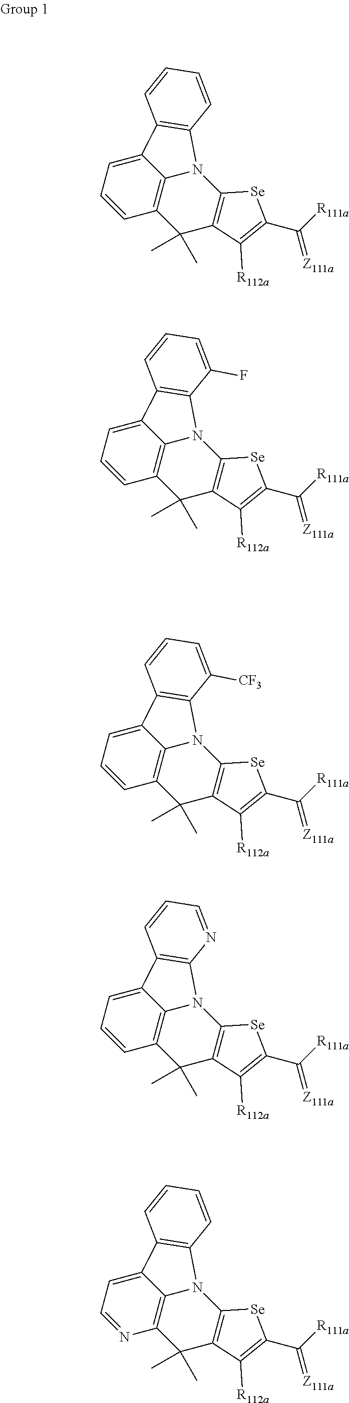 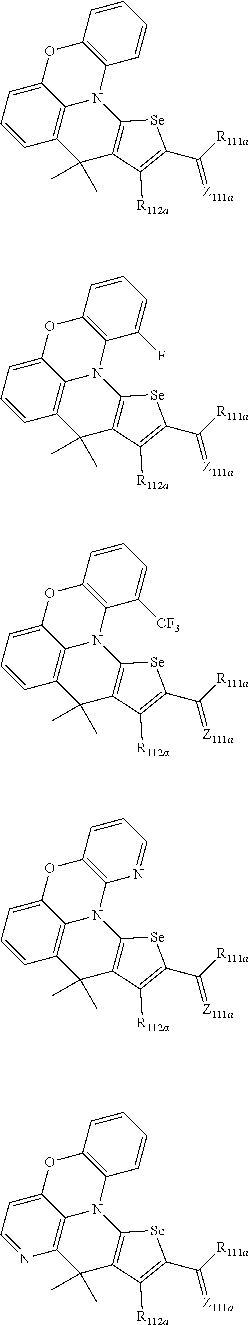 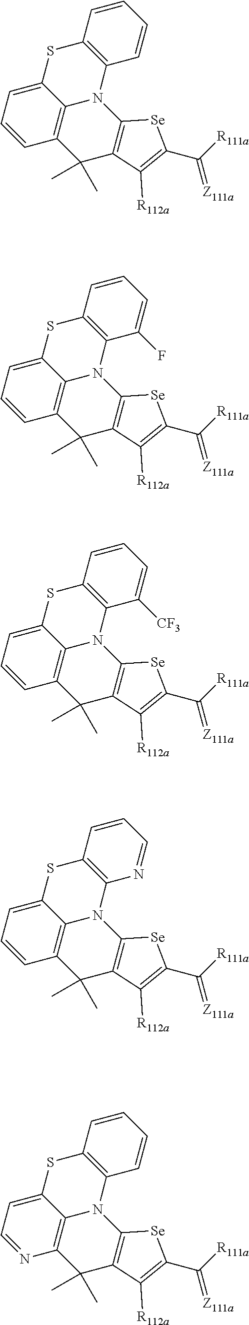 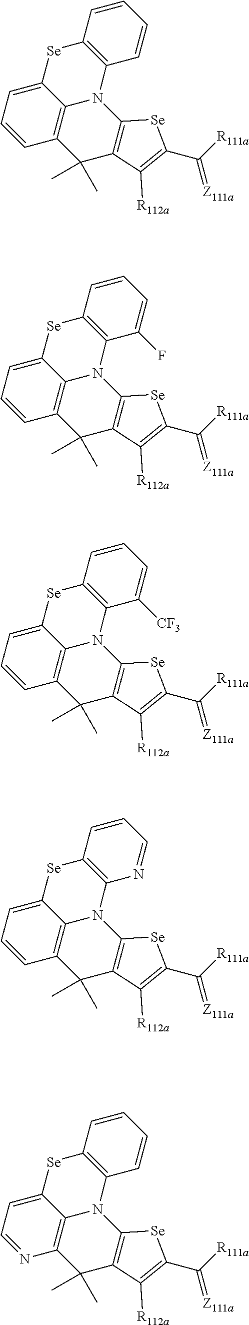 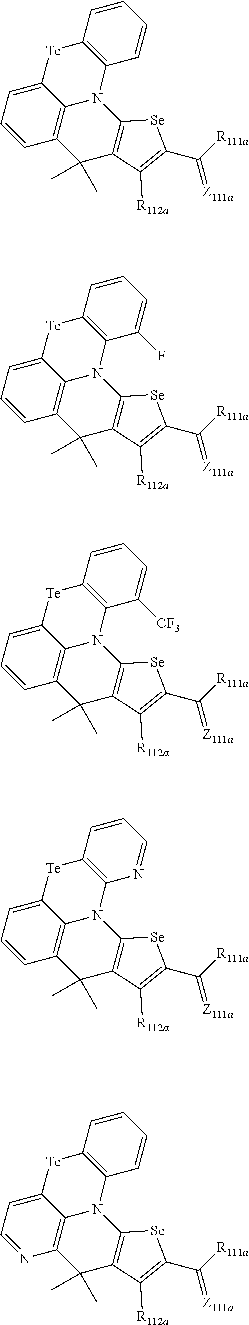 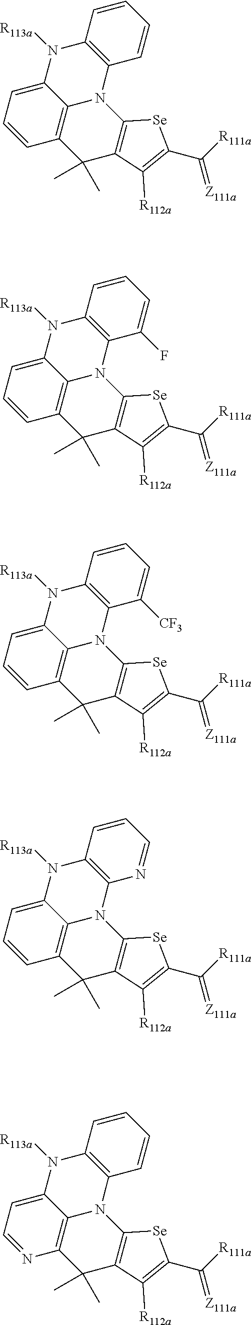 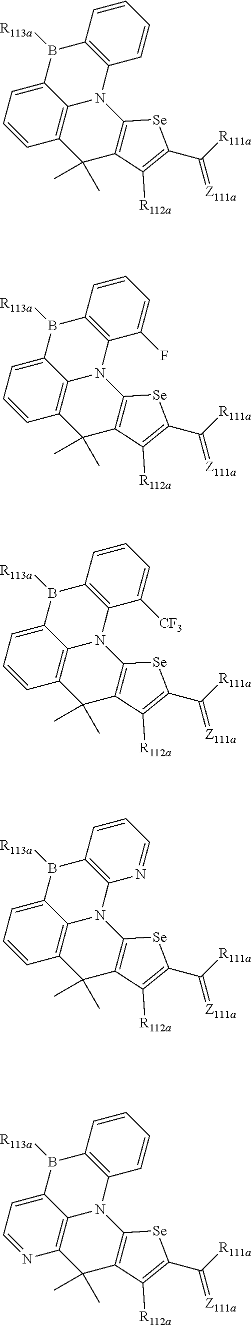 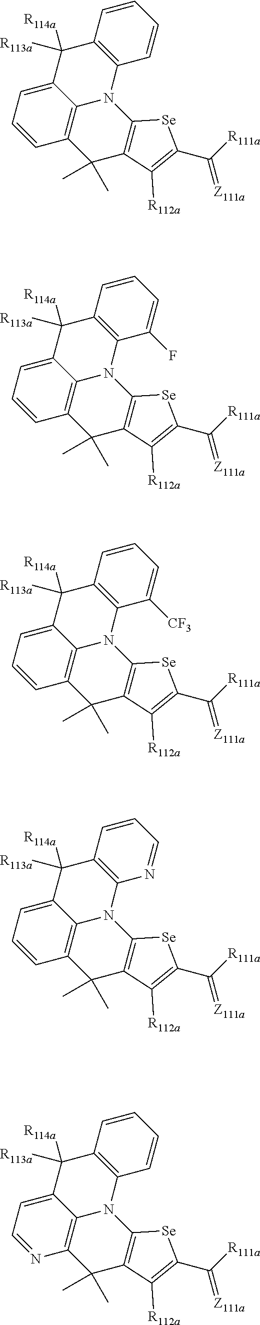 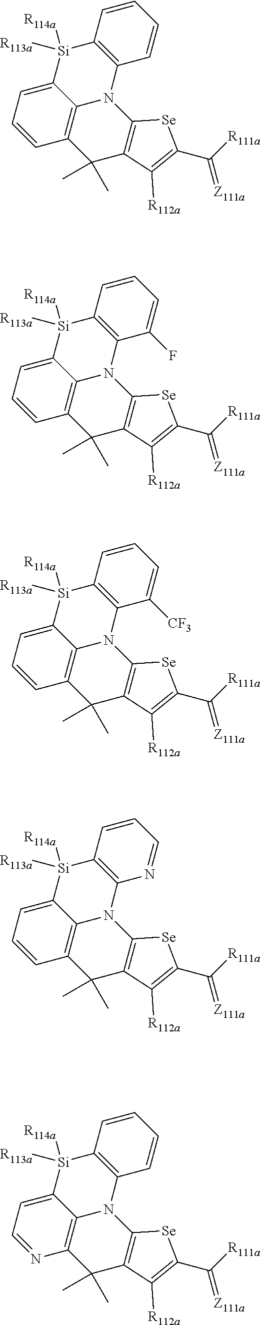 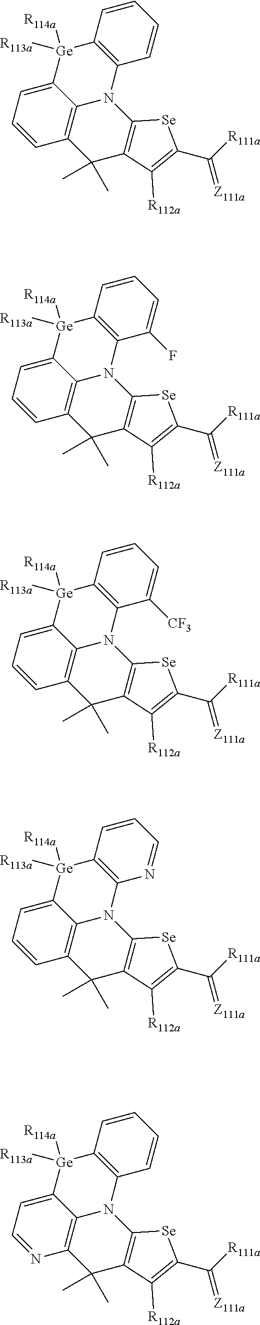 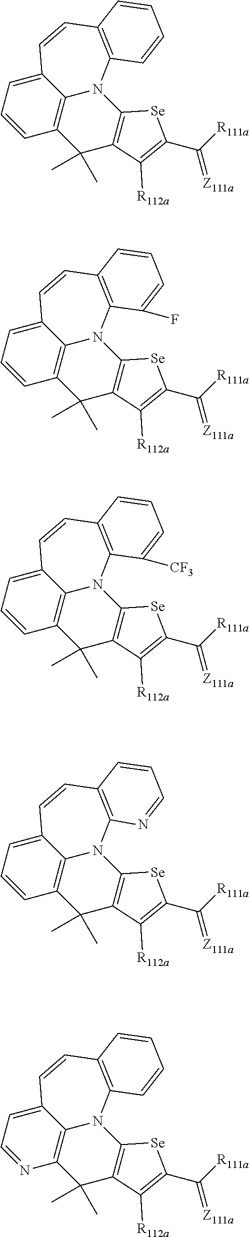 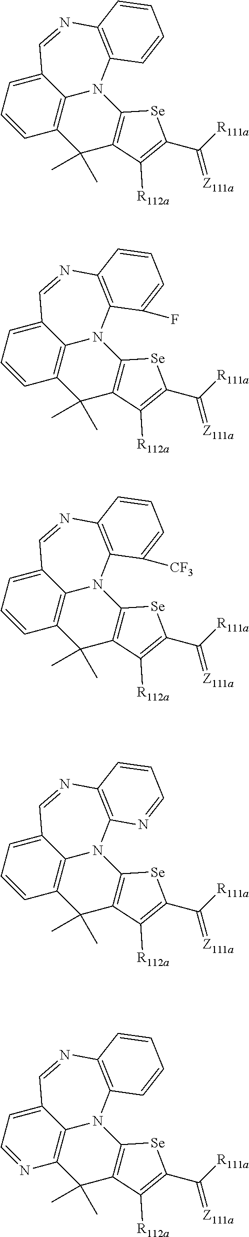 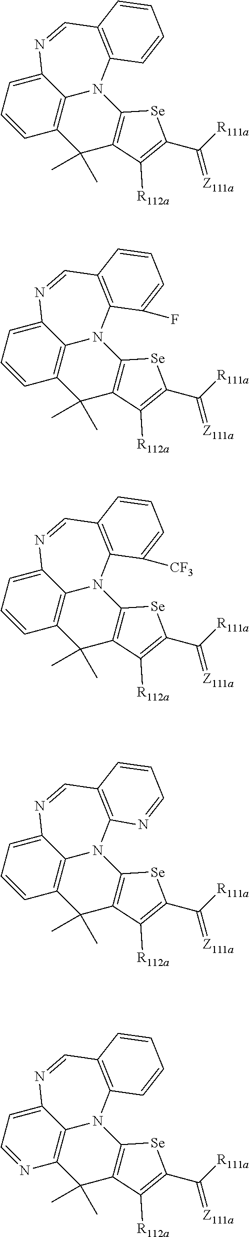 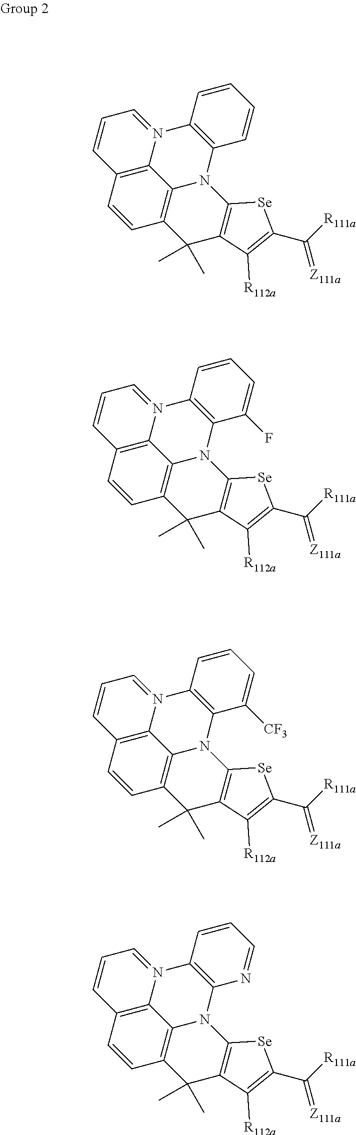 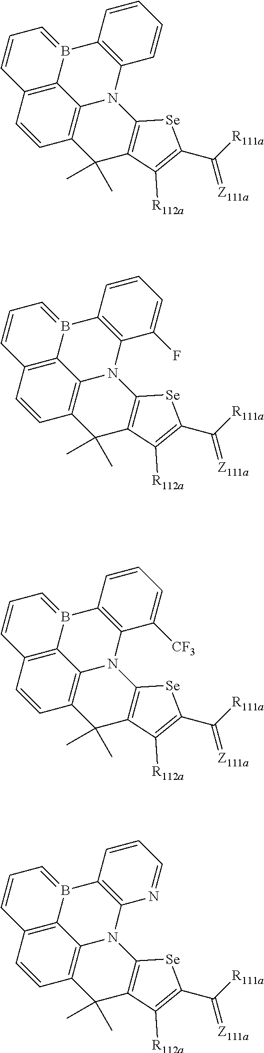 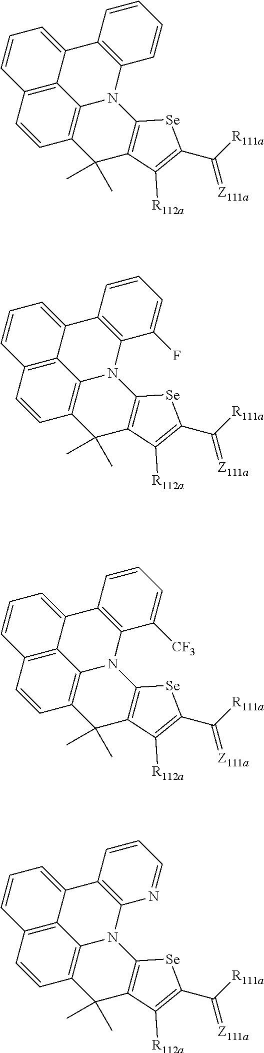 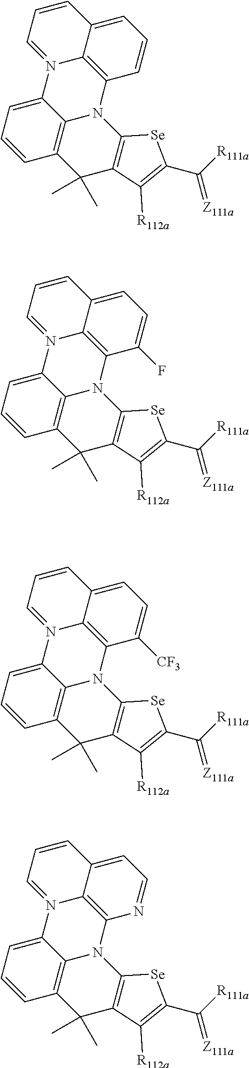 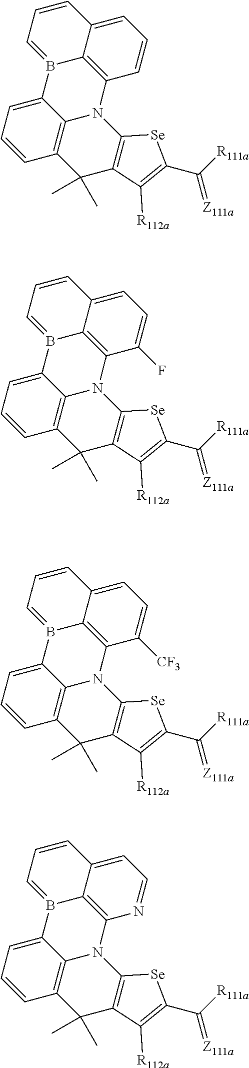 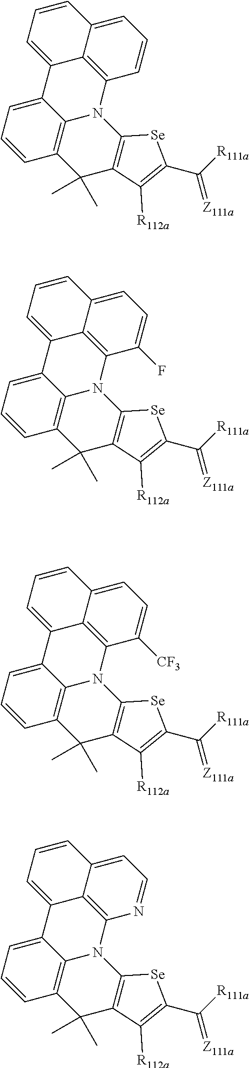 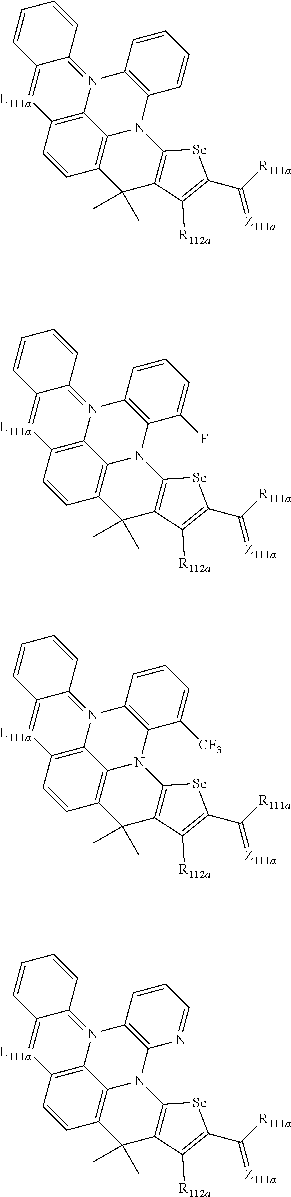 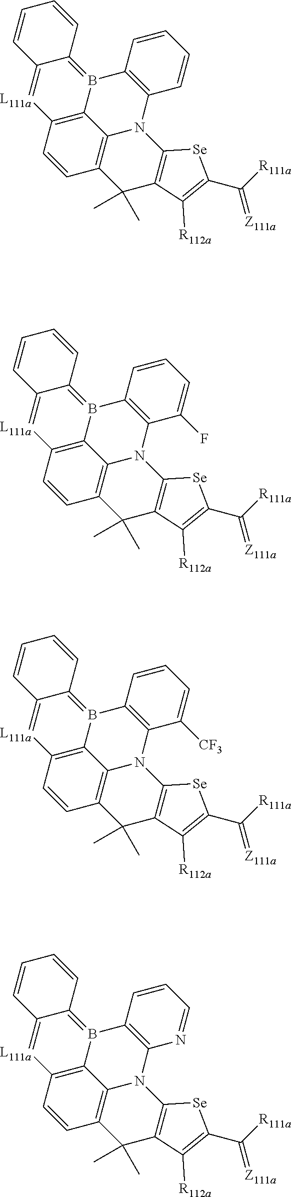 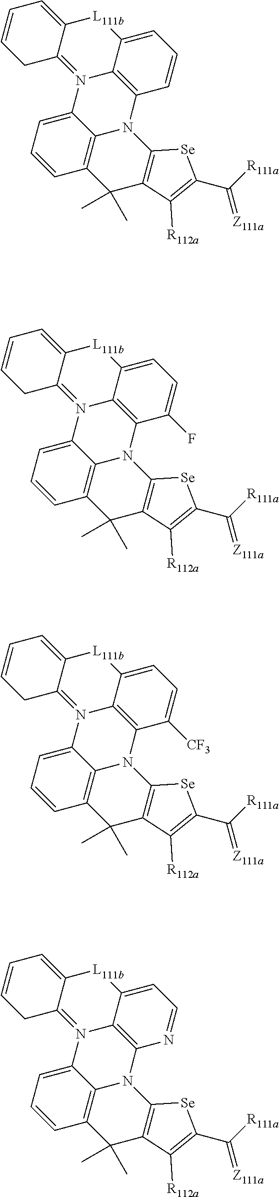 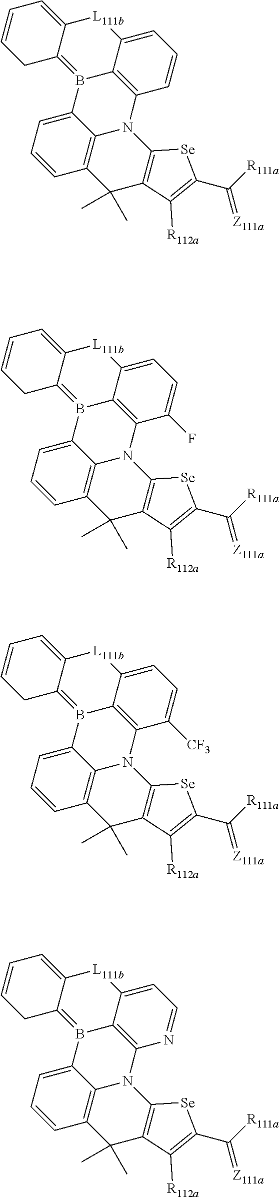 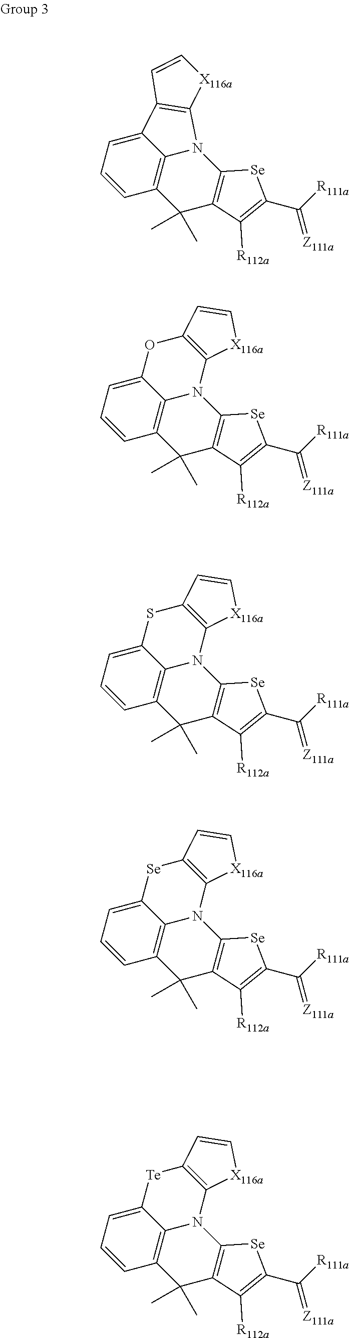 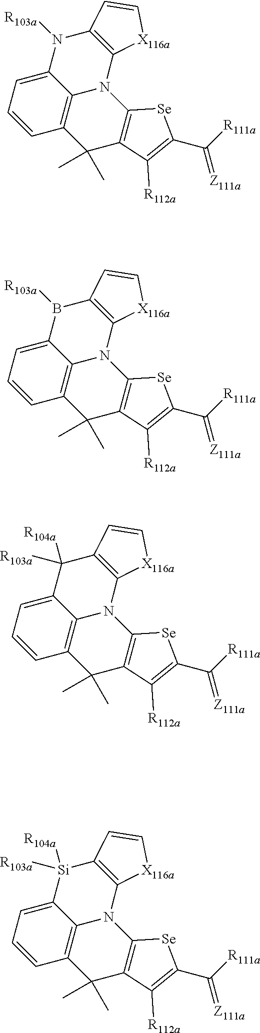 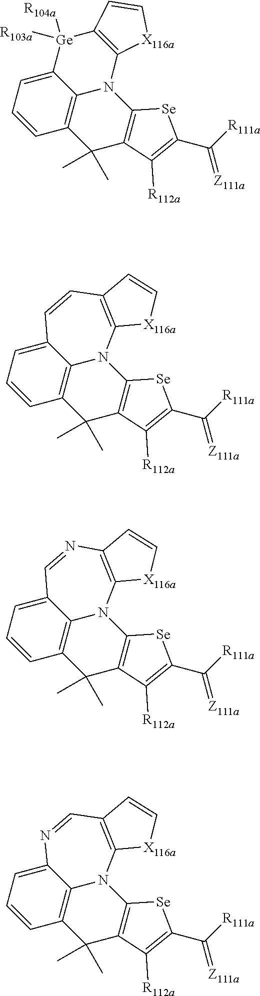 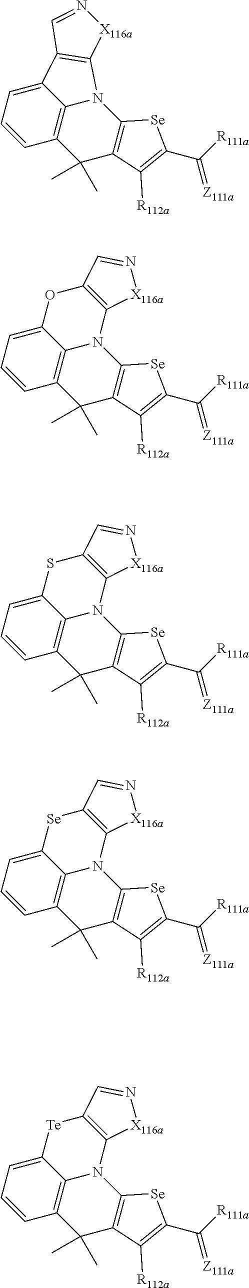 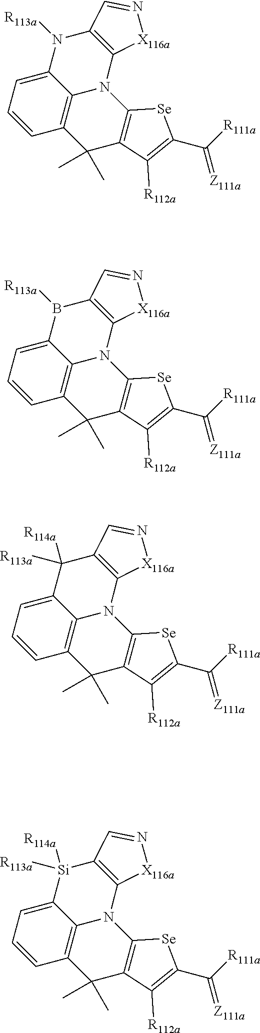 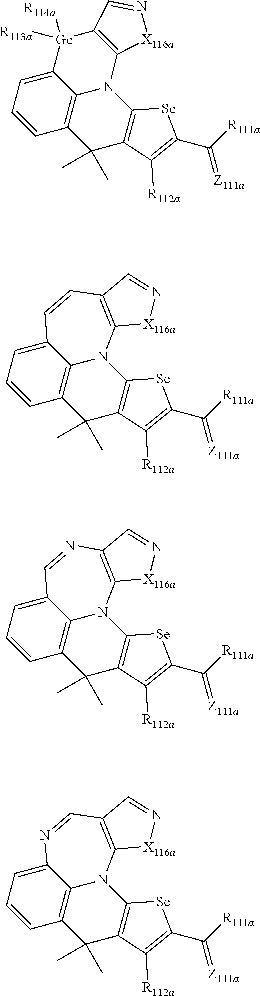 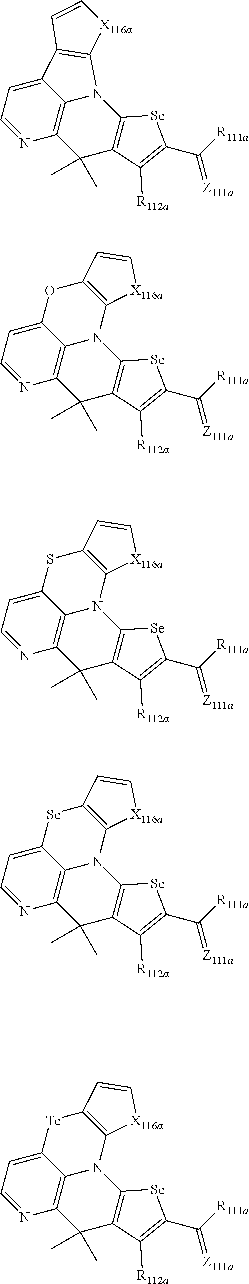 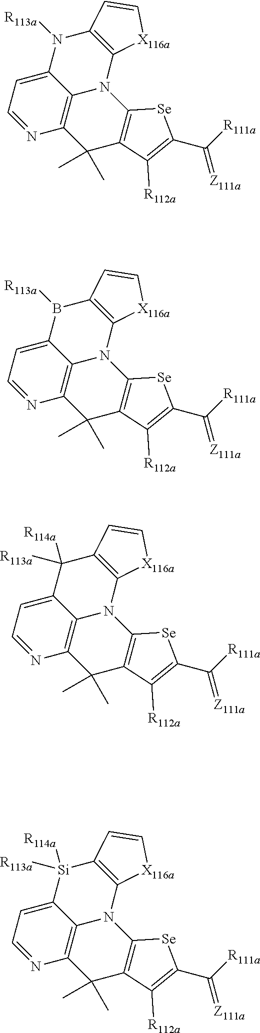 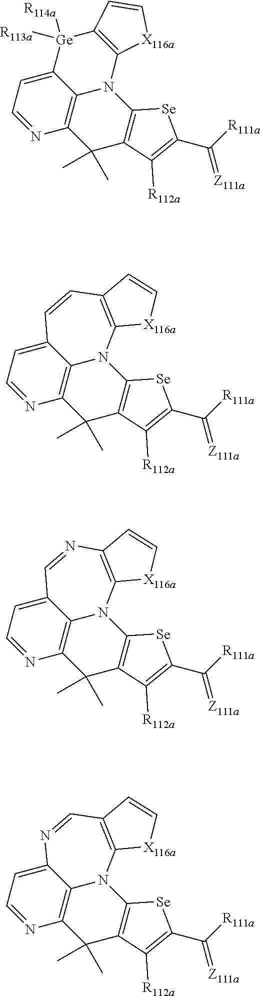
wherein, in the compounds of Groups 1 to 3,
R₁₁₁ₐ to R₁₁₄ are each as defined in connection with R₁₁₁ of Formula 1,
Z₁₁₁ₐ is as defined in connection with Z₁₁₁ of Formula 1, and
X₁₁& is as defined in connection with X₁₁₁ of Formula 1.

17. The electronic apparatus of claim 1, wherein the active layer comprises a p-type semiconductor compound, and
the p-type semiconductor compound comprises a compound represented by Formula 2: 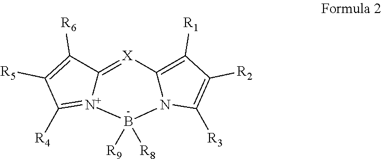
wherein, in Formula 2,
X is CR₇ or N,
R₁ to R₉ are each independently hydrogen, deuterium, a halogen, a cyano group, a nitro group, a hydroxy group, a C₁-C₃₀ alkyl group unsubstituted or substituted with at least one R₁₀ₐ, a C₁-C₃₀ alkoxy group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or any combination thereof,
at least one selected from R₈ and R₉ comprises fluorine or a cyano group,
R₁₀ₐ is:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, Q₃₁, Q₃₂, Q₁₁₁, and Q₁₁₂ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₅-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium,—F, a cyano group, a C₁-C₆₀ alkyl group, a C₁-C₆₀ alkoxy group, a phenyl group, a biphenyl group, or any combination thereof.

18. The electronic apparatus of claim 17, wherein the p-type semiconductor compound comprises any one of the following compounds:

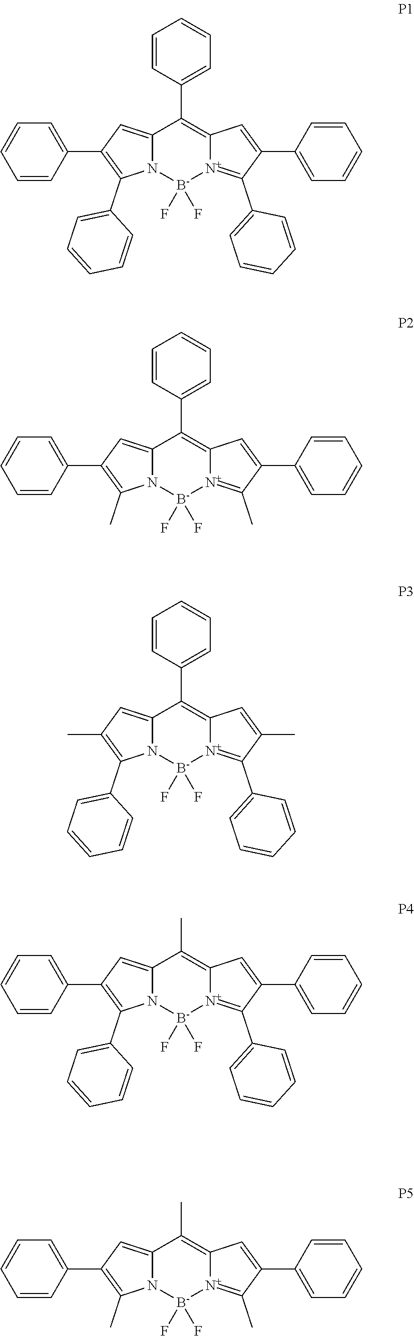 [SMILES: F[B-]1(F)n2c(cc(-c3ccccc3)c2-c2ccccc2)C(c2ccccc2)=C2C=C(c3ccccc3)C(c3ccccc3)=[N+]21 ; CC1=[N+]2C(=C(c3ccccc3)c3cc(-c4ccccc4)c(C)n3[B-]2(F)F)C=C1c1ccccc1 ; CC1=CC2=C(c3ccccc3)c3cc(C)c(-c4ccccc4)n3[B-](F)(F)[N+]2=C1c1ccccc1 ; CC1=C2C=C(c3ccccc3)C(c3ccccc3)=[N+]2[B-](F)(F)n2c1cc(-c1ccccc1)c2-c1ccccc1 ; CC1=C2C=C(c3ccccc3)C(C)=[N+]2[B-](F)(F)n2c1cc(-c1ccccc1)c2C]

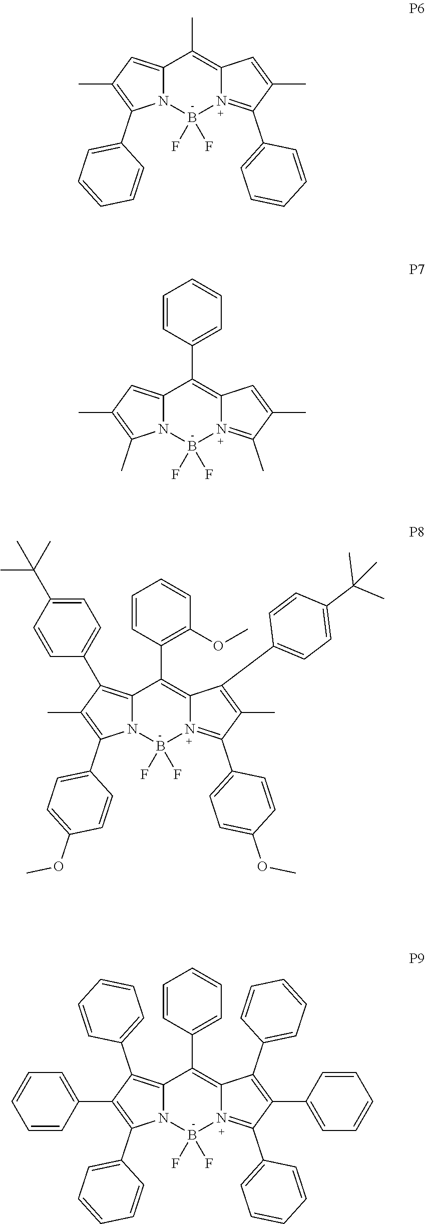

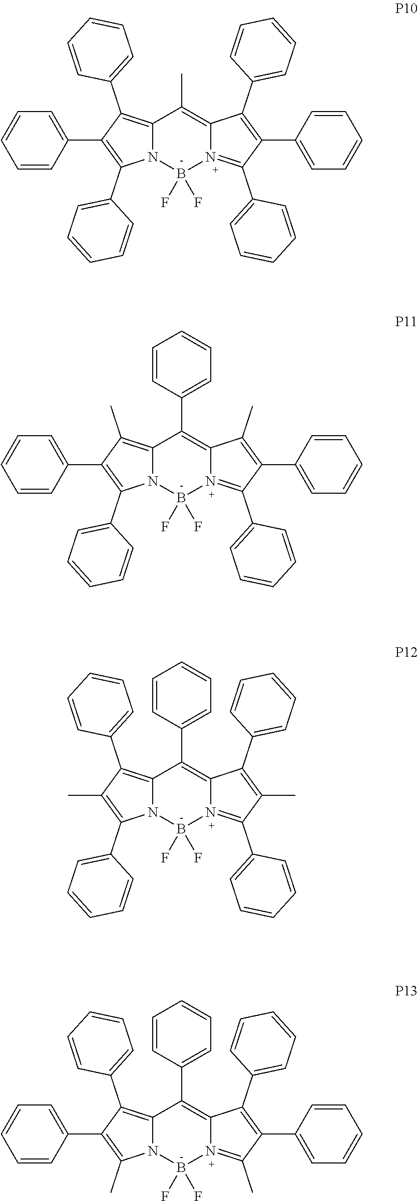

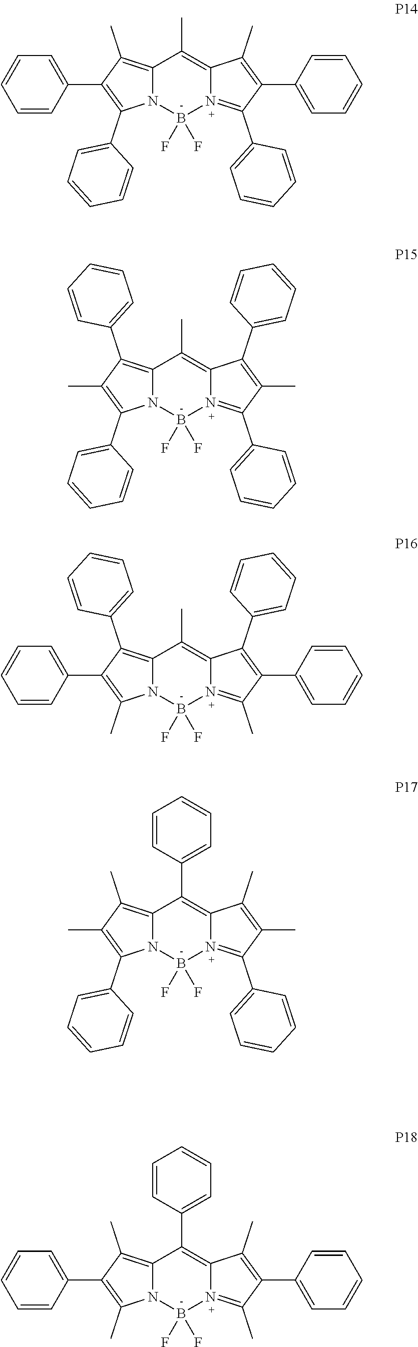

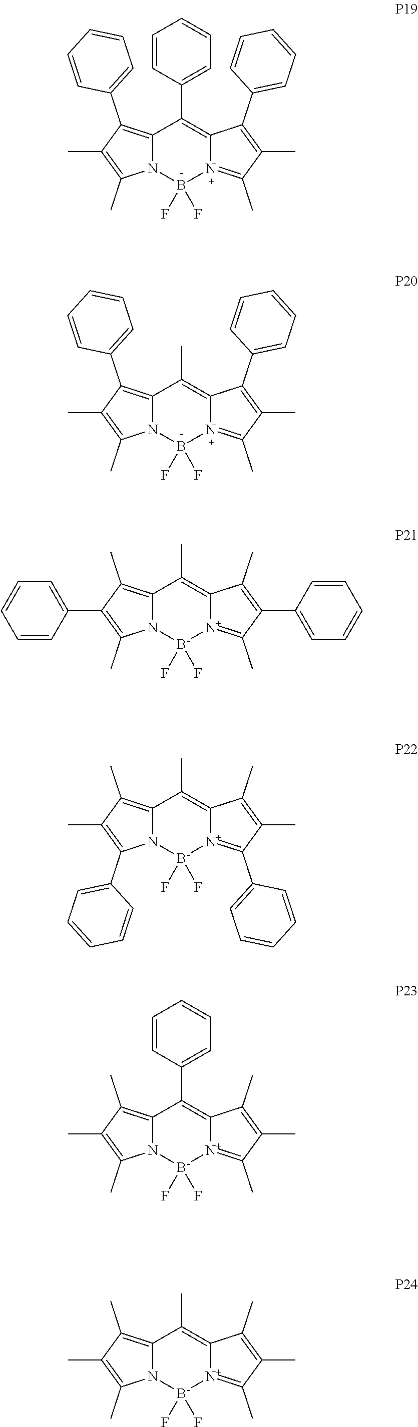

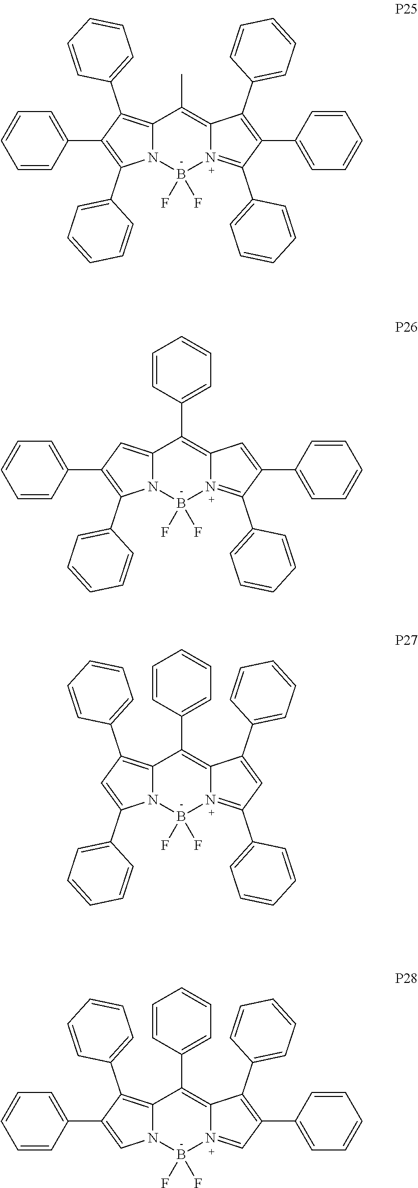

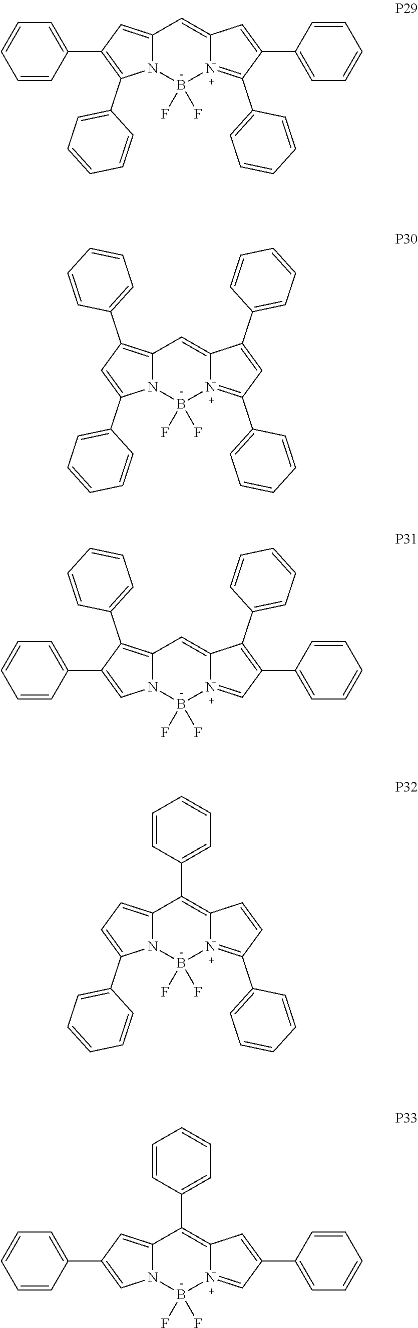

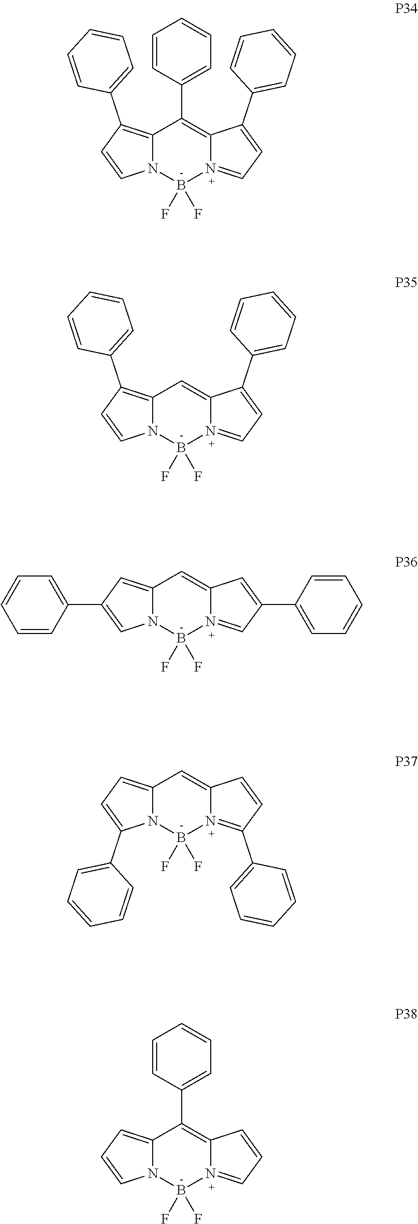

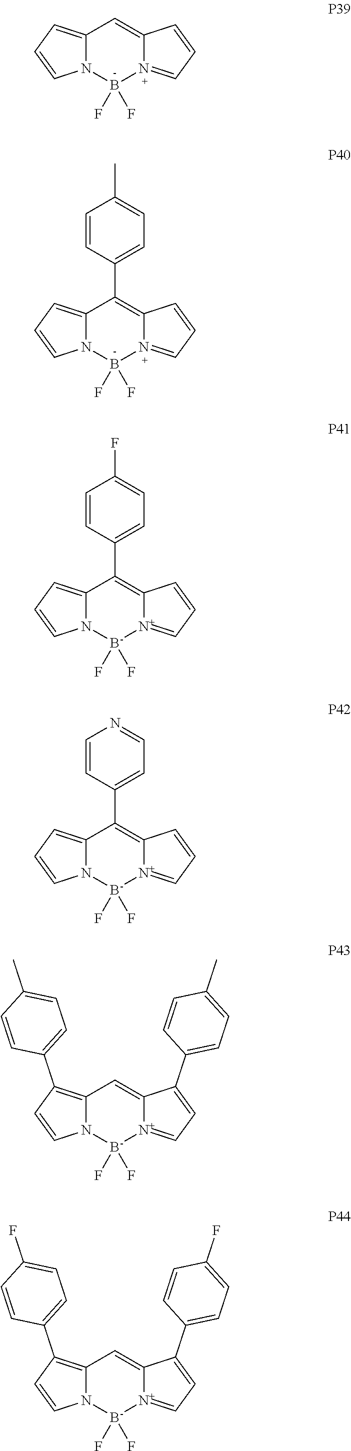

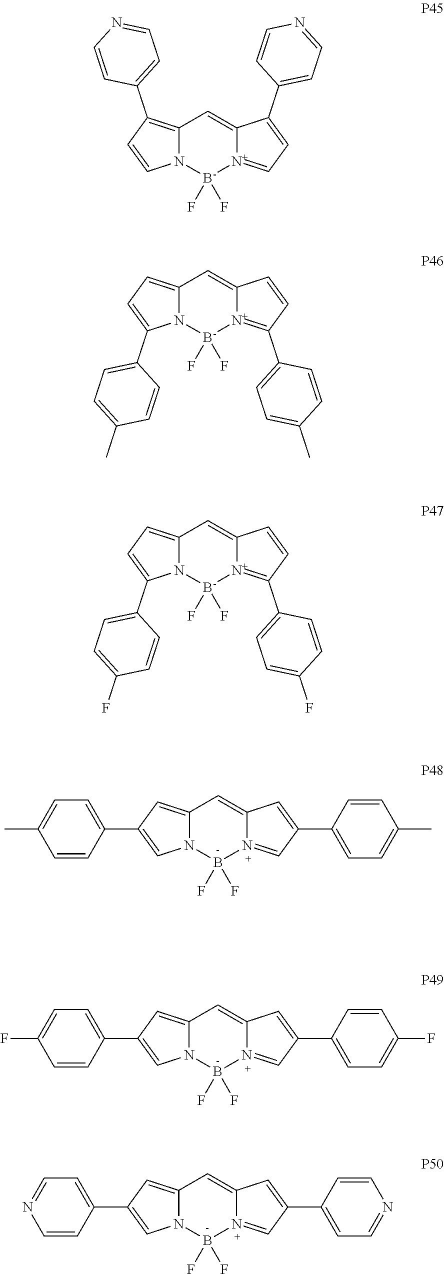

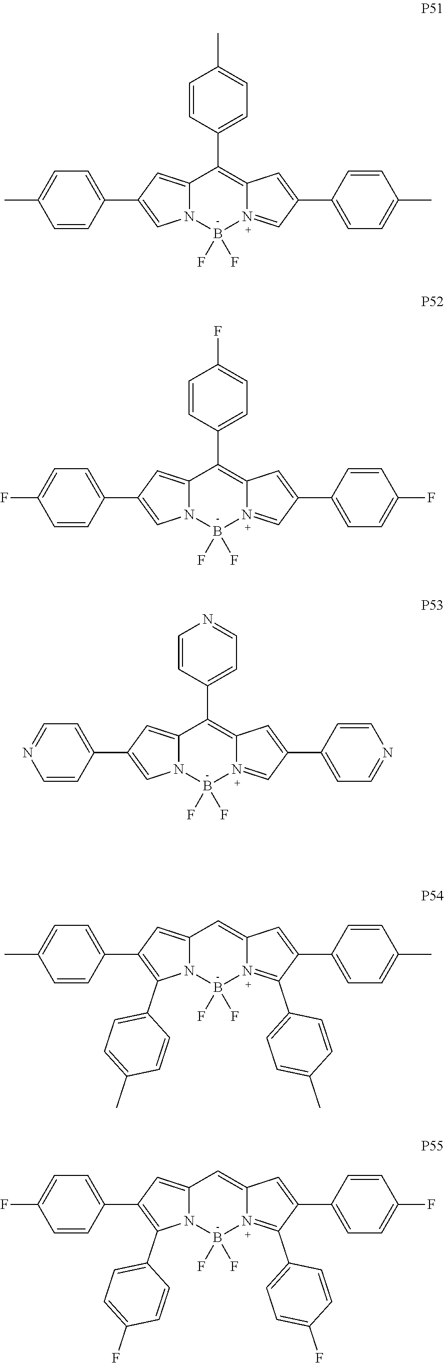

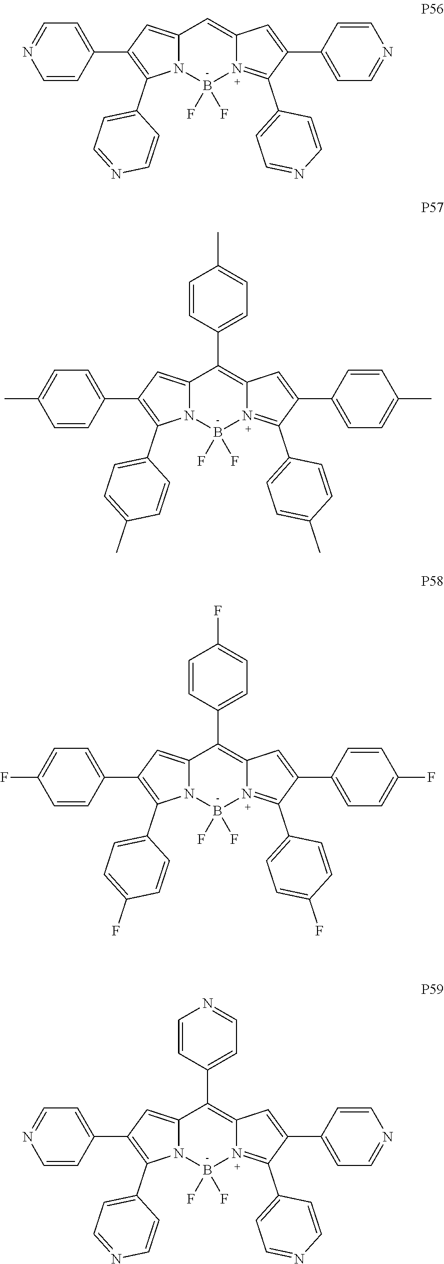

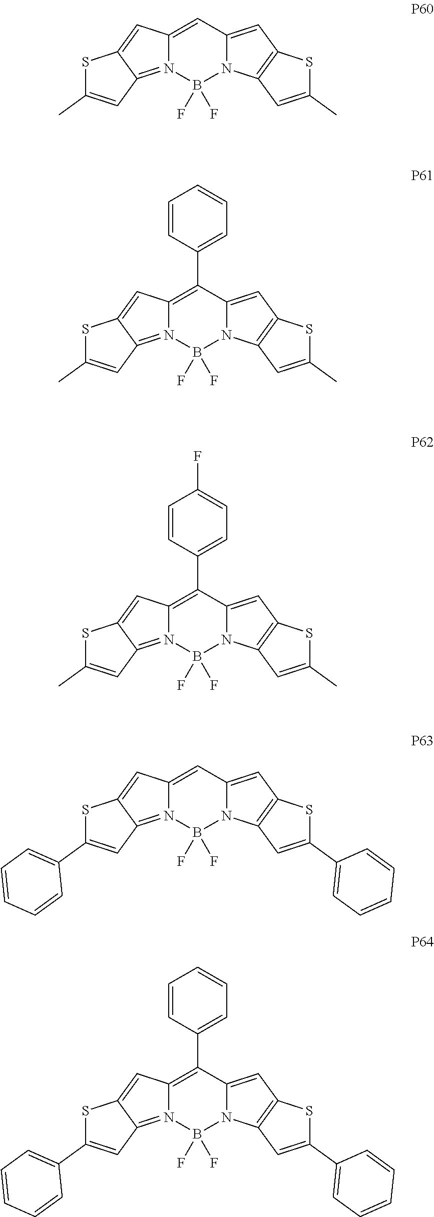

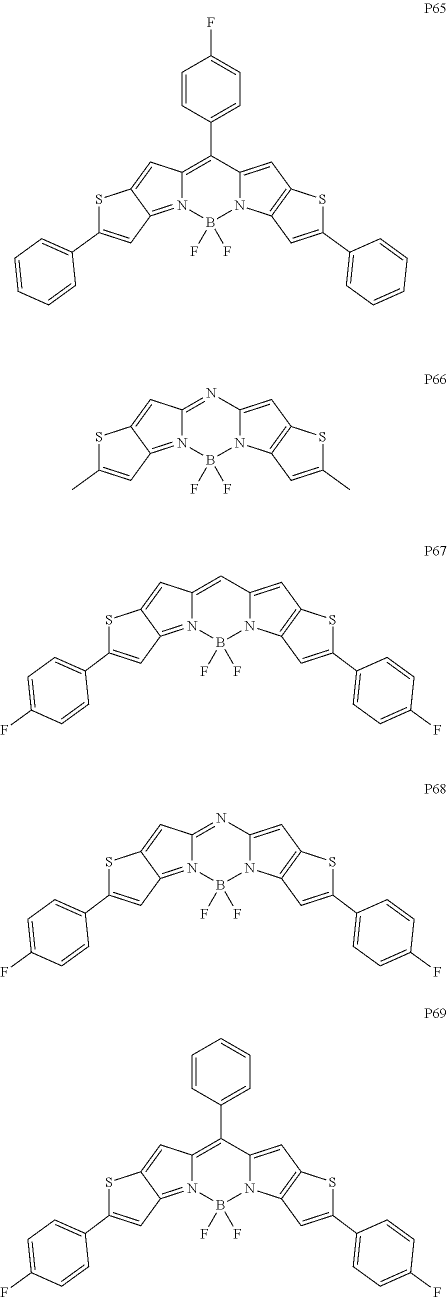

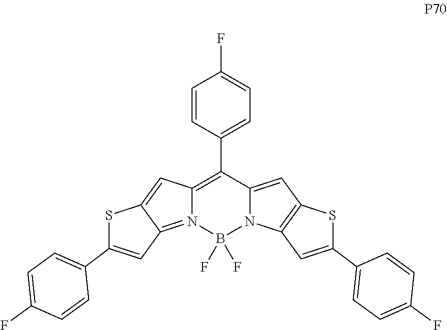

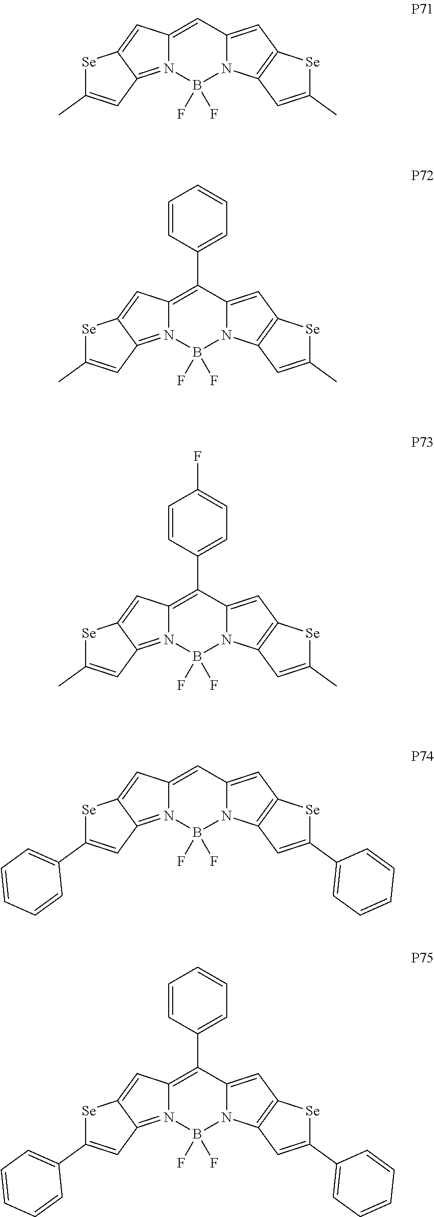

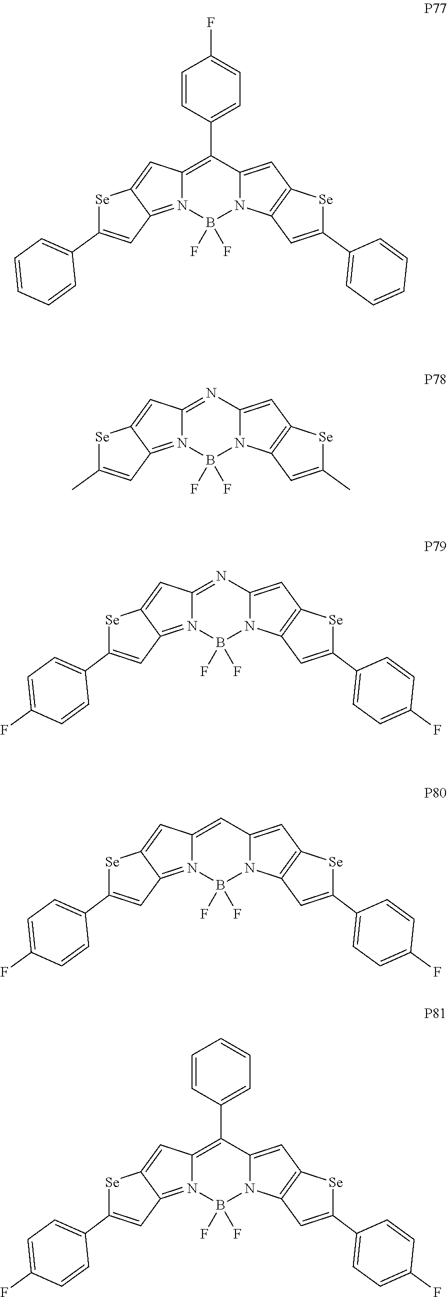

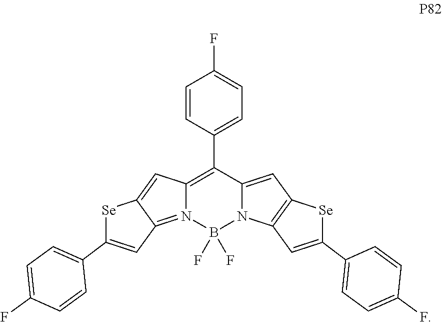

19. The electronic apparatus of claim 1, wherein the active layer comprises an n-type semiconductor compound, and
the n-type semiconductor compound comprises a compound represented by Formula 3 or 4: 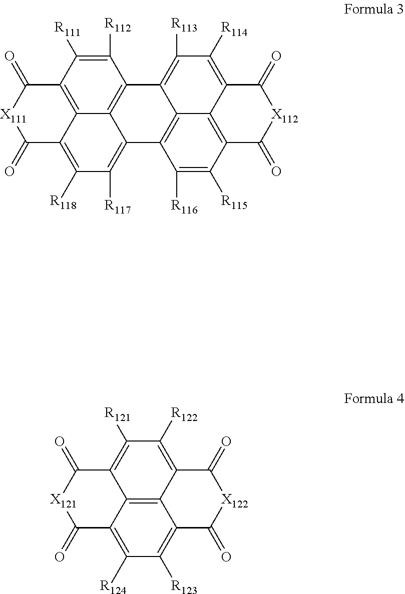
wherein, in Formula 3,
X₁₁₁ and X₁₁₂ are each independently O or NR₁₁₉,
R₁₁₁ to R₁₁₉ are each independently hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₃-C₃₀ heteroaryl group that is unsubstituted or substituted with at least one R₁₀ₐ, or any combination thereof,
wherein, in Formula 4,
X₁₂₁ and X₁₂₂ are each independently O or NR₁₂₅,
R₁₂₁ to R₁₂₅ are each independently hydrogen, deuterium, a halogen, a cyano group, a nitro group, a hydroxy group, a C₁-C₃₀ alkyl group that is unsubstituted or substituted with at least one R₁₀ₐ, a C₆-C₃₀ aryl group that is unsubstituted or substituted with at least one R₁₀ₐ, a C₅-C₃₀ heteroaryl group that is unsubstituted or substituted with at least one R₁₀ₐ, or any combination thereof,
wherein, in Formulae 3 and 4,
R₁₀ₐ is:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, Q₃₁, and Q₃₂ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a Cs—C₆₀ carbocyclic group, a C₁-C₆₀ heterocyclic group; a C₇-C₆₀ arylalkyl group; or a C₂-C₆₀ heteroarylalkyl group, each unsubstituted or substituted with deuterium,—F, a cyano group, a C₁-C₆₀ alkyl group, a C₁-C₆₀ alkoxy group, a phenyl group, a biphenyl group, or any combination thereof.

20. The electronic apparatus of claim 19, wherein the n-type semiconductor compound comprises any one of the following compounds: 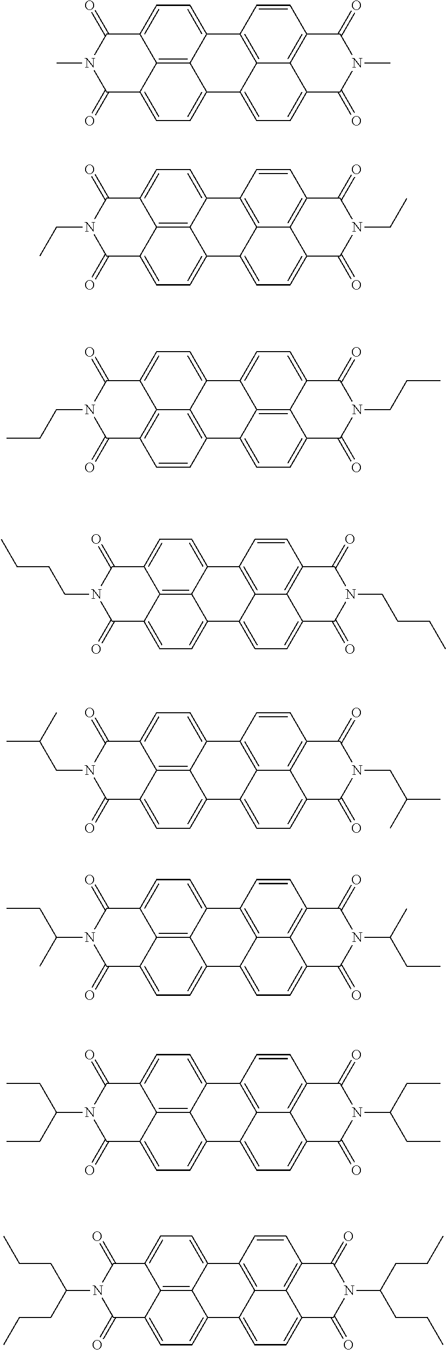 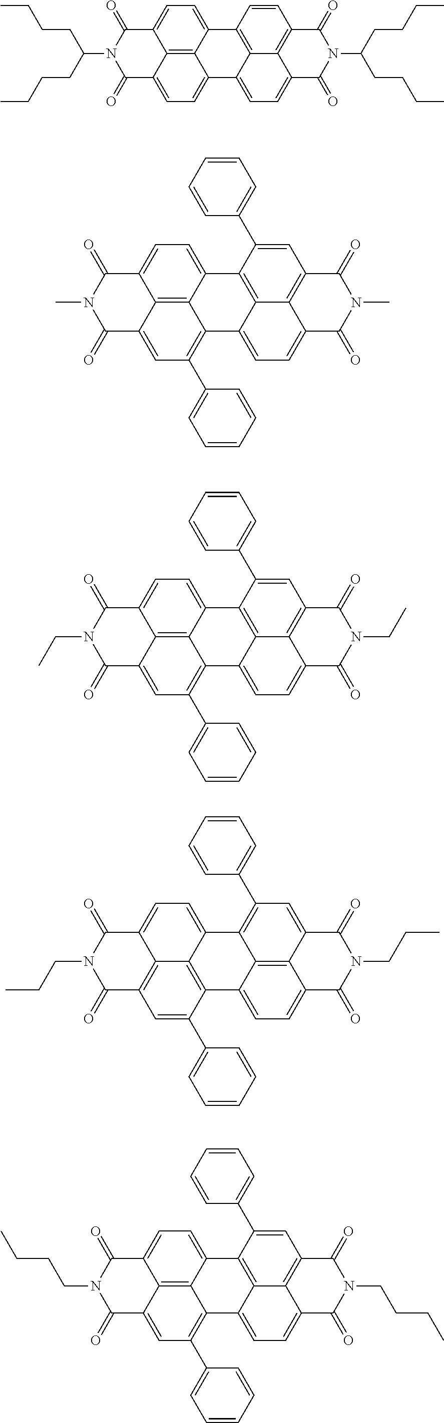 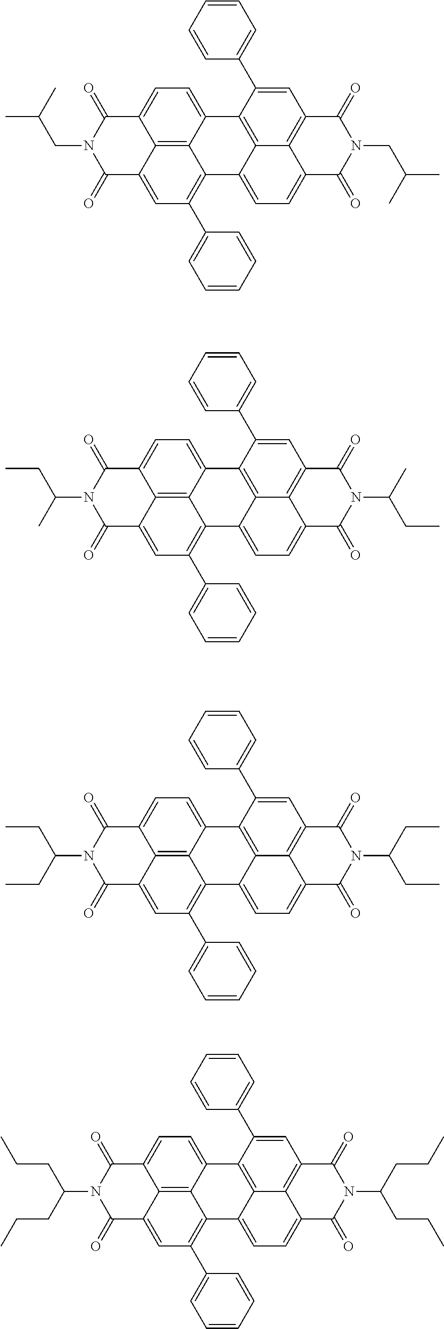 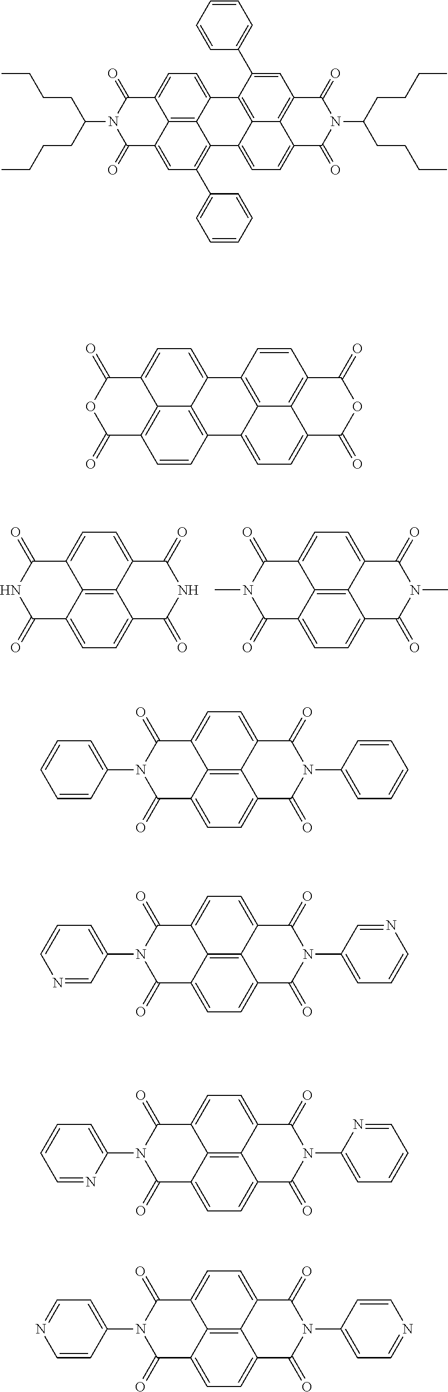 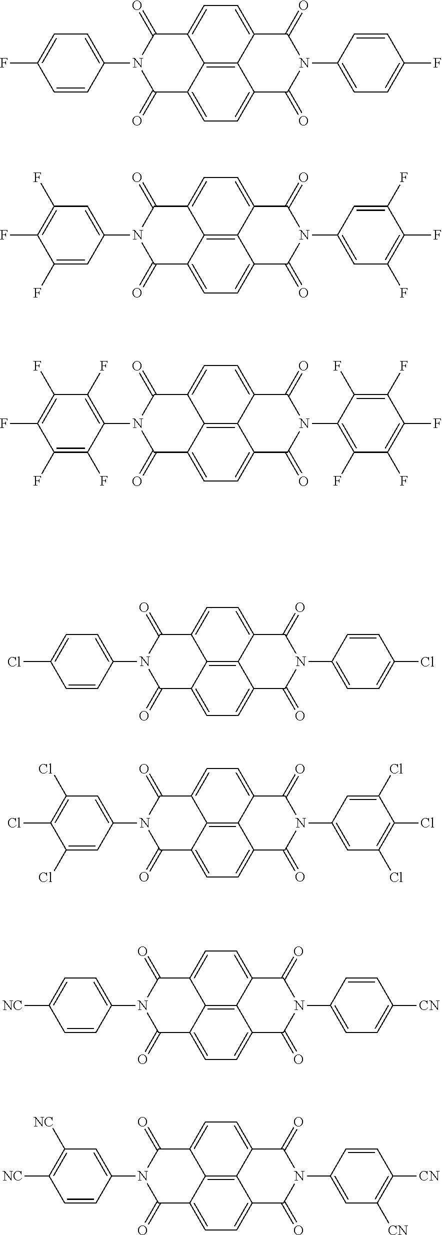 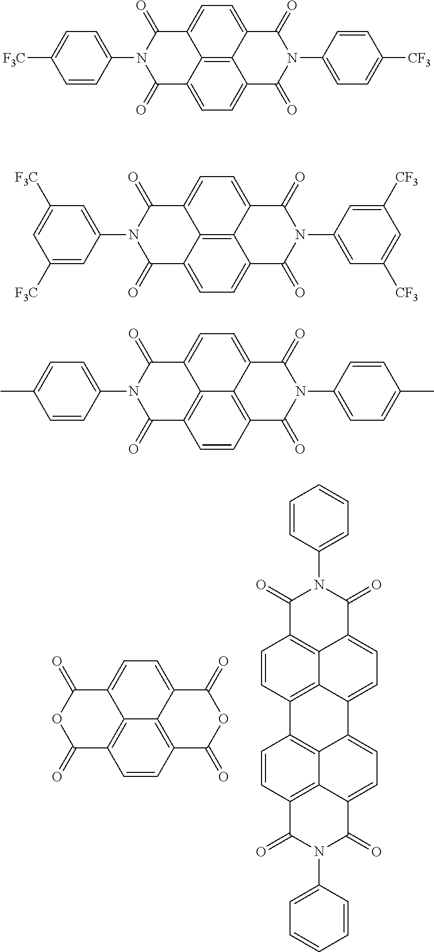 [chemical structure]
